(19) United States
(12) Patent Application Publication
(10) Pub. No.: US 2025/0351299 A1
(43) Pub. Date: Nov. 13, 2025

(54) ELECTRICAL ENERGY-MECHANICAL ENERGY CONVERTER

(71) Applicant: ELEMEC Co., Ltd., Kawasaki-shi (JP)

(72) Inventor: Yuta MIZUTANI, Kawasaki-shi (JP)

(21) Appl. No.: 19/267,640

(22) Filed: Jul. 14, 2025

Related U.S. Application Data
(63) Continuation of application No. PCT/JP2024/000710, filed on Jan. 12, 2024.

(30) Foreign Application Priority Data
Jan. 30, 2023 (JP) 2023-012342

(51) Int. Cl. H05K 7/20

(52) U.S. Cl. CPC H05K 7/20272

(57) ABSTRACT

A heat carrier inlet pipe, a U-phase heat carrier inlet pipe, a V-phase heat carrier inlet pipe and a W-phase heat carrier inlet pipe continued to the heat carrier inlet pipe, a U-phase line, a V-phase line and a W-phase line connected respectively to the U-phase heat carrier inlet pipe, the V-phase heat carrier inlet pipe and the W-phase heat carrier inlet pipe, a U-phase heat carrier coil, a V-phase heat carrier coil and a W-phase heat carrier coil connected respectively to the U-phase heat carrier inlet pipe, the V-phase heat carrier inlet pipe and the W-phase heat carrier inlet pipe, and a heat carrier outlet pipe through which a heat carrier flows after the U-phase heat carrier coil, the V-phase heat carrier coil and the W-phase heat carrier coil and current flows after the U-phase heat carrier coil, the V-phase heat carrier coil and the W-phase heat carrier coil.

### CROSS-REFERENCE TO RELATED APPLICATIONS

This application claims the benefit of priority and is a Continuation application of the prior International Patent Application No. PCT/JP2024/000710, with an international filing date of Jan. 12, 2024, which designated the United States, and is related to the Japanese Patent Application No. 2023-012342, filed Jan. 30, 2023, the entire disclosures of all applications are expressly incorporated by reference in their entirety herein.

### TECHNICAL FIELD

The present invention relates to a converter for converting an electrical energy to a mechanical energy or converting the mechanical energy to the electrical energy.

### BACKGROUND OF THE INVENTION

As for the converter for converting the electrical energy to the mechanical energy or converting the mechanical energy to the electrical energy, a rotating electrical machine that functions as an electric motor or an electric generator and a linear motor are conventionally known, for example. In the above described converter, it is important to suppress temperature increase.

Japanese Unexamined Patent Application Publication No. 2004-135386A discloses an electric machine in which a stator coil is formed by winding a single hollow conductor wire, which is doubled by folding the single hollow conductor at an intermediate position, around a stator core and the temperature increase is suppressed by allowing a heat carrier to flow through the hollow conductor wire.

### SUMMARY OF THE INVENTION

However, in the conventional electric machine described above, the cooling passage length of the hollow conductor is required for both directions to circulate the heat carrier in the wound coil. If the diameter of the hollow conductor is the same, the pressure loss of the heat carrier becomes extremely large since the conductive wire is doubled. In addition, if the space for arranging the hollow conductor is limited, it is necessary to use the hollow conductor having a thin diameter. Furthermore, the distance between the inlet and the outlet of heat carrier of the hollow conductor becomes long, and unevenness tends to occur between the inlet temperature and the outlet temperature of the heat carrier in the coil.

The present invention has been made in view of the conventional problems described above. The object of the present invention is to provide an electrical energy-mechanical energy converter having high cooling performance, high output, small size and lightweight, and excellent productivity.

The present invention solves the problems described above by the following solution means. Although the reference numerals corresponding to the embodiments of this invention are provided in parentheses to facilitate understanding, the present invention is not limited to them. In addition, the configurations explained with the reference numerals may be replaced or modified appropriately.

One aspect is an electrical energy-mechanical energy converter including:
a heat carrier inlet pipe (121) having an electrically non-conductive property so that a heat carrier flows inside the heat carrier inlet pipe (121),
a U-phase heat carrier inlet pipe (121U) continued to the heat carrier inlet pipe (121) so that the heat carrier flows inside the U-phase heat carrier pipe inlet pipe (121U) after the heat carrier flows inside the heat carrier inlet pipe (121), the U-phase heat carrier inlet pipe (121U) having an electrically conductive property;
a U-phase heat carrier coil (231) having a first wound hollow conductor wire which is continued to the U-phase heat carrier inlet pipe (121U) so that the heat carrier flows inside the first hollow conductor after the heat carrier flows inside the U-phase heat carrier inlet pipe (121U), the U-phase heat carrier coil (231) having an electrically conductive property;
a U-phase line (11U) connected to the U-phase heat carrier inlet pipe (121U), the U-phase line (11U) having an electrically conductive property;
a V-phase heat carrier inlet pipe (121V) continued to the heat carrier inlet pipe (121) so that the heat carrier flows inside the V-phase heat carrier inlet pipe (121V) after the heat carrier flows inside the heat carrier inlet pipe (121), the V-phase heat carrier inlet pipe (121V) having an electrically conductive property;
a V-phase heat carrier coil (232) having a second wound hollow conductor wire which is continued to the V-phase heat carrier inlet pipe (121V) so that the heat carrier flows inside the second hollow conductor after the heat carrier flows inside the V-phase heat carrier inlet pipe (121V), the V-phase heat carrier coil (232) having an electrically conductive property;
a V-phase line (11V) connected to the V-phase heat carrier inlet pipe (121V), the V-phase line (11V) having an electrically conductive property;
a W-phase heat carrier inlet pipe (121W) continued to the heat carrier inlet pipe (121) so that the heat carrier flows inside the W-phase heat carrier inlet pipe (121W) after the heat carrier flows inside the heat carrier inlet pipe (121), the W-phase heat carrier inlet pipe (121W) having an electrically conductive property;
a W-phase heat carrier coil (233) having a third wound hollow conductor wire which is continued to the W-phase heat carrier inlet pipe (121W) so that the heat carrier flows inside the third hollow conductor after the heat carrier flows inside the W-phase heat carrier inlet pipe (121W), the W-phase heat carrier coil (233) having an electrically conductive property;
a W-phase line (11W) connected to the W-phase heat carrier inlet pipe (121W), the W-phase line (11W) having an electrically conductive property; and
a heat carrier outlet pipe (122) having an electrically conductive property so that the heat carrier flows inside the heat carrier outlet pipe (122) after the heat carrier flows inside the U-phase heat carrier coil (231), and after the heat carrier flows inside the V-phase heat carrier coil (232), and after the heat carrier flows inside the W-phase heat carrier coil (233) and a current flows through the heat carrier outlet pipe (122) after the current flows through the U-phase heat carrier coil (231), and after the current flows through the V-phase heat carrier coil (232), and after the current flows through the W-phase heat carrier coil (233).

### BRIEF DESCRIPTION OF DRAWINGS

FIG. 1 is a drawing showing a stator of an electrical energy-mechanical energy converter prototyped this time.

FIG. 2 is a drawing for explaining a wiring outline of a stator coil of a rotating electrical machine 1.

FIG. 3A is a planar cross-sectional view of a U-phase connection portion 110U for explaining a U-phase connection portion. FIG. 3B is a simplified drawing of the vicinity of the U-phase connection portion.

FIG. 4 is a drawing simply showing a configuration of the coil in FIG. 2.

FIG. 5 is a drawing showing the configuration diagram of FIG. 4 divided vertically into U-phase, V-phase and W-phase to facilitate understanding of FIG. 4.

FIG. 6 is a drawing for explaining a flow of a heat carrier in FIG. 3B.

FIG. 7 is a drawing for explaining the flow of the heat carrier in FIG. 2.

FIG. 8 is a drawing for explaining the flow of the heat carrier using the exploded diagram shown in FIG. 4.

FIG. 9 is a drawing for explaining a flow of a current in FIG. 3B.

FIG. 10 is a drawing for explaining how the current flows from a U-phase line 11U to a V-phase line 11V in FIG. 2.

FIG. 11 is a drawing for explaining how the current flows from the U-phase line 11U to the V-phase line 11V with reference to the exploded diagram shown in FIG. 4.

FIG. 12 is a drawing for explaining the second embodiment of the rotating electrical machine.

FIG. 13 is a drawing for explaining the third embodiment of the rotating electrical machine.

FIG. 14A is a planar cross-sectional view of the U-phase connection portion 110U for explaining the U-phase connection portion. FIG. 14B is a simplified drawing of the vicinity of the U-phase connection portion.

FIG. 15 is a drawing simply showing a configuration of the coil in FIG. 13.

FIG. 16 is a drawing for explaining a flow of the heat carrier in FIG. 14B.

FIG. 17 is a drawing for explaining a flow of the heat carrier in FIG. 13.

FIG. 18 is a drawing for explaining a flow of the heat carrier using the exploded diagram shown in FIG. 15.

FIGS. 19A and 19B are drawings for explaining a flow of the current in FIGS. 14A and 14B.

FIG. 20 is a drawing for explaining how the current flows from the U-phase line 11U to the V-phase line 11V in FIG. 13.

FIG. 21 is a drawing for explaining how the current flows from the U-phase line 11U to the V-phase line 11V with reference to the exploded diagram shown in FIG. 15.

FIG. 22A is a planar cross-sectional view of the U-phase connection portion 110U of the fourth embodiment of the rotating electrical machine. FIG. 22B is a simplified diagram of the vicinity of the U-phase connection portion.

FIG. 23 is a drawing simply showing a configuration of the coil of the fourth embodiment.

FIG. 24 is a drawing showing the configuration diagram of FIG. 23 divided vertically into U-phase, V-phase and W-phase to facilitate understanding of FIG. 23.

FIGS. 25A and 25B are drawings showing an example of an arrangement of coils.

FIGS. 26A and 26B are drawings showing another example of an arrangement of coils.

FIG. 27 is a drawing showing another example of an arrangement of coils.

FIGS. 28A and 28B are drawings showing another modified embodiment (24-slot type) of the fourth embodiment.

FIG. 29 is a drawing showing the fifth embodiment of the rotating electrical machine.

FIG. 30A is a planar cross-sectional view of the U-phase connection portion 110U for explaining the U-phase connection portion. FIG. 30B is a simplified drawing of the vicinity of the U-phase connection portion.

FIG. 31 is a drawing simply showing a configuration of the coil in FIG. 29.

FIG. 32 is a drawing showing the configuration diagram of FIG. 31 divided vertically into U-phase, V-phase and W-phase to facilitate understanding of FIG. 31.

FIG. 33 is a drawing for explaining a flow of the heat carrier in FIG. 30B.

FIG. 34 is a drawing for explaining a flow of the heat carrier in FIG. 29.

FIG. 35 is a drawing for explaining a flow of the heat carrier using the exploded diagram shown in FIG. 31.

FIG. 36 is a drawing for explaining a flow of the current in FIG. 30B.

FIG. 37 is a drawing for explaining how the current flows from the U-phase line 11U to the V-phase line 11V in FIG. 29.

FIG. 38 is a drawing for explaining how the current flows from the U-phase line 11U to the V-phase line 11V with reference to the exploded diagram shown in FIG. 31.

FIG. 39 is a drawing simply showing a configuration of the coil of the rotating electrical machine of the sixth embodiment.

FIG. 40 is a drawing showing the configuration diagram of FIG. 39 divided vertically into U-phase, V-phase and W-phase to facilitate understanding of FIG. 39.

FIG. 41A is a planar cross-sectional view of the U-phase connection portion 110U for explaining the U-phase connection portion. FIG. 41B is a simplified drawing of the vicinity of the U-phase connection portion.

FIG. 42 is a drawing for explaining a flow of the heat carrier using the exploded diagram shown in FIG. 39.

FIG. 43 is a drawing for explaining how the current flows from the U-phase line 11U to the V-phase line 11V with reference to the exploded diagram shown in FIG. 39.

FIGS. 44A and 44B are drawings showing another modified embodiment (24-slot type) of the sixth embodiment.

FIG. 45A is a planar cross-sectional view of the U-phase connection portion 110U for explaining the U-phase connection portion of the seventh embodiment. FIG. 45B is a simplified drawing of the vicinity of the U-phase connection portion.

FIG. 46 is a drawing simply showing a configuration of the rotating electrical machine of the seventh embodiment.

FIG. 47 is a drawing showing the configuration diagram of FIG. 46 divided vertically into U-phase, V-phase and W-phase to facilitate understanding of FIG. 46.

FIGS. 48A to 48C are drawings showing an example of an arrangement of coils.

FIG. 49 is a drawing for explaining a flow of the heat carrier in FIG. 46.

FIG. 50 is a drawing for explaining how the current flows from the U-phase line 11U to the V-phase line 11V with reference to the exploded diagram shown in FIG. 46.

FIGS. 51A and 51B are drawings showing another modified embodiment (24-slot type) of the seventh embodiment.

FIGS. 52A and 52B are drawings showing another modified embodiment (36-slot type) of the seventh embodiment.

FIGS. 53A and 53B are drawings showing another modified embodiment (48-slot type) of the seventh embodiment.

FIG. 54A is a planar cross-sectional view of the U-phase connection portion 110U for explaining the U-phase connection portion of the eighth embodiment. FIG. 54B is a simplified drawing of the vicinity of the U-phase connection portion.

FIG. 55 is a drawing simply showing a configuration of the coil of the electrical energy-mechanical energy converter system of the ninth embodiment.

FIG. 56 is a drawing showing the configuration diagram of FIG. 55 divided vertically into U-phase, V-phase and W-phase to facilitate understanding of FIG. 55.

FIG. 57 is a phase arrangement diagram of the coil.

FIG. 58 is a drawing for explaining a flow of the heat carrier in FIG. 55.

FIG. 59 is a drawing for explaining how the current flows from the U-phase line 11U to the V-phase line 11V in FIG. 55.

FIGS. 60A and 60B are phase arrangement diagrams of the coil.

FIG. 61 is a perspective view showing the stator of a slotless type rotating electrical machine.

### DETAILED DESCRIPTION OF THE INVENTION

The embodiments of the present invention and the advantages of the present invention will be explained below in detail with reference to the attached drawings.

### First Embodiment

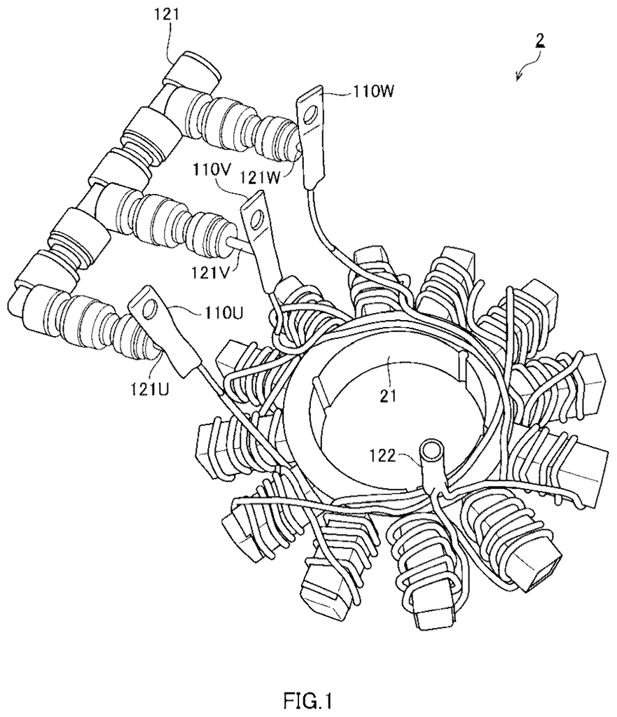

FIG. 1 is a drawing showing a stator of an electrical energy-mechanical energy converter prototyped this time.

In the following explanation, unless otherwise specified, a rotating electrical machine that functions as an electric motor or an electric generator will be explained as the electrical energy-mechanical energy converter.

FIG. 1 shows a stator that is a characteristic component of the rotating electrical machine of the present embodiment. Although the stator used in an outer rotor type rotating electrical machine is shown in FIG. 1, this configuration is merely an example. As shown in FIG. 1, a stator 2 is configured by winding a conductor wire around a stator core 21 to form coils. The above described conductor wire is the hollow conductor wire as described later. The above described coils can be roughly divided into U-phase coils forming a U-phase, V-phase coils forming a V-phase and W-phase coils forming a W-phase.

A heat carrier inlet pipe 121 branches into three paths on the downstream side in the flow direction of the heat carrier. One of the three paths is connected to a U-phase heat carrier inlet pipe 121U, another of the three paths is connected to a V-phase heat carrier inlet pipe 121V, and the other one of the three paths is connected to a W-phase heat carrier inlet pipe 121W.

The U-phase heat carrier inlet pipe 121U is continued to the hollow conductor wire forming the U-phase coil. In addition, the U-phase heat carrier inlet pipe 121U is connected to the U-phase line 11U via a U-phase connection portion 110U. The V-phase heat carrier inlet pipe 121V is continued to the hollow conductor wire forming the V-phase coil. In addition, the V-phase heat carrier inlet pipe 121V is connected to the V-phase line 11V via a V-phase connection portion. The W-phase heat carrier inlet pipe 121W is continued to the hollow conductor wire forming the W-phase coil. In addition, the W-phase heat carrier inlet pipe 121W is connected to a W-phase line 11W via a W-phase connection portion.

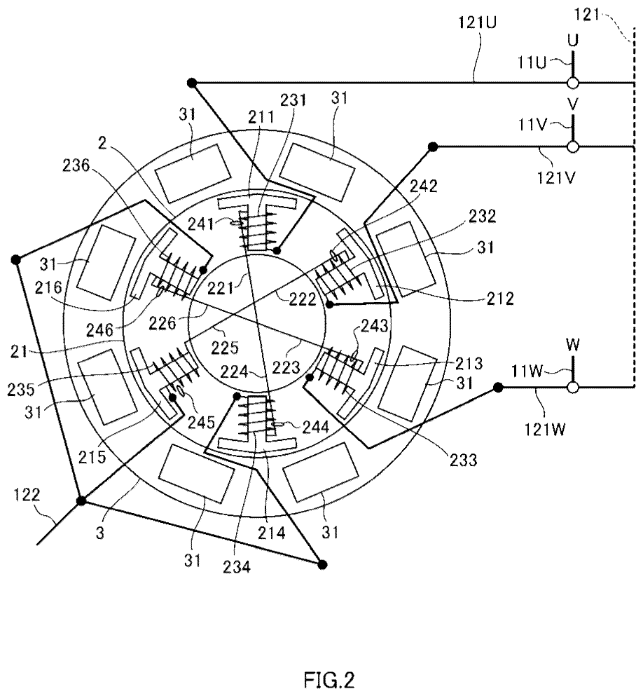

FIG. 2 is a drawing for explaining a wiring outline of a stator coil of a rotating electrical machine 1.

The rotating electrical machine 1 shown in FIG. 2 is an example of this invention and is an outer rotor type with six slots and eight poles (6N8P) where a stator 2 including six slots is arranged on the inner periphery side while a rotor 3 including eight permanent magnets 31 is arranged on the outer periphery side. In addition, the coil is a concentrated winding type.

The stator core 21 of the stator 2 is formed with six slots. Specifically, a first slot 211, a second slot 212, a third slot 213, a fourth slot 214, a fifth slot 215 and a sixth slot 216 are formed in the stator core 21. The second slot 212 is positioned next to the first slot 211. The third slot 213 is positioned next to the second slot 212. The fourth slot 214 is positioned next to the third slot 213. The fifth slot 215 is positioned next to the fourth slot 214. The sixth slot 216 is positioned next to the fifth slot 215. The first slot 211 is positioned next to the sixth slot 216.

A first coil 231 is formed by winding a first hollow conductor wire 221 around the first slot 211. As described above, the coil is formed by winding a single hollow conductor wire around the slot. Thus, it is possible to use a conventional manufacturing device and an excellent productivity is achieved. As an example, the size of the first hollow conductor wire 221 has an outer diameter of approximately 1 to 6 mm and an inner diameter of 0.5 mm or more. Thus, the heat carrier can flow through the first hollow conductor wire 221. However, since the size of the hollow conductor wire depends on the size of the rotating electrical machine, an appropriate size should be selected in accordance with the size of the rotating electrical machine. The same applies to the hollow conductor wire described later. As an insulating material for the hollow conductor wire, an insulating varnish can be used, for example. However, since a high-grade varnish is not required, the cost can be suppressed. Alternatively, an insulating tape or a shrinkable tube may be used. An insulating material using an ultra-thin type shrinkable tube may also be used. In such a case, the insulating material is shrunk in a state that several conductor wires are bundled together. When the hollow conductor wire is used, since the inside of the conductor wire is directly cooled, there is no need to consider the inhibition of the heat dissipation from the surface of the conductor wire due to the insulation coating. Thus, the insulation coating can be made thicker and it is easy to further increase the voltage.

In addition, a temperature sensor 241 for detecting the coil temperature is provided in the first coil 231. One end (heat carrier inlet) of the first hollow conductor wire 221 is connected to the U-phase heat carrier inlet pipe 121U. The U-phase heat carrier inlet pipe 121U has an electrically conductive property and the electricity flows through the U-phase heat carrier inlet pipe 121U. The U-phase heat carrier inlet pipe 121U is connected to the heat carrier inlet pipe 121 having an electrically non-conductive property. The heat carrier inlet pipe 121 is branched into three paths on the downstream side of the heat carrier. One of the three paths is connected to the U-phase heat carrier inlet pipe 121U, another of the three paths is connected to the V-phase heat carrier inlet pipe 121V, and the other one of the three paths is connected to the W-phase heat carrier inlet pipe 121W.

The other end (heat carrier outlet) of the first hollow conductor wire 221 is connected to one end (heat carrier inlet) of a fourth hollow conductor wire 224 of the fourth slot 214.

A second coil 232 is formed by winding a second hollow conductor wire 222 around the second slot 212. Same as the first hollow conductor wire 221, the second hollow conductor wire 222 has a hollow shape so that the heat carrier can flow through the second hollow conductor wire 222. A temperature sensor 242 for detecting the coil temperature is provided in the second coil 232. One end (heat carrier inlet) of the second hollow conductor wire 222 is connected to the V-phase heat carrier inlet pipe 121V. The other end (heat carrier outlet) of the second hollow conductor wire 222 is connected to one end (heat carrier inlet) of a fifth hollow conductor wire 225 of the fifth slot 215.

A third coil 233 is formed by winding a third hollow conductor wire 223 around the third slot 213. Same as the first hollow conductor wire 221, the third hollow conductor wire 223 has a hollow shape so that the heat carrier can flow through the third hollow conductor wire 223. A temperature sensor 243 for detecting the coil temperature is provided in the third coil 233. One end (heat carrier inlet) of the third hollow conductor wire 223 is connected to the W-phase heat carrier inlet pipe 121W. The other end (heat carrier outlet) of the third hollow conductor wire 223 is connected to one end (heat carrier inlet) of a sixth hollow conductor wire 226 of the sixth slot 216.

A fourth coil 234 is formed by winding the fourth hollow conductor wire 224 around the fourth slot 214. Same as the first hollow conductor wire 221, the fourth hollow conductor wire 224 has a hollow shape so that the heat carrier can flow through the fourth hollow conductor wire 224. A temperature sensor 244 for detecting the coil temperature is provided in the fourth coil 234. One end (heat carrier inlet) of the fourth hollow conductor wire 224 is connected to the other end (heat carrier outlet) of the first hollow conductor wire 221. The other end (heat carrier outlet) of the fourth hollow conductor wire 224 is connected to a heat carrier outlet pipe 122. Note that the heat carrier outlet pipe 122 has an electrically conductive property and electricity flows through the heat carrier outlet pipe 122. However, the heat carrier outlet pipe 122 is connected to a non-conductive component.

A fifth coil 235 is formed by winding the fifth hollow conductor wire 225 around the fifth slot 215. Same as the first hollow conductor wire 221, the fifth hollow conductor wire 225 has a hollow shape so that the heat carrier can flow through the fifth hollow conductor wire 225. A temperature sensor 245 for detecting the coil temperature is provided in the fifth coil 235. One end (heat carrier inlet) of the fifth hollow conductor wire 225 is connected to the other end (heat carrier outlet) of the second hollow conductor wire 222. The other end (heat carrier outlet) of the fifth hollow conductor wire 225 is connected to the heat carrier outlet pipe 122.

A sixth coil 236 is formed by winding the sixth hollow conductor wire 226 around the sixth slot 216. Same as the first hollow conductor wire 221, the sixth hollow conductor wire 226 has a hollow shape so that the heat carrier can flow through the sixth hollow conductor wire 226. A temperature sensor 246 for detecting the coil temperature is provided in the sixth coil 236. One end (heat carrier inlet) of the sixth hollow conductor wire 226 is connected to the other end (heat carrier outlet) of the third hollow conductor wire 223. The other end (heat carrier outlet) of the sixth hollow conductor wire 226 is connected to the heat carrier outlet pipe 122.

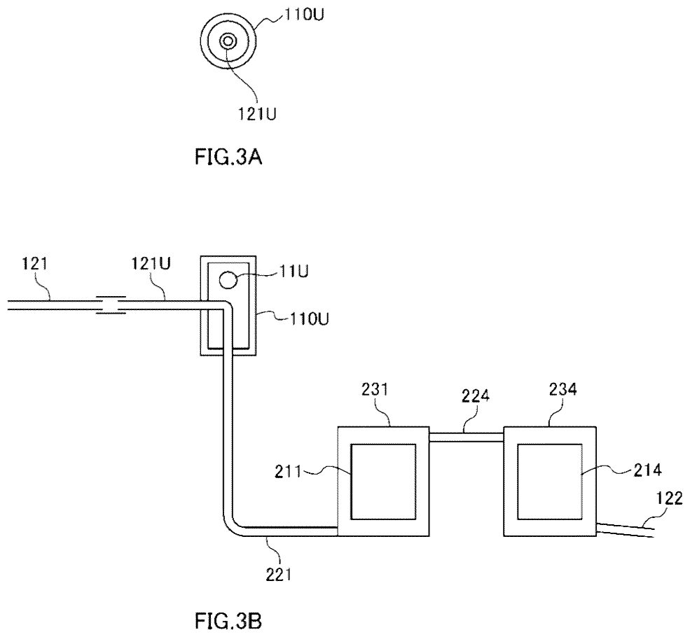

FIGS. 3A and 3B are drawings for explaining a U-phase connection portion. FIG. 3A is a planar cross-sectional view of the U-phase connection portion 110U. FIG. 3B is a simplified drawing of the vicinity of the U-phase connection portion.

As described above, the U-phase line 11U is connected to the U-phase heat carrier inlet pipe 121U via the U-phase connection portion 110U. The U-phase heat carrier inlet pipe 121U is connected to one end (heat carrier inlet) of the first hollow conductor wire 221 of the first slot 211. The other end (heat carrier outlet) of the first hollow conductor wire 221 is connected to one end (heat carrier inlet) of the fourth hollow conductor wire 224 of the fourth slot 214. The other end (heat carrier outlet) of the fourth hollow conductor wire 224 is connected to the heat carrier outlet pipe 122. By employing the above described configuration, the U-phase heat carrier inlet pipe 121U, the first slot 211 (first hollow conductor wire 221), the fourth slot 214 (fourth hollow conductor wire 224) and the heat carrier outlet pipe 122 are arranged in series. Note that the U-phase heat carrier inlet pipe 121U, the first hollow conductor wire 221 and the fourth hollow conductor wire 224 may be the same. Namely, the first hollow conductor wire 221 may also form the fourth coil 234 by being wound around fourth slot 214 in addition to form the first coil 231 by being wound around the first slot 211.

Although the U-phase connection portion is explained in FIGS. 3A and 3B, the explanation of the V-phase connection portion and the W-phase connection portion is omitted since the configuration is the same.

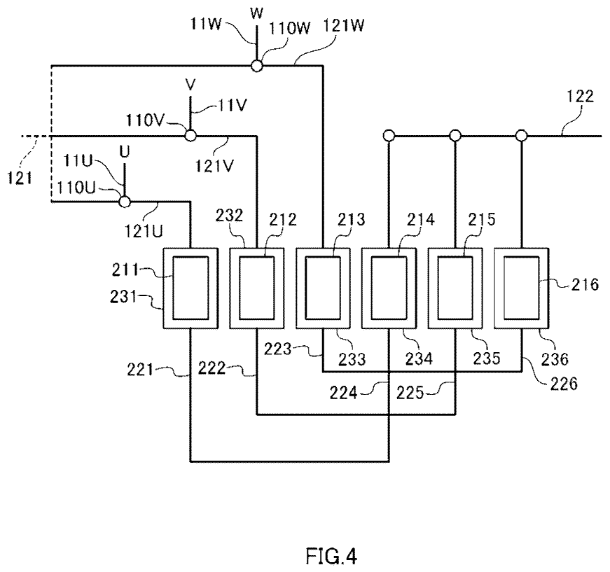

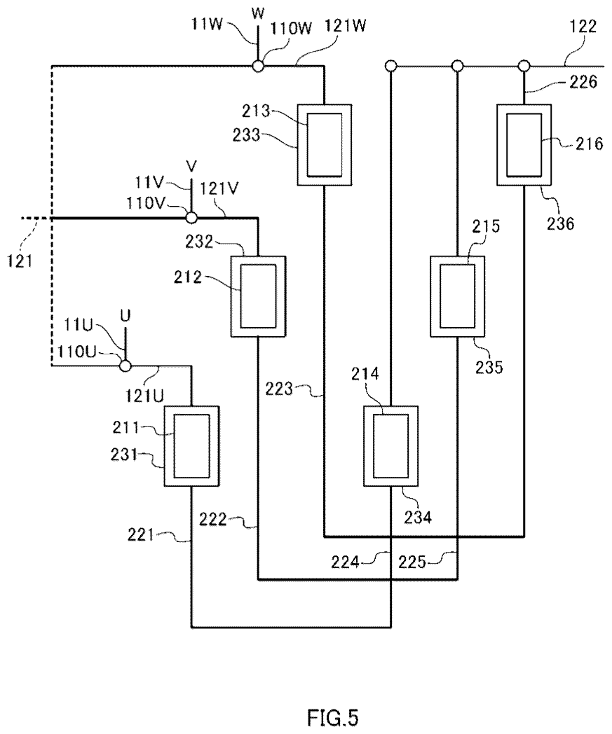

FIG. 4 is a drawing simply showing the configuration of the coil in FIG. 2. FIG. 5 is a drawing showing the configuration diagram of FIG. 4 divided vertically into U-phase, V-phase and W-phase to facilitate understanding of FIG. 4.

The heat carrier inlet pipe 121 is branched into three paths on the downstream side of the heat carrier. One of the three paths is connected to the U-phase heat carrier inlet pipe 121U, another of the three paths is connected to the V-phase heat carrier inlet pipe 121V, and the other one of the three paths is connected to the W-phase heat carrier inlet pipe 121W.

The U-phase heat carrier inlet pipe 121U is continued to one end (heat carrier inlet) of the first hollow conductor wire 221 of the first coil 231 formed in the first slot 211. The other end (heat carrier outlet) of the first hollow conductor wire 221 is continued to one end (heat carrier inlet) of the fourth hollow conductor wire 224 of the fourth coil 234 formed in the fourth slot 214. The other end (heat carrier outlet) of the fourth hollow conductor wire 224 is continued to the heat carrier outlet pipe 122.

In addition, the V-phase heat carrier inlet pipe 121V is continued to one end (heat carrier inlet) of the second hollow conductor wire 222 of the second coil 232 formed in the second slot 212. The other end (heat carrier outlet) of the second hollow conductor wire 222 is continued to one end (heat carrier inlet) of the fifth hollow conductor wire 225 of the fifth coil 235 formed in the fifth slot 215. The other end (heat carrier outlet) of the fifth hollow conductor wire 225 is continued to the heat carrier outlet pipe 122.

Furthermore, the W-phase heat carrier inlet pipe 121W is continued to one end (heat carrier inlet) of the third hollow conductor wire 223 of the third coil 233 formed in the third slot 213. The other end (heat carrier outlet) of the third hollow conductor wire 223 is continued to one end (heat carrier inlet) of the sixth hollow conductor wire 226 of the sixth coil 236 formed in the sixth slot 216. The other end (heat carrier outlet) of the sixth hollow conductor wire 226 is continued to the heat carrier outlet pipe 122.

Then, the flow of the heat carrier will be explained.

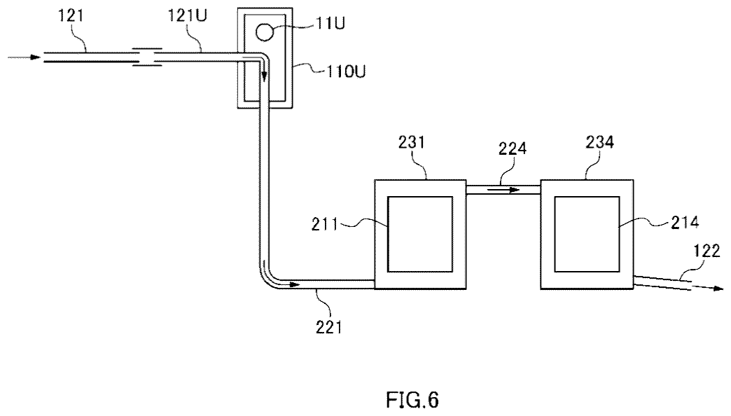

FIG. 6 is a drawing for explaining the flow of the heat carrier in FIG. 3B. Note that the arrow marks indicate the flow direction of the heat carrier.

As shown by the arrow marks, after the heat carrier flows through the heat carrier inlet pipe 121, the heat carrier branches into the U-phase heat carrier inlet pipe 121U, passes through the first hollow conductor wire 221 of the first coil 231 and the fourth hollow conductor wire 224 of the fourth coil 234 and flows into the heat carrier outlet pipe 122.

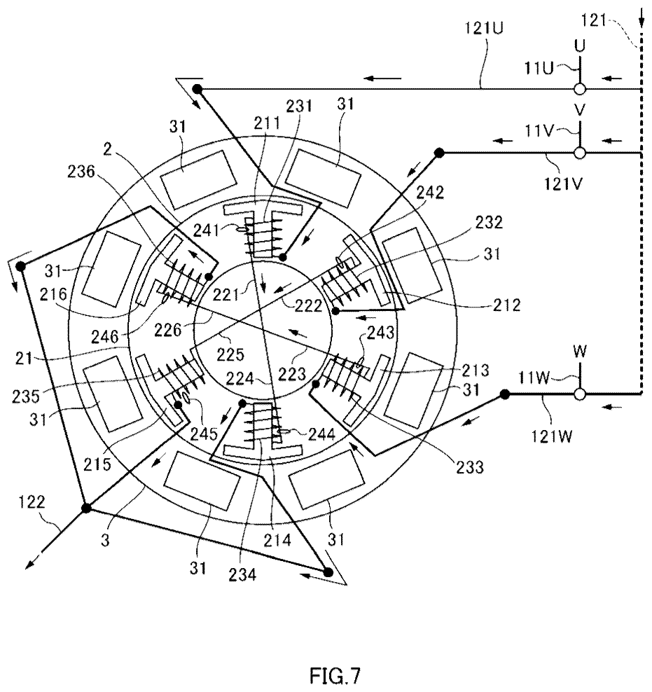

FIG. 7 is a drawing for explaining the flow of the heat carrier in FIG. 2. Note that the arrow marks indicate the flow direction of the heat carrier.

After the heat carrier flows through the heat carrier inlet pipe 121, the heat carrier divides into three flows.

The first flow passes through the U-phase heat carrier inlet pipe 121U, flows through the first hollow conductor wire 221 of the first coil 231, passes through the fourth hollow conductor wire 224 of the fourth coil 234, and flows into the heat carrier outlet pipe 122.

The second flow passes through the V-phase heat carrier inlet pipe 121V, flows through the second hollow conductor wire 222 of the second coil 232, passes through the fifth hollow conductor wire 225 of the fifth coil 235, and flows into the heat carrier outlet pipe 122.

The third flow passes through the W-phase heat carrier inlet pipe 121W, flows through the third hollow conductor wire 223 of the third coil 233, passes through the sixth hollow conductor wire 226 of the sixth coil 236, and flows into the heat carrier outlet pipe 122.

The flow of the heat carrier will be explained below using an exploded diagram.

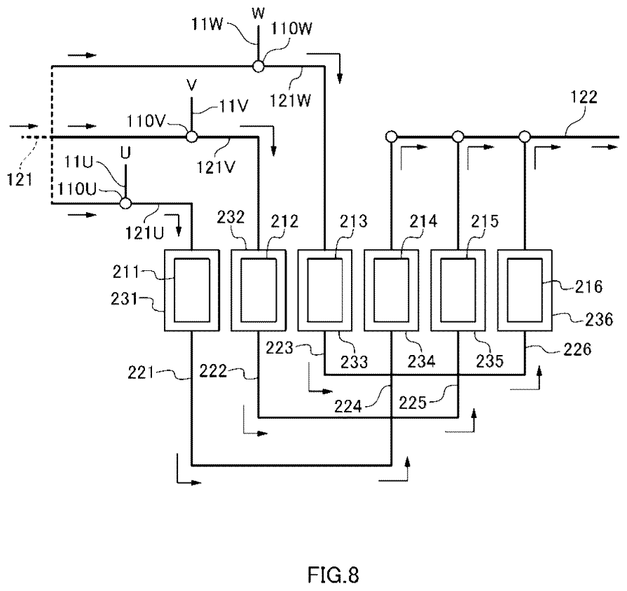

FIG. 8 is a drawing for explaining the flow of the heat carrier using the exploded diagram shown in FIG. 4. Note that the arrow marks indicate the flow direction of the heat carrier.

After the heat carrier flows through the heat carrier inlet pipe 121, the heat carrier divides into three flows.

The first flow passes through the U-phase heat carrier inlet pipe 121U, flows through the first hollow conductor wire 221 of the first coil 231, passes through the fourth hollow conductor wire 224 of the fourth coil 234, and flows into the heat carrier outlet pipe 122.

The second flow passes through the V-phase heat carrier inlet pipe 121V, flows through the second hollow conductor wire 222 of the second coil 232, passes through the fifth hollow conductor wire 225 of the fifth coil 235, and flows into the heat carrier outlet pipe 122.

The third flow passes through the W-phase heat carrier inlet pipe 121W, flows through the third hollow conductor wire 223 of the third coil 233, passes through the sixth hollow conductor wire 226 of the sixth coil 236, and flows into the heat carrier outlet pipe 122.

Then, the flow of the current will be explained.

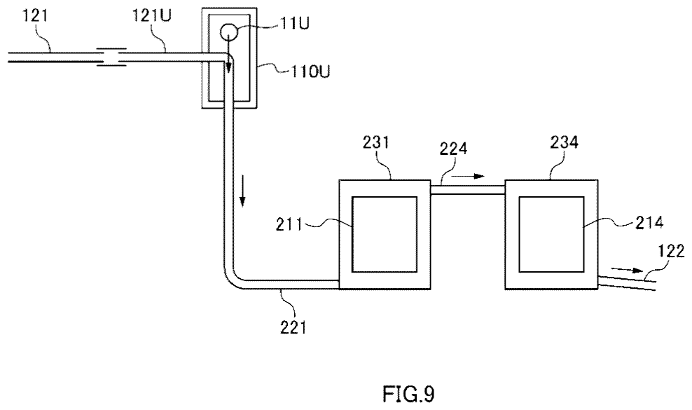

FIG. 9 is a drawing for explaining the flow of the current in FIG. 3B. Note that the arrow marks indicate the flow direction of the current.

After the current flows through the U-phase line 11U, the current flows through the first hollow conductor wire 221 of the first coil 231, passes through the fourth hollow conductor wire 224 of the fourth coil 234, and reaches the heat carrier outlet pipe 122. The flow of the current after reaching the heat carrier outlet pipe 122 will be described later.

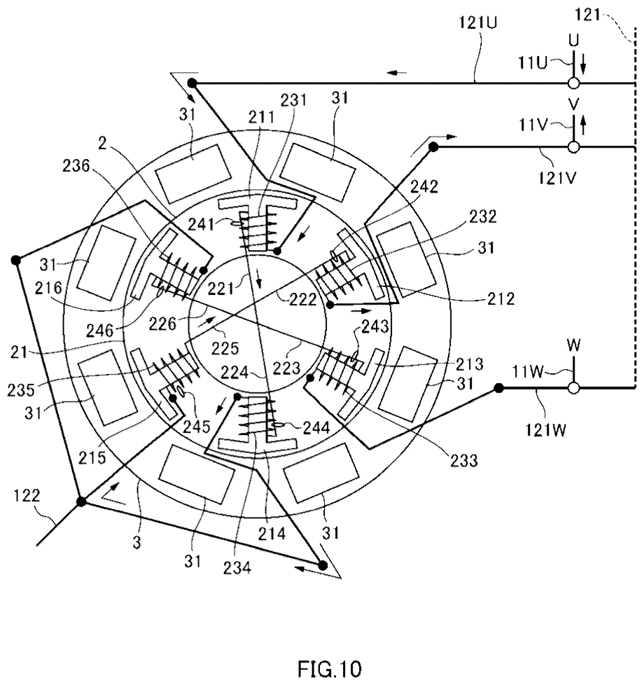

FIG. 10 is a drawing for explaining how the current flows from the U-phase line 11U to the V-phase line 11V in FIG. 2. Note that the arrow marks indicate the flow direction of the current.

The current input from the U-phase line 11U flows in the order of the U-phase heat carrier inlet pipe 121U, the first hollow conductor wire 221, the fourth hollow conductor wire 224, the heat carrier outlet pipe 122, the fifth hollow conductor wire 225, the second hollow conductor wire 222 and the V-phase heat carrier inlet pipe 121V and reaches the V-phase line 11V.

The flow of the above described current will be explained below with reference to the exploded diagram.

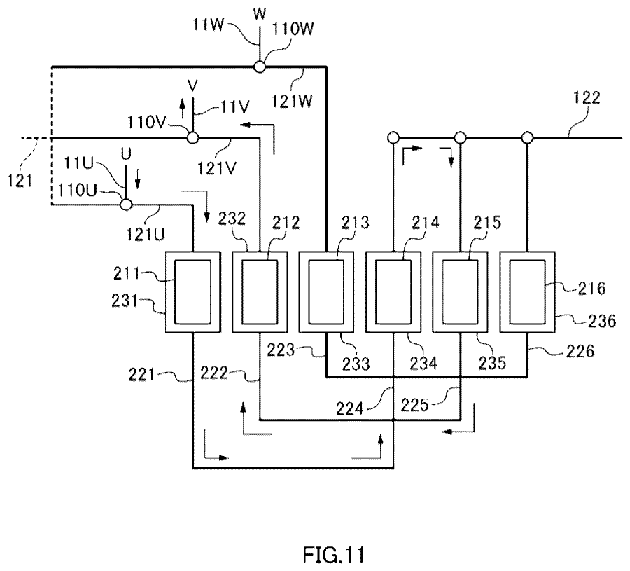

FIG. 11 is a drawing for explaining how the current flows from the U-phase line 11U to the V-phase line 11V with reference to the exploded diagram shown in FIG. 4. Note that the arrow marks indicate the flow direction of the current.

The current input from the U-phase line 11U flows in the order of the U-phase heat carrier inlet pipe 121U, the first hollow conductor wire 221, the fourth hollow conductor wire 224, the heat carrier outlet pipe 122, the fifth hollow conductor wire 225, the second hollow conductor wire 222 and the V-phase heat carrier inlet pipe 121V and reaches the V-phase line 11V.

Each of the coils is formed by winding the hollow conductor wire around each of the slots. Since the heat carrier through the inside of the above described hollow conductor wire, the cooling performance of the rotating electrical machine is excellent. Therefore, the magnets used in the rotor 3 do not need to have high heat resistance specifications. It is possible to keep the cost required for the magnet low. In addition, it becomes also possible to use magnets with high magnetic force but low heat resistance. Thus, it becomes possible to achieve further size reduction and weight reduction in the rotating electrical machine.

As described above, the cooling passage of the hollow conductor is required for both directions in the electric machine of Japanese Unexamined Patent Application Publication No. 2004-135386A. However, there is no need for both directions in the present embodiment. Therefore, when using the same coil configuration as Japanese Unexamined Patent Application Publication No. 2004-135386 (i.e., when using a hollow conductor wire of the same diameter), the length of the flow path of the heat carrier of the heat carrier coils becomes half and the cross-sectional area of the flow path of the heat carrier becomes approximately twice as large. With the same electrical (output) motor performance, when securing a certain amount of heat removal from the coil, the required pump pressure for the same required flow rate of the heat carrier is calculated from Fanning's equation “ΔP=4f*pu\hat{ }2/2*L/d” to be approximately 1/30. Thus, the required power of the pump also becomes approximately 1/30 or less. Consequently, significant downsizing, weight reduction and significant power saving of the pump are enabled.

If compared to the case when securing the same pump pressure, the flow rate of the heat carrier flowing through the hollow conductor wire increases by 7 times or more. When using a hollow conductor of the same diameter, the allowable current of the coil becomes 2.5 times or more. Thus, it is possible to amplify the motor output by nearly 2.5 times.

In addition, since the distance of the heat carrier flowing through the coil becomes shorter, it is possible to equalize and uniformize the temperatures between the heat carrier inlet and the heat carrier outlet of each coil. Thus, the temperature unevenness in the coil less likely to occur.

Furthermore, when the pump pressure is constant, it becomes possible to select the hollow conductor with a thinner diameter. Thus, the freedom of motor design is expanded and miniaturization and weight reduction of the motor size becomes possible if the motor output is the same.

In addition, the rotating electrical machine can be manufactured by forming each coil with the hollow conductor wire and then adding the current lines for each phase. Thus, the productivity is excellent.

Furthermore, since the heat carrier always flows in one direction, the flow resistance is low and the output required for the pump is also low.

Moreover, the structure is simple and the productivity is excellent from the viewpoint that the hollow conductor wire can be easily arranged.

### Second Embodiment

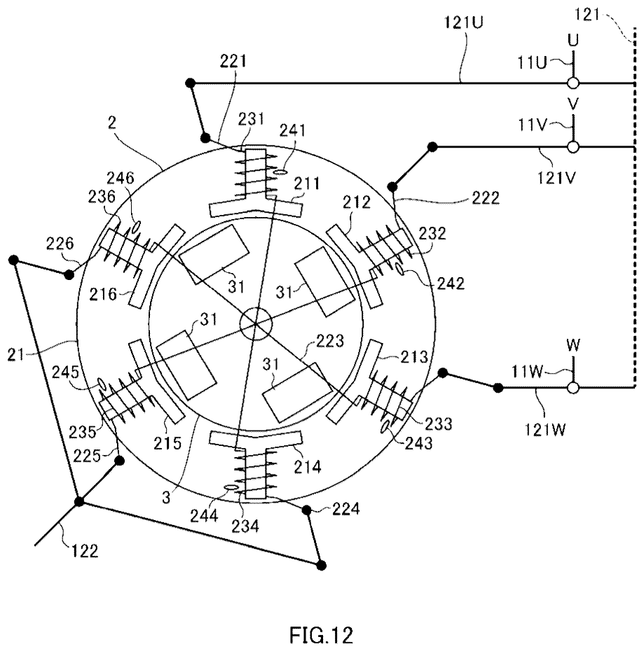

FIG. 12 is a drawing for explaining the second embodiment of the rotating electrical machine.

In the following explanation, the same reference numerals are assigned to the components having the same functions as the components described above and duplicate explanations are omitted appropriately.

The rotating electrical machine of the first embodiment is the outer rotor type with six slots and eight poles (6N8P) where the stator 2 including six slots is arranged on the inner periphery side while the rotor 3 including eight permanent magnets 31 is arranged on the outer periphery side.

On the other hand, the rotating electrical machine of the second embodiment shown in FIG. 12 is an inner rotor type with six slots and four poles (6N4P) where the rotor 3 including four permanent magnets 31 is arranged on the inner circumferential side and the stator 2 including six slots is arranged on the outer circumferential side.

The stator core 21 of the stator 2 is formed with six slots. Specifically, the first slot 211, the second slot 212, the third slot 213, the fourth slot 214, the fifth slot 215 and the sixth slot 216 are formed in the stator core 21. The second slot 212 is positioned next to the first slot 211. The third slot 213 is positioned next to the second slot 212. The fourth slot 214 is positioned next to the third slot 213. The fifth slot 215 is positioned next to the fourth slot 214. The sixth slot 216 is positioned next to the fifth slot 215. The first slot 211 is positioned next to the sixth slot 216.

The configuration of each slot is basically the same as that of the first embodiment. Therefore, the first slot 211 and the fourth slot 214 will be specifically explained here.

The first coil 231 is formed by winding the first hollow conductor wire 221 around the first slot 211. The first hollow conductor wire 221 has a hollow shape so that the heat carrier can flow through the first hollow conductor wire 221. One end (heat carrier inlet) of the first hollow conductor wire 221 is connected to the U-phase heat carrier inlet pipe 121U. The other end (heat carrier outlet) of the first hollow conductor wire 221 is connected to one end (heat carrier inlet) of the fourth hollow conductor wire 224 of the fourth slot 214.

The fourth coil 234 is formed by winding the fourth hollow conductor wire 224 around the fourth slot 214. The fourth hollow conductor wire 224 has a hollow shape so that the heat carrier can flow through the fourth hollow conductor wire 224. One end (heat carrier inlet) of the fourth hollow conductor wire 224 is connected to the other end (heat carrier outlet) of the first hollow conductor wire 221. The other end (heat carrier outlet) of the fourth hollow conductor wire 224 is connected to the heat carrier outlet pipe 122.

As described above, the configurations of the first slot 211 and the fourth slot 214 are the same as those of the first embodiment. Since the other slots are also the same as those of the first embodiment, a detailed explanation is omitted.

Even when the above described inner rotor type is used, it is possible to achieve the same operations and effects as those of the first embodiment. Namely, since the heat carrier flows through the inside of the hollow conductor wire, excellent cooling performance is achieved for the rotating electrical machine (electrical energy-mechanical energy converter). In addition, further miniaturization and weight reduction of the rotating electrical machine can be achieved and productivity is also excellent.

### Third Embodiment

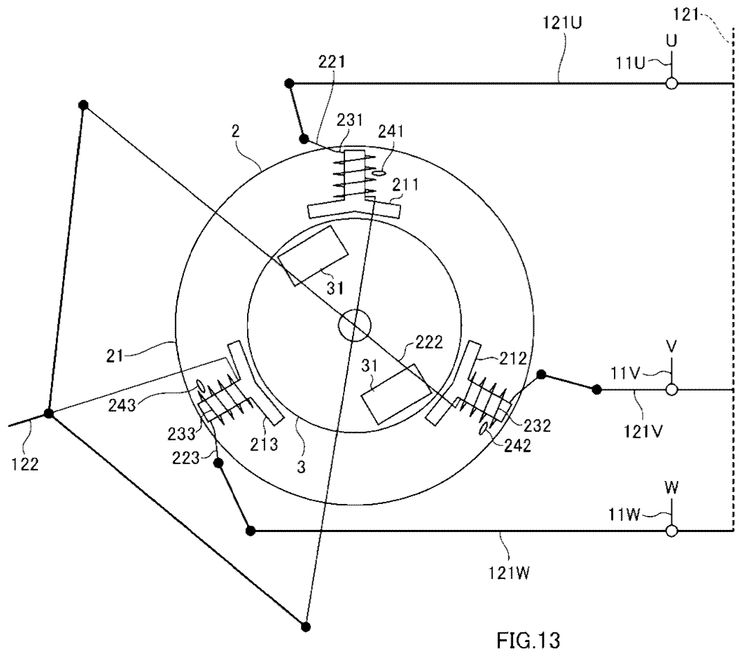

FIG. 13 is a drawing for explaining the third embodiment of the rotating electrical machine.

The rotating electrical machine of the second embodiment is the inner rotor type with six slots and four poles (6N4P) where the rotor 3 including four permanent magnets 31 is arranged on the inner circumferential side and the stator 2 including six slots is arranged on the outer circumferential side.

On the other hand, the rotating electrical machine of the third embodiment shown in FIG. 13 is an inner rotor type with three slots and two poles (3N2P) where the rotor 3 including two permanent magnets 31 is arranged on the inner circumferential side and the stator 2 including three slots is arranged on the outer circumferential side.

The first coil 231 is formed by winding the first hollow conductor wire 221 around the first slot 211. The first hollow conductor wire 221 has a hollow shape so that the heat carrier can flow through the first hollow conductor wire 221. One end (heat carrier inlet) of the first hollow conductor wire 221 is connected to the U-phase heat carrier inlet pipe 121U. The other end (heat carrier outlet) of the first hollow conductor wire 221 is connected to the heat carrier outlet pipe 122.

The second coil 232 is formed by winding the second hollow conductor wire 222 around the second slot 212. The second hollow conductor wire 222 has a hollow shape so that the heat carrier can flow through the second hollow conductor wire 222. One end (heat carrier inlet) of the second hollow conductor wire 222 is connected to the V-phase heat carrier inlet pipe 121V. The other end (heat carrier outlet) of the second hollow conductor wire 222 is connected to the heat carrier outlet pipe 122.

The third coil 233 is formed by winding the third hollow conductor wire 223 around the third slot 213. The third hollow conductor wire 223 has a hollow shape so that the heat carrier can flow through the third hollow conductor wire 223. One end (heat carrier inlet) of the third hollow conductor wire 223 is connected to the W-phase heat carrier inlet pipe 121W. The other end (heat carrier outlet) of the third hollow conductor wire 223 is connected to the heat carrier outlet pipe 122.

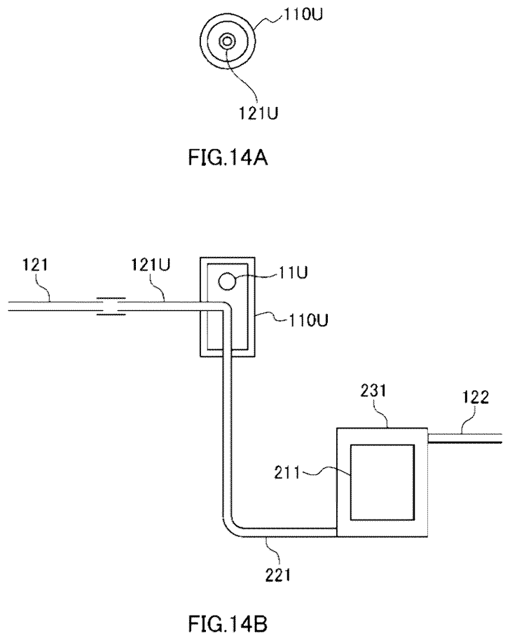

FIGS. 14A and 14B are drawings for explaining the U-phase connection portion. FIG. 14A is a planar cross-sectional view of the U-phase connection portion 110U. FIG. 14B is a simplified drawing of the vicinity of the U-phase connection portion.

The U-phase heat carrier inlet pipe 121U is connected to the U-phase line 11U via the U-phase connection portion 110U. The U-phase heat carrier inlet pipe 121U is connected to one end (heat carrier inlet) of the first hollow conductor wire 221 of the first slot 211. The other end (heat carrier outlet) of the first hollow conductor wire 221 is connected to the heat carrier outlet pipe 122.

Although the U-phase connection portion is explained in FIGS. 14A and 14B, the explanation of the V-phase connection portion and the W-phase connection portion is omitted since the configuration is the same.

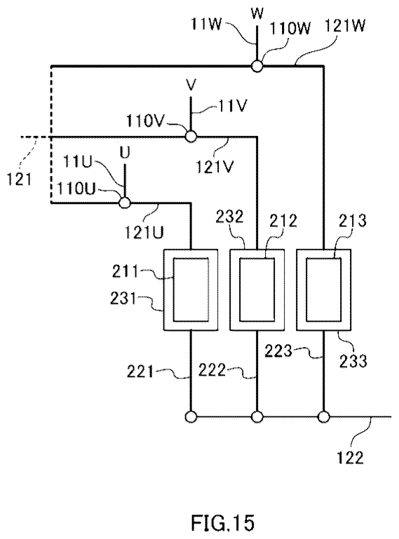

FIG. 15 is a drawing simply showing a configuration of the coil in FIG. 13.

The heat carrier inlet pipe 121 is branched into three paths on the downstream side of the heat carrier. One of the three paths is connected to the U-phase heat carrier inlet pipe 121U, another of the three paths is connected to the V-phase heat carrier inlet pipe 121V, and the other one of the three paths is connected to the W-phase heat carrier inlet pipe 121W.

The U-phase heat carrier inlet pipe 121U is continued to one end (heat carrier inlet) of the first hollow conductor wire 221 of the first coil 231 formed in the first slot 211. The other end (heat carrier outlet) of the first hollow conductor wire 221 is continued to the heat carrier outlet pipe 122.

In addition, the V-phase heat carrier inlet pipe 121V is continued to one end (heat carrier inlet) of the second hollow conductor wire 222 of the second coil 232 formed in the second slot 212. The other end (heat carrier outlet) of the second hollow conductor wire 222 is continued to the heat carrier outlet pipe 122.

Furthermore, the W-phase heat carrier inlet pipe 121W is continued to one end (heat carrier inlet) of the third hollow conductor wire 223 of the third coil 233 formed in the third slot 213. The other end (heat carrier outlet) of the third hollow conductor wire 223 is continued to the heat carrier outlet pipe 122.

Then, the flow of the heat carrier will be explained.

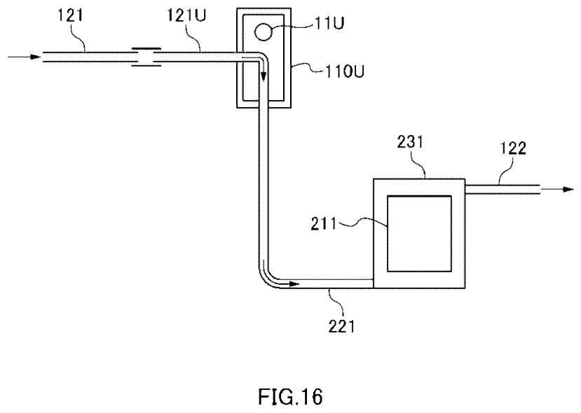

FIG. 16 is a drawing for explaining the flow of the heat carrier in FIG. 14B. Note that the arrow marks indicate the flow direction of the heat carrier.

As shown by the arrow marks, after the heat carrier flows through the heat carrier inlet pipe 121, the heat carrier branches into the U-phase heat carrier inlet pipe 121U, passes through the first hollow conductor wire 221 of the first coil 231 and flows into the heat carrier outlet pipe 122.

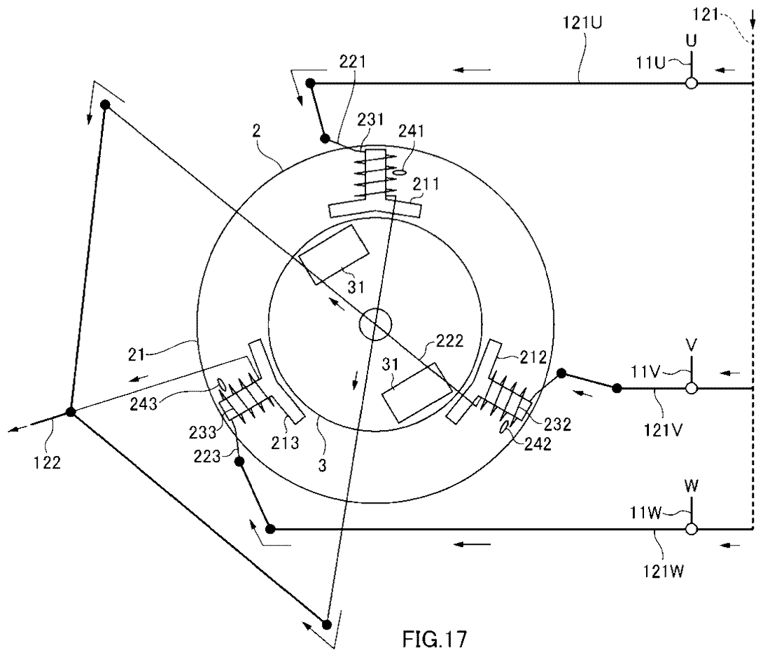

FIG. 17 is a drawing for explaining the flow of the heat carrier in FIG. 13. Note that the arrow marks indicate the flow direction of the heat carrier.

After the heat carrier flows through the heat carrier inlet pipe 121, the heat carrier divides into three flows.

The first flow passes through the U-phase heat carrier inlet pipe 121U, flows through the first hollow conductor wire 221 of the first coil 231, and flows into the heat carrier outlet pipe 122.

The second flow passes through the V-phase heat carrier inlet pipe 121V, flows through the second hollow conductor wire 222 of the second coil 232, and flows into the heat carrier outlet pipe 122.

The third flow passes through the W-phase heat carrier inlet pipe 121W, flows through the third hollow conductor wire 223 of the third coil 233, and flows into the heat carrier outlet pipe 122.

The flow of the heat carrier will be explained below using an exploded diagram.

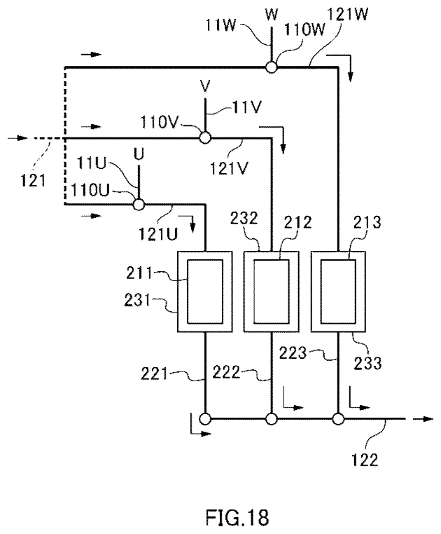

FIG. 18 is a drawing for explaining the flow of the heat carrier using the exploded diagram shown in FIG. 15. Note that the arrow marks indicate the flow direction of the heat carrier.

After the heat carrier flows through the heat carrier inlet pipe 121, the heat carrier divides into three flows.

The first flow passes through the U-phase heat carrier inlet pipe 121U, flows through the first hollow conductor wire 221 of the first coil 231, and flows into the heat carrier outlet pipe 122.

The second flow passes through the V-phase heat carrier inlet pipe 121V, flows through the second hollow conductor wire 222 of the second coil 232, and flows into the heat carrier outlet pipe 122.

The third flow passes through the W-phase heat carrier inlet pipe 121W, flows through the third hollow conductor wire 223 of the third coil 233, and flows into the heat carrier outlet pipe 122.

Then, the flow of the current will be explained.

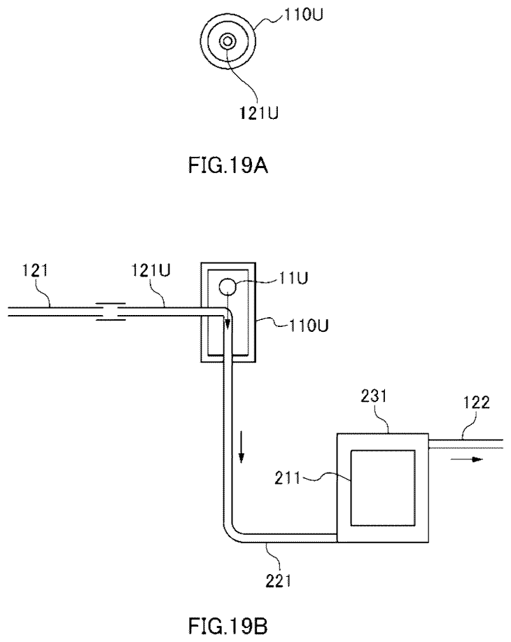

FIGS. 19A and 19B are drawings for explaining the flow of the current in FIGS. 14A and 14B. Note that the arrow marks indicate the flow direction of the current.

After the current flows through the U-phase line 11U, the current flows through the first hollow conductor wire 221 of the first coil 231 and reaches the heat carrier outlet pipe 122. The flow of the current after reaching the heat carrier outlet pipe 122 will be described later.

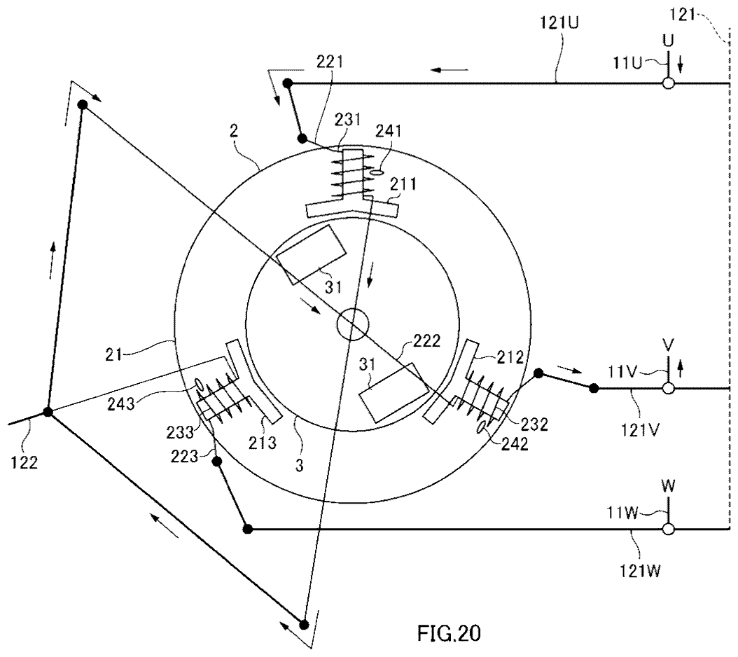

FIG. 20 is a drawing for explaining how the current flows from the U-phase line 11U to the V-phase line 11V in FIG. 13. Note that the arrow marks indicate the flow direction of the current.

The current input from the U-phase line 11U flows in the order of the first hollow conductor wire 221, the heat carrier outlet pipe 122 and the second hollow conductor wire 222 and reaches the V-phase line 11V.

The flow of the above described current will be explained below with reference to the exploded diagram.

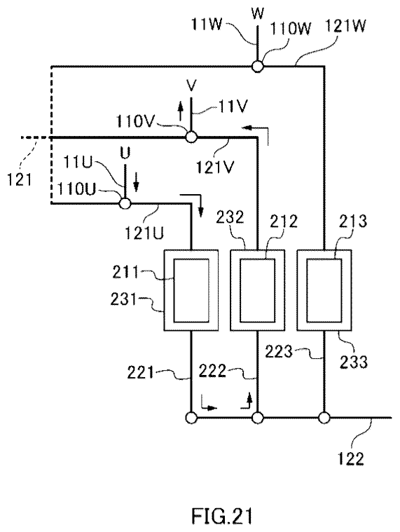

FIG. 21 is a drawing for explaining how the current flows from the U-phase line 11U to the V-phase line 11V with reference to the exploded diagram shown in FIG. 15. Note that the arrow marks indicate the flow direction of the current.

The current input from the U-phase line 11U flows in the order of the first hollow conductor wire 221, the heat carrier outlet pipe 122 and the second hollow conductor wire 222 and reaches the V-phase line 11V.

Even when the above described configuration is used, it is possible to achieve the same operations and effects as those of the first embodiment. Namely, since the heat carrier flows through the inside of the above described hollow conductor wire, excellent cooling performance is achieved for the rotating electrical machine (electrical energy-mechanical energy converter). In addition, further miniaturization and weight reduction of the rotating electrical machine can be achieved and productivity is also excellent.

### Fourth Embodiment

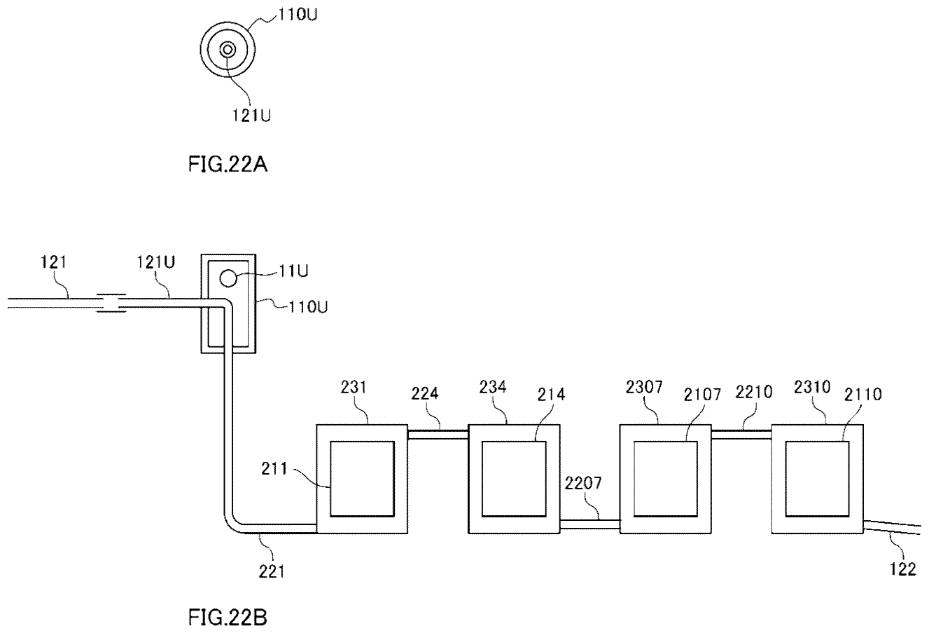

FIGS. 22A and 22B are the drawings showing the fourth embodiment of the rotating electrical machine.

In the rotating electrical machine of the first embodiment and the second embodiment, the stator 2 having six slots is arranged. As for the U-phase connection portion, as shown in FIGS. 3A and 3B, the U-phase heat carrier inlet pipe 121U, the first slot 211 (first hollow conductor wire 221), the fourth slot 214 (fourth hollow conductor wire 224) and the heat carrier outlet pipe 122 are arranged in series.

On the other hand, in the rotating electrical machine of the fourth embodiment, as for the U-phase connection portion, as shown in FIGS. 22A and 22B, the U-phase heat carrier inlet pipe 121U, the first slot 211, (first hollow conductor wire 221), the fourth slot 214 (fourth hollow conductor wire 224), the seventh slot 2107 (first hollow conductor wire 2207), the tenth slot 2110 (tenth hollow conductor wire 2210) and the heat carrier outlet pipe 122 are arranged in series.

Although the U-phase connection portion is explained in FIGS. 22A and 22B, the explanation of the V-phase connection portion and the W-phase connection portion is omitted since the configuration is the same.

As apparent from the comparison between FIGS. 22A and 22B and FIGS. 3A and 3B, the configuration of FIGS. 22A and 22B is formed by preparing two pairs of the configuration shown in FIGS. 3A and 3B and connecting them in series.

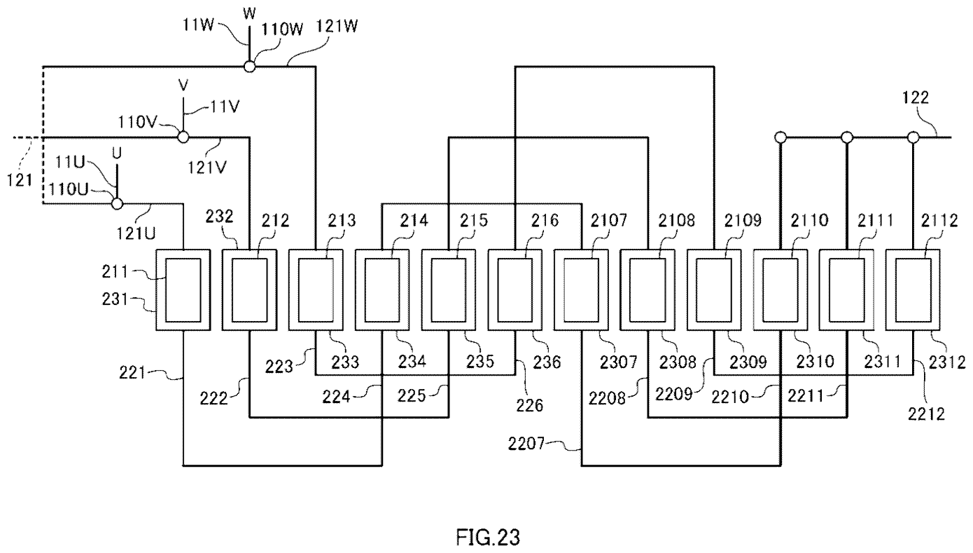

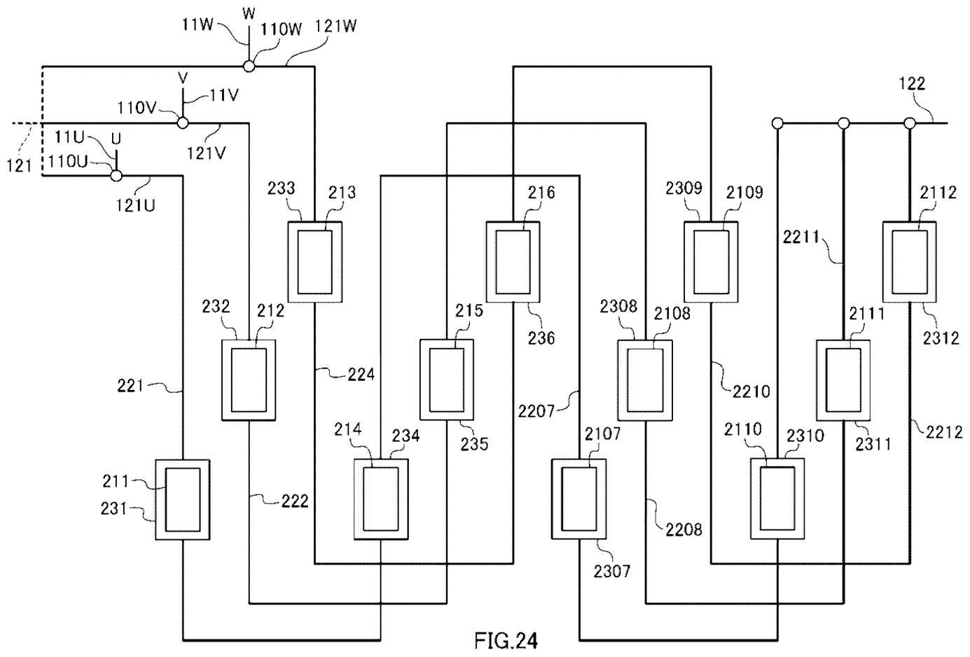

FIG. 23 is a drawing simply showing the configuration of the coil of the fourth embodiment. FIG. 24 is a drawing showing the configuration diagram of FIG. 23 divided vertically into U-phase, V-phase and W-phase to facilitate understanding of FIG. 23.

The heat carrier inlet pipe 121 is branched into three paths on the downstream side of the heat carrier. One of the three paths is connected to the U-phase heat carrier inlet pipe 121U, another of the three paths is connected to the V-phase heat carrier inlet pipe 121V, and the other one of the three paths is connected to the W-phase heat carrier inlet pipe 121W.

The U-phase heat carrier inlet pipe 121U is continued to one end (heat carrier inlet) of the first hollow conductor wire 221 of the first coil 231 formed in the first slot 211. The other end (heat carrier outlet) of the first hollow conductor wire 221 is continued to one end (heat carrier inlet) of the fourth hollow conductor wire 224 of the fourth coil 234 formed in the fourth slot 214. The other end (heat carrier outlet) of the fourth hollow conductor wire 224 is continued to one end (heat carrier inlet) of the seventh hollow conductor wire 2207 of the seventh coil 2307 formed in the seventh slot 2107. The other end (heat carrier outlet) of the seventh hollow conductor wire 2207 is continued to one end (heat carrier inlet) of the tenth hollow conductor wire 2210 of the tenth coil 2310 formed in the tenth slot 2110. The other end (heat carrier outlet) of the tenth hollow conductor wire 2210 is continued to the heat carrier outlet pipe 122.

In addition, the V-phase heat carrier inlet pipe 121V is continued to one end (heat carrier inlet) of the second hollow conductor wire 222 of the second coil 232 formed in the second slot 212. The other end (heat carrier outlet) of the second hollow conductor wire 222 is continued to one end (heat carrier inlet) of the fifth hollow conductor wire 225 of the fifth coil 235 formed in the fifth slot 215. The other end (heat carrier outlet) of the fifth hollow conductor wire 225 is continued to one end (heat carrier inlet) of the eighth hollow conductor wire 2208 of the eighth coil 2308 formed in the eighth slot 2108. The other end (heat carrier outlet) of the eighth hollow conductor wire 2208 is continued to one end (heat carrier inlet) of the eleventh hollow conductor wire 2211 of the eleventh coil 2311 formed in the eleventh slot 2111. The other end (heat carrier outlet) of the eleventh hollow conductor wire 2211 is continued to the heat carrier outlet pipe 122.

Furthermore, the W-phase heat carrier inlet pipe 121W is continued to one end (heat carrier inlet) of the third hollow conductor wire 223 of the third coil 233 formed in the third slot 213. The other end (heat carrier outlet) of the third hollow conductor wire 223 is continued to one end (heat carrier inlet) of the sixth hollow conductor wire 226 of the sixth coil 236 formed in the sixth slot 216. The other end (heat carrier outlet) of the sixth hollow conductor wire 226 is continued to one end (heat carrier inlet) of the ninth hollow conductor wire 2209 of the ninth coil 2309 formed in the ninth slot 2109. The other end (heat carrier outlet) of the ninth hollow conductor wire 2209 is continued to one end (heat carrier inlet) of the twelfth hollow conductor wire 2212 of the twelfth coil 2312 formed in the twelfth slot 2112. The other end (heat carrier outlet) of the twelfth hollow conductor wire 2212 is continued to the heat carrier outlet pipe 122.

As apparent from the comparison between FIG. 23 and FIG. 4, the configuration of FIG. 23 is formed by preparing two pairs of the configuration shown in FIG. 4 and connecting them in series.

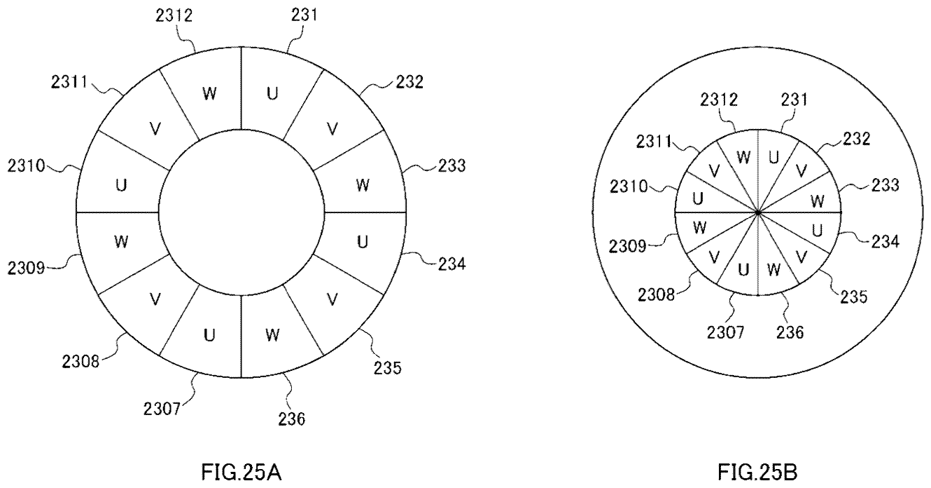

FIGS. 25A and 25B are drawings showing an example of the arrangement of the coils.

Although each of the coils is shown in a state of being exploded and arranged horizontally in a single line in FIG. 23 in order to show the configuration simply, the coils are arranged in the order as shown in FIG. 25A for the rotating electrical machine of the inner rotor type with twelve slots and eight poles (12N8P). Namely, the second coil 232, which is the V-phase coil, is positioned next to the first coil 231, which is the U-phase coil, in the clockwise direction. The third coil 233, which is the W-phase coil, is positioned next to the second coil 232. The fourth coil 234, which is the U-phase coil, is positioned next to the third coil 233. The fifth coil 235, which is the V-phase coil, is positioned next to the fourth coil 234. The sixth coil 236, which is the W-phase coil, is positioned next to the fifth coil 235. The seventh coil 2307, which is the U-phase coil, is positioned next to the sixth coil 236. The eighth coil 2308, which is the V-phase coil, is positioned next to the seventh coil 2307. The ninth coil 2309, which is the W-phase coil, is positioned next to the eighth coil 2308. The tenth coil 2310, which is the U-phase coil, is positioned next to the ninth coil 2309. The eleventh coil 2311, which is the V-phase coil, is positioned next to the tenth coil 2310. The twelfth coil 2312, which is the W-phase coil, is positioned next to the eleventh coil 2311.

In addition, even for the rotating electrical machine of the outer rotor type with twelve slots and eight poles (12N8P), the slots are arranged as shown in FIG. 25B which is the same order as shown in FIG. 25A.

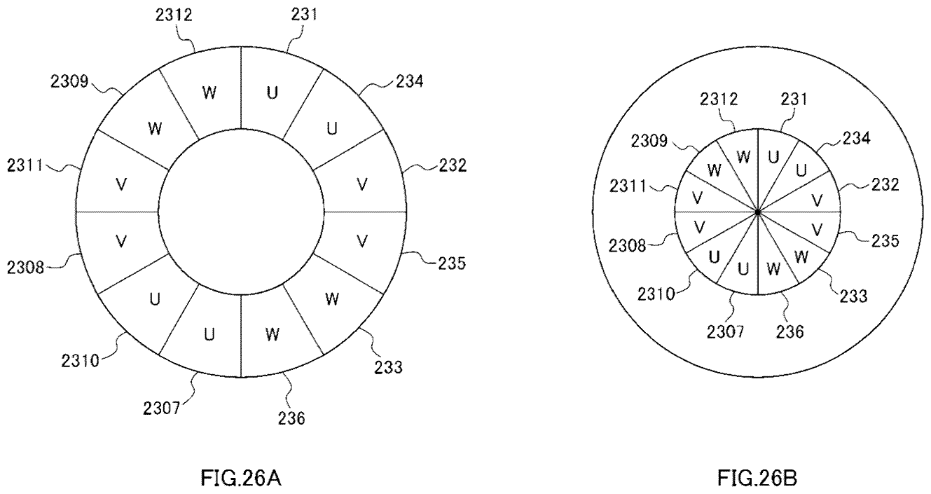

FIGS. 26A and 26B are drawings showing another example of the arrangement of the coils.

For the rotating electrical machine of the inner rotor type with twelve slots and fourteen poles (12N14P), the coils are arranged in the order shown in FIG. 26A. Namely, the fourth coil 234, which is the U-phase coil, is positioned next to the first coil 231, which is the U-phase coil, in the clockwise direction. The second coil 232, which is the V-phase coil, is positioned next to the fourth coil 234. The fifth coil 235, which is the V-phase coil, is positioned next to the second coil 232. The third coil 233, which is the W-phase coil, is positioned next to the fifth coil 235. The sixth coil 236, which is the W-phase coil, is positioned next to the third coil 233. The seventh coil 2307, which is the U-phase coil, is positioned next to the sixth coil 236. The tenth coil 2310, which is the U-phase coil, is positioned next to the seventh coil 2307. The eighth coil 2308, which is the V-phase coil, is positioned next to the tenth coil 2310. The eleventh coil 2311, which is the V-phase coil, is positioned next to the eighth coil 2308. The ninth coil 2309, which is the W-phase coil, is positioned next to the eleventh coil 2311. The twelfth coil 2312, which is the W-phase coil, is positioned next to the ninth coil 2309.

For the rotating electrical machine of the outer rotor type with twelve slots and fourteen poles (12N14P), the coils are arranged as shown in FIG. 25B which is the same order as shown in FIG. 26A.

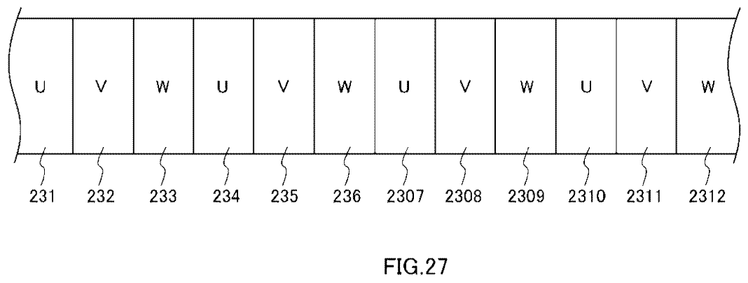

FIG. 27 is a drawing showing another example of the arrangement of the coils.

When the electrical energy-mechanical energy converter is a linear motor, the coils are arranged in the order shown in FIG. 27. Namely, the second coil 232, which is the V-phase coil, is positioned next to the first coil 231, which is the U-phase coil. The third coil 233, which is the W-phase coil, is positioned next to the second coil 232. The fourth coil 234, which is the U-phase coil, is positioned next to the third coil 233. The fifth coil 235, which is the V-phase coil, is positioned next to the fourth coil 234. The sixth coil 236, which is the W-phase coil, is positioned next to the fifth coil 235. The seventh coil 2307, which is the U-phase coil, is positioned next to the sixth coil 236. The eighth coil 2308, which is the V-phase coil, is positioned next to the seventh coil 2307. The ninth coil 2309, which is the W-phase coil, is positioned next to the eighth coil 2308. The tenth coil 2310, which is the U-phase coil, is positioned next to the ninth coil 2309. The eleventh coil 2311, which is the V-phase coil, is positioned next to the tenth coil 2310. The twelfth coil 2312, which is the W-phase coil, is positioned next to the eleventh coil 2311.

By employing the above described configuration, it is possible to achieve the rotating electrical machine where the stator 2 with twelve slots is arranged.

As apparent from the comparison between FIGS. 3A and 3B (six slots) and FIGS. 22A and 22B (twelve slots), the number of the slots can be increased by connecting necessary pairs of the configurations of FIGS. 3A and 3B in series. For example, eighteen slots can be achieved by connecting three pairs of the configurations of FIGS. 3A and 3B in series. Twenty four slots can be achieved by connecting four pairs of the configurations of FIGS. 3A and 3B in series.

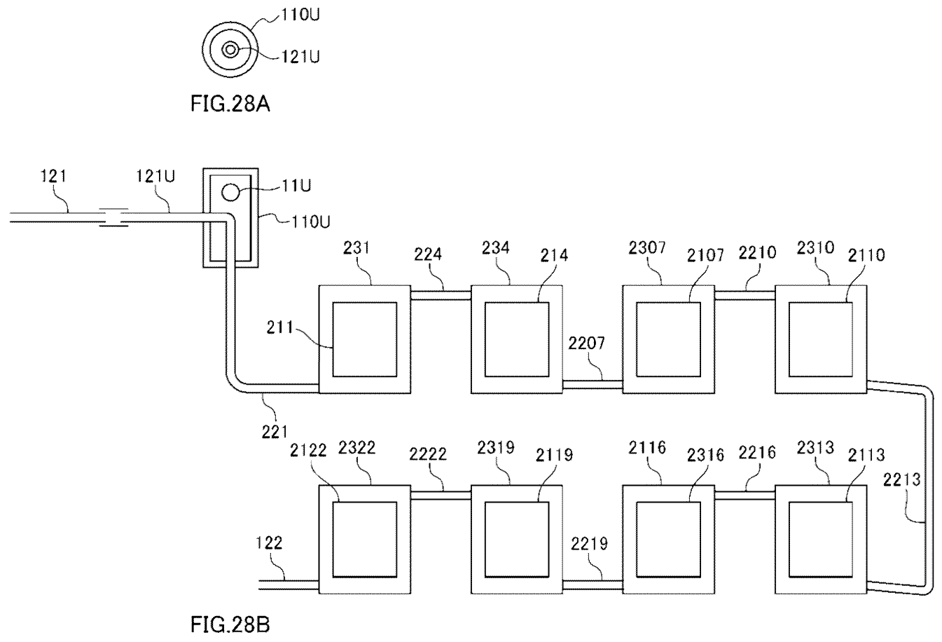

Namely, twenty four slots can be achieved by connecting the U-phase heat carrier inlet pipe 121U, the first slot 211 (first hollow conductor wire 221), the fourth slot 214 (fourth hollow conductor wire 224), the seventh slot 2107 (seventh hollow conductor wire 2207), the tenth slot 2110 (tenth hollow conductor wire 2210), the thirteenth slot 2113 (thirteenth hollow conductor wire 2213), the sixteenth slot 2116 (sixteenth hollow conductor wire 2216), nineteenth slot 2119 (nineteenth hollow conductor wire 2219), the twenty second slot 2122 (twenty second hollow conductor wire 2222) and the heat carrier outlet pipe 122 in series as the U-phase connection portion is shown in FIGS. 28A and 28B.

Although the U-phase connection portion is explained in FIGS. 28A and 28B, the explanation of the V-phase connection portion and the W-phase connection portion is omitted since the configuration is the same.

By employing the above described configuration, it is possible to achieve the rotating electrical machine where the stator 2 with twenty four slots is arranged.

### Fifth Embodiment

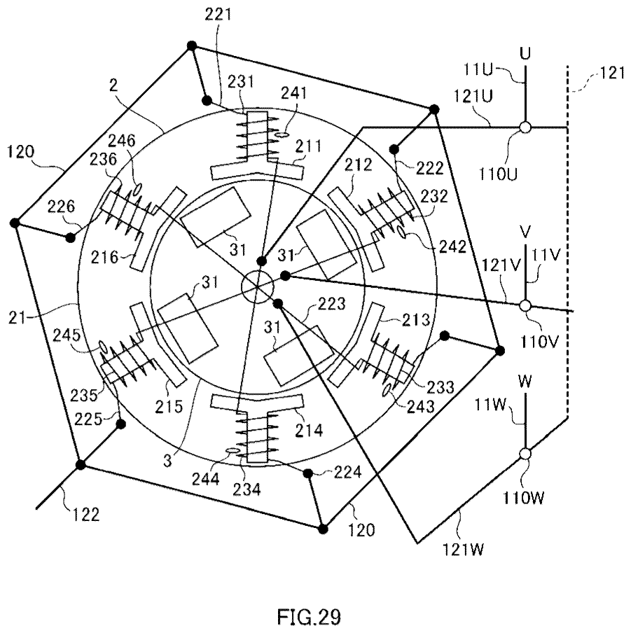

FIG. 29 is a drawing showing the fifth embodiment of the rotating electrical machine.

The rotating electrical machine of the second embodiment shown in FIG. 12 is the inner rotor type with six slots and four poles (6N4P) where the rotor 3 including four permanent magnets 31 is arranged on the inner circumferential side and the stator 2 including six slots is arranged on the outer circumferential side. As for the U-phase connection portion, the U-phase heat carrier inlet pipe 121U, the first slot 211 (first hollow conductor wire 221), the fourth slot 214 (fourth hollow conductor wire 224) and the heat carrier outlet pipe 122 are arranged in series.

On the other hand, the rotating electrical machine of the fifth embodiment shown in FIG. 29 is the same as the second embodiment about the configuration that the inner rotor type with six slots and four poles (6N4P) where the rotor 3 including four permanent magnets 31 is arranged on the inner circumferential side and the stator 2 including six slots is arranged on the outer circumferential side. However, as for the U-phase connection portion, the U-phase heat carrier inlet pipe 121U is branched into the first slot 211 (first hollow conductor wire 221) and the fourth slot 214 (fourth hollow conductor wire 224) in parallel. The specific configuration will be explained below.

The stator core 21 of the stator 2 is formed with six slots. Specifically, the first slot 211, the second slot 212, the third slot 213, the fourth slot 214, the fifth slot 215 and the sixth slot 216 are formed in the stator core 21. The second slot 212 is positioned next to the first slot 211. The third slot 213 is positioned next to the second slot 212. The fourth slot 214 is positioned next to the third slot 213. The fifth slot 215 is positioned next to the fourth slot 214. The sixth slot 216 is positioned next to the fifth slot 215. The first slot 211 is positioned next to the sixth slot 216.

The first coil 231 is formed by winding the first hollow conductor wire 221 around the first slot 211. One end (heat carrier inlet) of the first hollow conductor wire 221 is connected to the U-phase heat carrier inlet pipe 121U. The other end (heat carrier outlet) of the first hollow conductor wire 221 is connected to the heat carrier outlet pipe 122.

The second coil 232 is formed by winding the second hollow conductor wire 222 around the second slot 212. One end (heat carrier inlet) of the second hollow conductor wire 222 is connected to the V-phase heat carrier inlet pipe 121V. The other end (heat carrier outlet) of the second hollow conductor wire 222 is connected to the heat carrier outlet pipe 122.

The third coil 233 is formed by winding the third hollow conductor wire 223 around the third slot 213. One end (heat carrier inlet) of the third hollow conductor wire 223 is connected to the W-phase heat carrier inlet pipe 121W. The other end (heat carrier outlet) of the third hollow conductor wire 223 is connected to the heat carrier outlet pipe 122.

The fourth coil 234 is formed by winding the fourth hollow conductor wire 224 around the fourth slot 214. One end (heat carrier inlet) of the fourth hollow conductor wire 224 is connected to the U-phase heat carrier inlet pipe 121U. The other end (heat carrier outlet) of the fourth hollow conductor wire 224 is connected to the heat carrier outlet pipe 122.

The fifth coil 235 is formed by winding the fifth hollow conductor wire 225 around the fifth slot 215. One end (heat carrier inlet) of the fifth hollow conductor wire 225 is connected to the V-phase heat carrier inlet pipe 121V. The other end (heat carrier outlet) of the fifth hollow conductor wire 225 is connected to the heat carrier outlet pipe 122.

The sixth coil 236 is formed by winding the sixth hollow conductor wire 226 around the sixth slot 216. One end (heat carrier inlet) of the sixth hollow conductor wire 226 is connected to the W-phase heat carrier inlet pipe 121W. The other end (heat carrier outlet) of the sixth hollow conductor wire 226 is connected to the heat carrier outlet pipe 122.

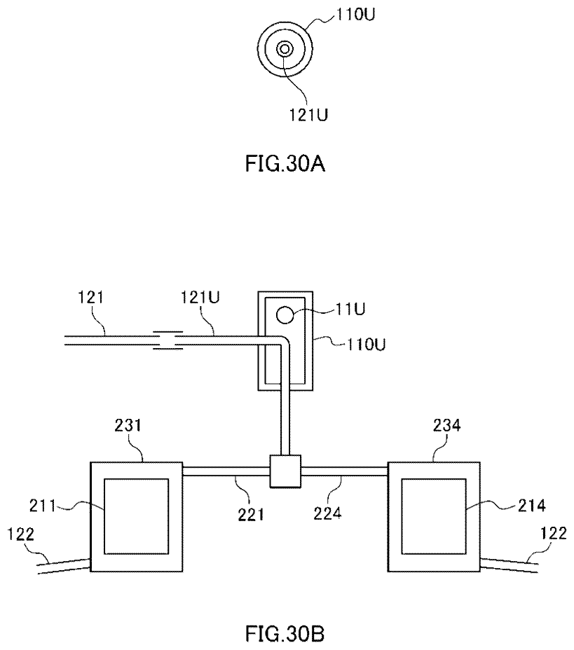

FIGS. 30A and 30B are drawings for explaining the U-phase connection portion. FIG. 30A is a planar cross-sectional view of the U-phase connection portion 110U. FIG. 30B is a simplified drawing of the vicinity of the U-phase connection portion.

The U-phase heat carrier inlet pipe 121U is connected to the U-phase line 11U via the U-phase connection portion 110U. The U-phase heat carrier inlet pipe 121U is branched into two. One of the branched pipes is connected to one end (heat carrier inlet) of the first hollow conductor wire 221 of the first slot 211. The other end (heat carrier outlet) of the first hollow conductor wire 221 is connected to the heat carrier outlet pipe 122. In addition, another of branched U-phase heat carrier inlet pipe 121U is connected to one end (heat carrier inlet) of the fourth hollow conductor wire 224 of the fourth slot 214. The other end (heat carrier outlet) of the fourth hollow conductor wire 224 is connected to the heat carrier outlet pipe 122. As described above, the first slot 211 (first hollow conductor wire 221) and the fourth slot 214 (fourth hollow conductor wire 224) are arranged in parallel.

Although the U-phase connection portion is explained in FIGS. 30A and 30B, the explanation of the V-phase connection portion and the W-phase connection portion is omitted since the configuration is the same.

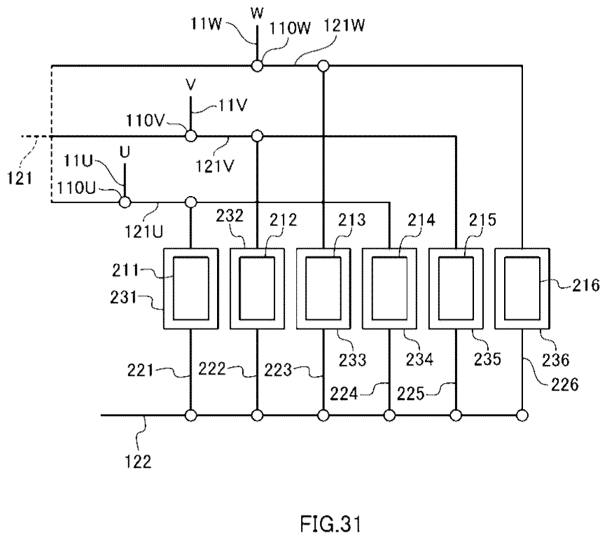

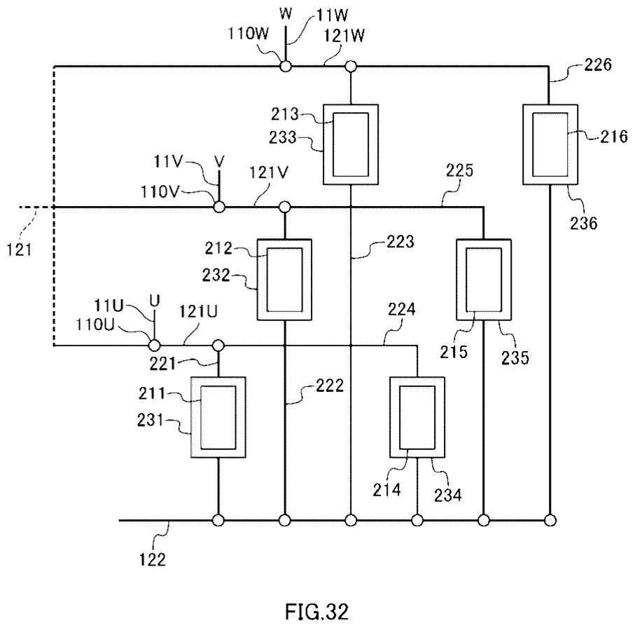

FIG. 31 is a drawing simply showing the configuration of the coil in FIG. 29. FIG. 32 is a drawing showing the configuration diagram of FIG. 31 divided vertically into U-phase, V-phase and W-phase to facilitate understanding of FIG. 31.

The heat carrier inlet pipe 121 is branched into three paths on the downstream side of the heat carrier. One of the three paths is connected to the U-phase heat carrier inlet pipe 121U, another of the three paths is connected to the V-phase heat carrier inlet pipe 121V, and the other one of the three paths is connected to the W-phase heat carrier inlet pipe 121W.

The U-phase heat carrier inlet pipe 121U is continued to one end (heat carrier inlet) of the first hollow conductor wire 221 of the first coil 231 formed in the first slot 211 and continued to one end (heat carrier inlet) of the fourth hollow conductor wire 224 of the fourth coil 234 formed in the fourth slot 214. The other end (heat carrier outlet) of the first hollow conductor wire 221 is continued to the heat carrier outlet pipe 122. The other end (heat carrier outlet) of the fourth hollow conductor wire 224 is also continued to the heat carrier outlet pipe 122.

In addition, the V-phase heat carrier inlet pipe 121V is continued to one end (heat carrier inlet) of the second hollow conductor wire 222 of the second coil 232 formed in the second slot 212 and continued to one end (heat carrier inlet) of the fifth hollow conductor wire 225 of the fifth coil 235 formed in the fifth slot 215. The other end (heat carrier outlet) of the second hollow conductor wire 222 is continued to the heat carrier outlet pipe 122. The other end (heat carrier outlet) of the fifth hollow conductor wire 225 is also continued to the heat carrier outlet pipe 122.

Furthermore, the W-phase heat carrier inlet pipe 121W is continued to one end (heat carrier inlet) of the third hollow conductor wire 223 of the third coil 233 formed in the third slot 213 and continued to one end (heat carrier inlet) of the sixth hollow conductor wire 226 of the sixth coil 236 formed in the sixth slot 216. The other end (heat carrier outlet) of the third hollow conductor wire 223 is continued to the heat carrier outlet pipe 122. The other end (heat carrier outlet) of the sixth hollow conductor wire 226 is also continued to the heat carrier outlet pipe 122.

Then, the flow of the heat carrier will be explained.

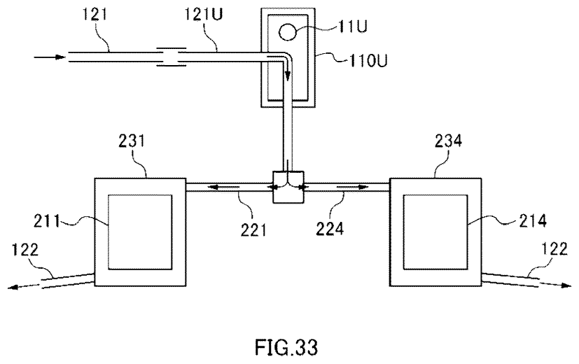

FIG. 33 is a drawing for explaining the flow of the heat carrier in FIG. 30B. Note that the arrow marks indicate the flow direction of the heat carrier.

As shown by the arrow marks, after the heat carrier flows from the heat carrier inlet pipe 121 to the U-phase heat carrier inlet pipe 121U, the heat carrier divides into two. One of them passes through the first hollow conductor wire 221 of the first coil 231 and flows into the heat carrier outlet pipe 122. The other of them passes through the fourth hollow conductor wire 224 of the fourth coil 234 and flows into the heat carrier outlet pipe 122.

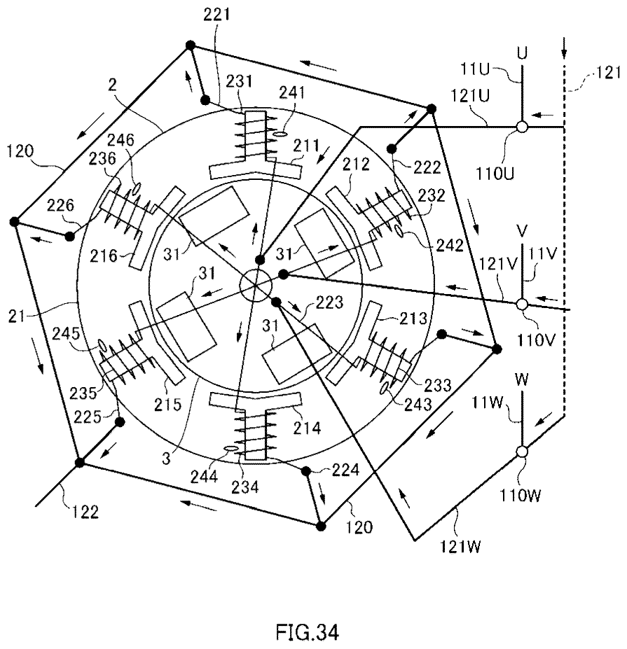

FIG. 34 is a drawing for explaining the flow of the heat carrier in FIG. 29. Note that the arrow marks indicate the flow direction of the heat carrier.

After the heat carrier flows through the heat carrier inlet pipe 121, the heat carrier divides into three flows.

The first flow passes through the U-phase heat carrier inlet pipe 121U and divides into two. One of them passes through the first hollow conductor wire 221 of the first coil 231 and flows into the heat carrier outlet pipe 122. The other of them passes through the fourth hollow conductor wire 224 of the fourth coil 234 and flows into the heat carrier outlet pipe 122.

The second flow passes through the V-phase heat carrier inlet pipe 121V and divides into two. One of them passes through the second hollow conductor wire 222 of the second coil 232 and flows into the heat carrier outlet pipe 122. The other of them passes through the fifth hollow conductor wire 225 of the fifth coil 235 and flows into the heat carrier outlet pipe 122.

The third flow passes through the W-phase heat carrier inlet pipe 121W and divides into two. One of them passes through the third hollow conductor wire 223 of the third coil 233 and flows into the heat carrier outlet pipe 122. The other of them passes through the fifth hollow conductor wire 225 of the fifth coil 235 and flows into the heat carrier outlet pipe 122. The heat carrier passes through the sixth hollow conductor wire 226 of the sixth coil 236 and flows into the heat carrier outlet pipe 122.

The flow of the heat carrier will be explained below using an exploded diagram.

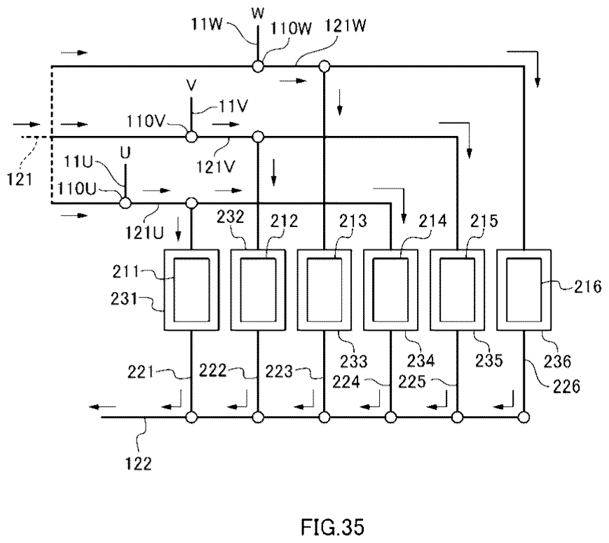

FIG. 35 is a drawing for explaining the flow of the heat carrier using the exploded diagram shown in FIG. 31. Note that the arrow marks indicate the flow direction of the heat carrier.

After the heat carrier flows through the heat carrier inlet pipe 121, the heat carrier divides into three flows.

The first flow passes through the U-phase heat carrier inlet pipe 121U and divides into two. One of them passes through the first hollow conductor wire 221 of the first coil 231 and flows into the heat carrier outlet pipe 122. The other of them passes through the fourth hollow conductor wire 224 of the fourth coil 234 and flows into the heat carrier outlet pipe 122.

The second flow passes through the V-phase heat carrier inlet pipe 121V and divides into two. One of them passes through the second hollow conductor wire 222 of the second coil 232 and flows into the heat carrier outlet pipe 122. The other of them passes through the fifth hollow conductor wire 225 of the fifth coil 235 and flows into the heat carrier outlet pipe 122.

The third flow passes through the W-phase heat carrier inlet pipe 121W and divides into two. One of them passes through the third hollow conductor wire 223 of the third coil 233 and flows into the heat carrier outlet pipe 122. The other of them passes through the sixth hollow conductor wire 226 of the sixth coil 236 and flows into the heat carrier outlet pipe 122.

Then, the flow of the current will be explained.

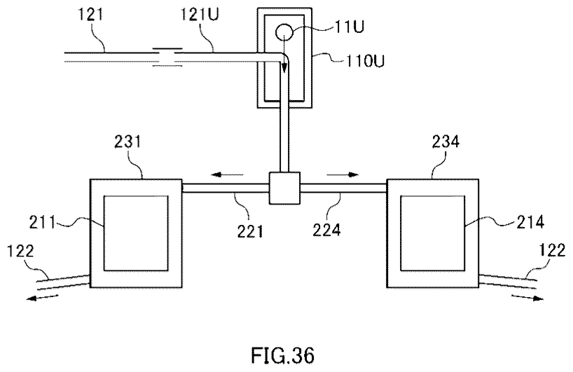

FIG. 36 is a drawing for explaining the flow of the current in FIG. 30B. Note that the arrow marks indicate the flow direction of the current.

After the current flows through the U-phase line 11U, the current flows through the U-phase heat carrier inlet pipe 121U, passes through the first hollow conductor wire 221 of the first coil 231 and reaches the heat carrier outlet pipe 122 as one flow, and the current passes through the fourth hollow conductor wire 224 of the fourth coil 234 and reaches the heat carrier outlet pipe 122 as the other flow. The flow of current after reaching the heat carrier outlet pipe 122 will be described later.

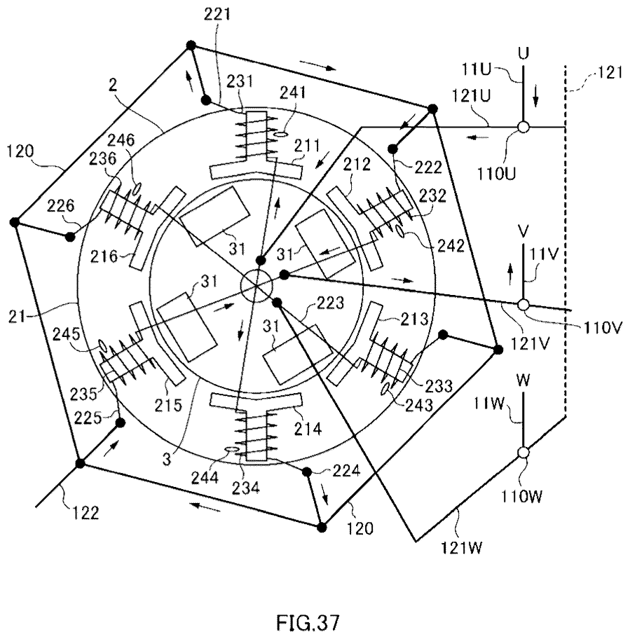

FIG. 37 is a drawing for explaining how the current flows from the U-phase line 11U to the V-phase line 11V in FIG. 29. Note that the arrow marks indicate the flow direction of the current.

The current input from the U-phase line 11U flows through the U-phase heat carrier inlet pipe 121U, passes through the first hollow conductor wire 221 of the first coil 231 and reaches the heat carrier outlet pipe 122 as one flow, and passes through the fourth hollow conductor wire 224 of the fourth coil 234 and reaches the heat carrier outlet pipe 122 as the other flow. Then, the current flows through the second hollow conductor wire 222 of the second coil 232, the fourth hollow conductor wire 224 of the fourth coil 234 and the V-phase heat carrier inlet pipe 121V and reaches the V-phase line 11V.

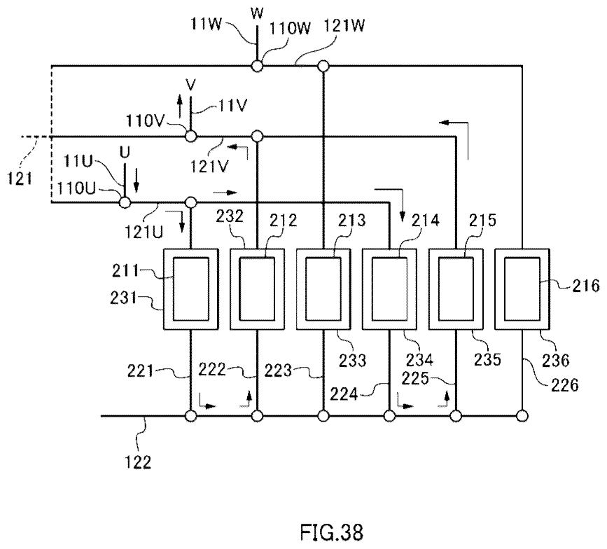

The flow of the above described current will be explained below with reference to the exploded diagram. FIG. 38 is a drawing for explaining how the current flows from the U-phase line 11U to the V-phase line 11V with reference to the exploded diagram shown in FIG. 31. Note that the arrow marks indicate the flow direction of the current.

The current input from the U-phase line 11U flows through the U-phase heat carrier inlet pipe 121U, passes through the first hollow conductor wire 221 of the first coil 231 and reaches the heat carrier outlet pipe 122 as one flow, and passes through the fourth hollow conductor wire 224 of the fourth coil 234 and reaches the heat carrier outlet pipe 122 as the other flow. Then, the current flows through the second hollow conductor wire 222 of the second coil 232, flows through the fifth hollow conductor wire 225 of the fifth coil 235, flows through the V-phase heat carrier inlet pipe 121V and reaches the V-phase line 11V.

By employing the above described configuration, the length of the flow path of the heat carrier becomes shorter compared to the first embodiment and the second embodiment. Thus, the pressure loss of the heat carrier flowing through the path can be reduced and a heat carrier pump with a lower discharge pressure can be used. However, the determination of the series or parallel circuit of the coil is appropriately selected according to the motor design.

### Sixth Embodiment

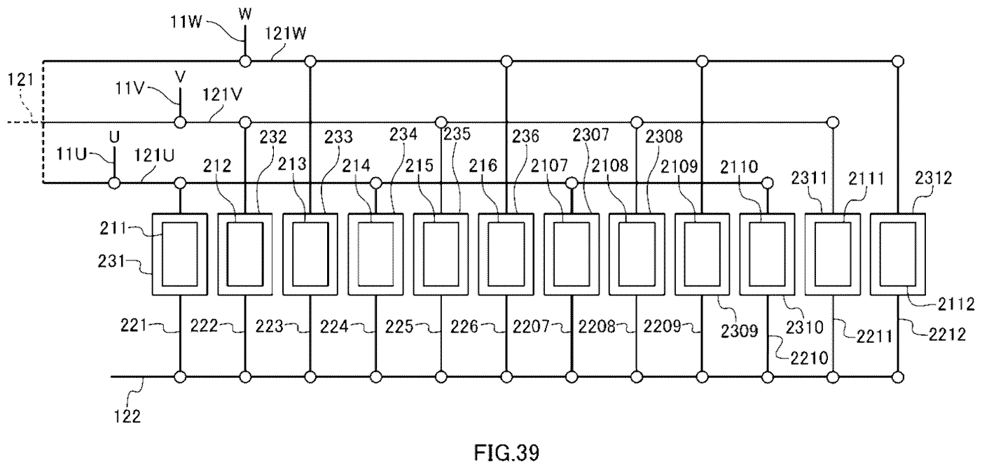

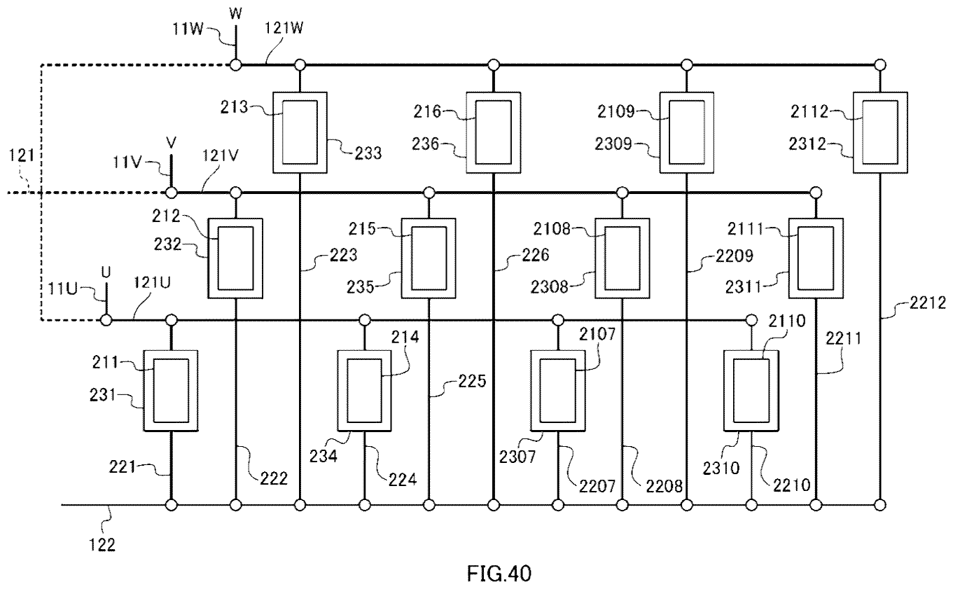

FIG. 39 is a drawing simply showing the configuration of the coil of the rotating electrical machine of the sixth embodiment. FIG. 40 is a drawing showing the configuration diagram of FIG. 39 divided vertically into U-phase, V-phase and W-phase to facilitate understanding of FIG. 39.

Although the stator 2 with six slots is arranged in the fifth embodiment, the number of the slots may be increased. For example, as shown in FIG. 39, the stator 2 with twelve slots can be used. In this case, the slots are twelve: the first slot 211; the second slot 212; the third slot 213; the fourth slot 214; the fifth slot 215; the sixth slot 216; the seventh slot 2107; the eighth slot 2108; the ninth slot 2109; the tenth slot 2110; the eleventh slot 2111; and the twelfth slot 2112.

The configuration of the first slot 211, the second slot 212, the third slot 213, the fourth slot 214, the fifth slot 215 and the sixth slot 216 is basically the same as that of the first embodiment. Therefore, the first slot 211 and the fourth slot 214 are specifically described here.

The first coil 231 is formed by winding the first hollow conductor wire 221 around the first slot 211. The first hollow conductor wire 221 has a hollow shape so that the heat carrier can flow through the first hollow conductor wire 221. One end (heat carrier inlet) of the first hollow conductor wire 221 is connected to the U-phase heat carrier inlet pipe 121U. The other end (heat carrier outlet) of the first hollow conductor wire 221 is connected to the heat carrier outlet pipe 122.

The fourth coil 234 is formed by winding the fourth hollow conductor wire around the fourth slot 214. The fourth hollow conductor wire 224 has a hollow shape so that the heat carrier can flow through the fourth hollow conductor wire 224. One end (heat carrier inlet) of the fourth hollow conductor wire 224 is connected to the U-phase heat carrier inlet pipe 121U. The other end (heat carrier outlet) of the fourth hollow conductor wire 224 is connected to the heat carrier outlet pipe 122.

As described above, the configuration of the first slot 211 and the fourth slot 214 is the same as that of the first embodiment. Since the other slots (second slot 212, third slot 213, fifth slot 215, sixth slot 216) are also the same as the first embodiment, a detailed description is omitted.

In addition, the seventh slot 2107 is the same as the first slot 211. Namely, the seventh coil 2307 is formed by winding the seventh hollow conductor wire 2207 around the seventh slot 2107. The seventh hollow conductor wire 2207 has a hollow shape so that the heat carrier can flow through the seventh hollow conductor wire 2207. One end (heat carrier inlet) of the seventh hollow conductor wire2207 is connected to the U-phase heat carrier inlet pipe 121U. The other end (heat carrier outlet) of the seventh hollow conductor wire 2207 is connected to the heat carrier outlet pipe 122.

The eighth slot 2108 is the same as the second slot 212. Namely, the eighth coil 2308 is formed by winding the eighth hollow conductor wire 2208 around the eighth slot 2108. The eighth hollow conductor wire 2208 has a hollow shape so that the heat carrier can flow through the eighth hollow conductor wire 2208. One end (heat carrier inlet) of the eighth hollow conductor wire 2208 is connected to the V-phase heat carrier inlet pipe 121V. The other end (heat carrier outlet) of the eighth hollow conductor wire 2208 is connected to the heat carrier outlet pipe 122.

The ninth slot 2109 is the same as the third slot 213. Namely, the ninth coil 2309 is formed by winding the ninth hollow conductor wire 2209 around the ninth slot 2109. The ninth hollow conductor wire 2209 has a hollow shape so that the heat carrier can flow through the ninth hollow conductor wire 2209. One end (heat carrier inlet) of the ninth hollow conductor wire 2209 is connected to the W-phase heat carrier inlet pipe 121W. The other end (heat carrier outlet) of the ninth hollow conductor wire 2209 is connected to the heat carrier outlet pipe 122.

The tenth slot 2110 is the same as the fourth slot 214. Namely, the tenth coil 2310 is formed by winding the tenth hollow conductor wire 2210 around the tenth slot 2110. The tenth hollow conductor wire 2210 has a hollow shape so that the heat carrier can flow through the tenth hollow conductor wire 2210. One end (heat carrier inlet) of the tenth hollow conductor wire 2210 is connected to the U-phase heat carrier inlet pipe 121U. The other end (heat carrier outlet) of the tenth hollow conductor wire 2210 is connected to the heat carrier outlet pipe 122.

The eleventh slot 2111 is the same as the fifth slot 215. Namely, the eleventh coil 2311 is formed by winding the eleventh hollow conductor wire 2211 around the eleventh slot 2111. The eleventh hollow conductor wire 2211 has a hollow shape so that the heat carrier can flow through the eleventh hollow conductor wire 2211. One end (heat carrier inlet) of the eleventh hollow conductor wire 2211 is connected to the V-phase heat carrier inlet pipe 121V. The other end (heat carrier outlet) of the eleventh hollow conductor wire 2211 is connected to the heat carrier outlet pipe 122.

The twelfth slot 2112 is the same as the sixth slot 216. Namely, the twelfth coil 2312 is formed by winding the twelfth hollow conductor wire 2212 around the twelfth slot 2112. The twelfth hollow conductor wire 2212 has a hollow shape so that the heat carrier can flow through the twelfth hollow conductor wire 2212. One end (heat carrier inlet) of the twelfth hollow conductor wire 2212 is connected to the W-phase heat carrier inlet pipe 121W. The other end (heat carrier outlet) of the twelfth hollow conductor wire 2212 is connected to the heat carrier outlet pipe 122.

As apparent from the comparison between FIG. 39 and FIG. 31, the configuration of FIG. 39 is formed by preparing two pairs of the configuration shown in FIG. 31 and connecting them in parallel.

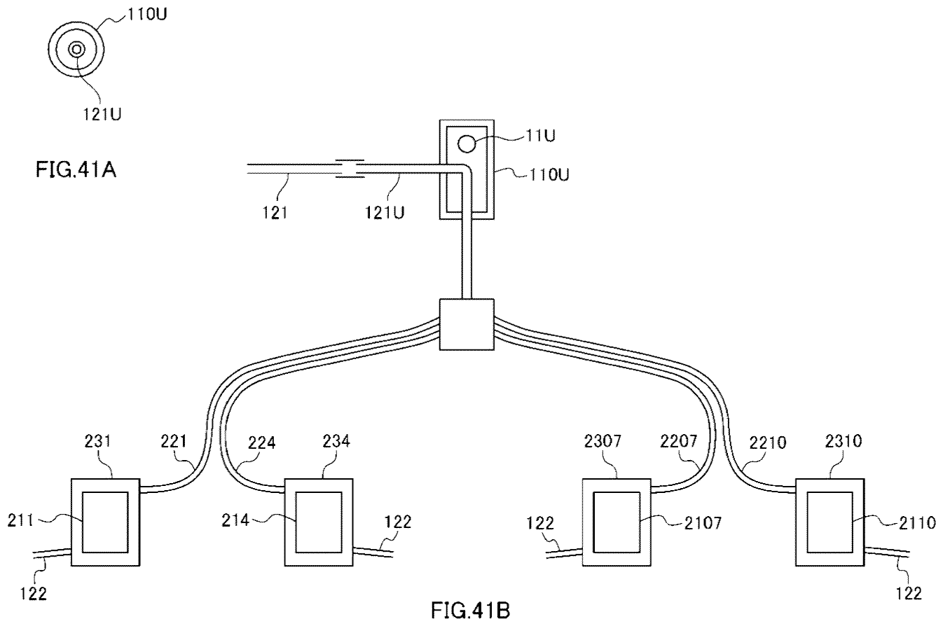

FIGS. 41A and 41B are drawings for explaining the U-phase connection portion. FIG. 41A is a planar cross-sectional view of the U-phase connection portion 110U. FIG. 41B is a simplified drawing of the vicinity of the U-phase connection portion.

As described above, one end (heat carrier inlet) of the first hollow conductor wire 221 of the first coil 231 is connected to the U-phase heat carrier inlet pipe 121U. The other end (heat carrier outlet) of the first hollow conductor wire 221 is connected to the heat carrier outlet pipe 122. In addition, one end (heat carrier inlet) of the fourth hollow conductor wire 224 of the fourth coil 234 is connected to the U-phase heat carrier inlet pipe 121U. The other end (heat carrier outlet) of the fourth hollow conductor wire 224 is connected to the heat carrier outlet pipe 122. Furthermore, one end (heat carrier inlet) of the seventh hollow conductor wire 2207 of the seventh coil 2307 is connected to the U-phase heat carrier inlet pipe 121U. The other end (heat carrier outlet) of the seventh hollow conductor wire 2207 is connected to the heat carrier outlet pipe 122. Furthermore, one end (heat carrier inlet) of the tenth hollow conductor wire 2210 of the tenth coil 2310 is also connected to the U-phase heat carrier inlet pipe 121U. The other end (heat carrier outlet) of the tenth hollow conductor wire 2210 is connected to the heat carrier outlet pipe 122. As described above, the first slot 211 (first hollow conductor wire 221), the fourth slot 214 (fourth hollow conductor wire 224), the seventh slot 2107 (seventh hollow conductor wire 2207) and the tenth slot 2110 (tenth hollow conductor wire 2210) are arranged in parallel.

Although the U-phase connection portion is explained in FIGS. 41A and 41B, the explanation of the V-phase connection portion and the W-phase connection portion is omitted since the configuration is the same.

Then, the flow of the heat carrier will be explained.

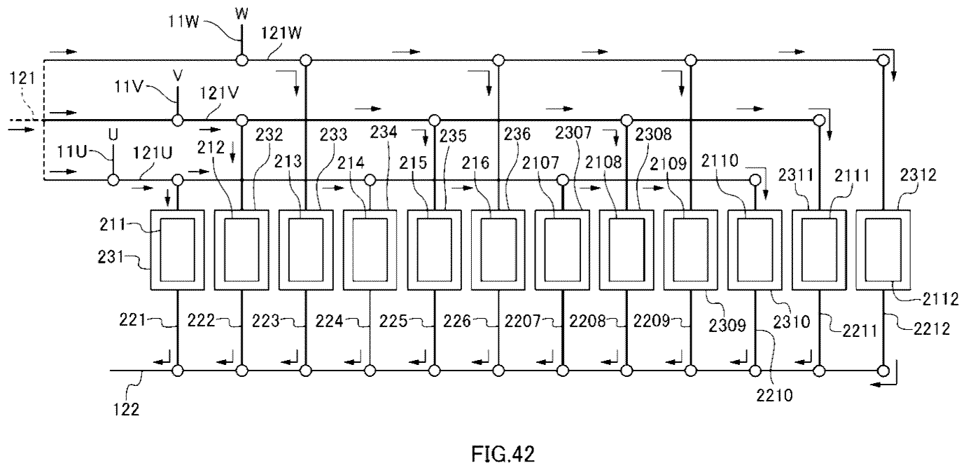

FIG. 42 is a drawing for explaining the flow of the heat carrier using the exploded diagram shown in FIG. 39. Note that the arrow marks indicate the flow direction of the heat carrier.

After the heat carrier flows through the heat carrier inlet pipe 121, the heat carrier divides into three flows.

The first flow passes through the U-phase heat carrier inlet pipe 121U and further divides into four. The first of them passes through the first hollow conductor wire 221 of the first coil 231 and flows into the heat carrier outlet pipe 122. The second of them passes through the fourth hollow conductor wire 224 of the fourth coil 234 and flows into the heat carrier outlet pipe 122. The third of them passes through the seventh hollow conductor wire 2207 of the seventh coil 2307 and flows into the heat carrier outlet pipe 122. The fourth of them passes through the tenth hollow conductor wire 2210 of the tenth coil 2310 and flows into the heat carrier outlet pipe 122.

The second flow passes through the V-phase heat carrier inlet pipe 121V and further divides into four. The first of them passes through the second hollow conductor wire 222 of the second coil 232 and flows into the heat carrier outlet pipe 122. The second of them passes through the fifth hollow conductor wire 225 of the fifth coil 235 and flows into the heat carrier outlet pipe 122. The third of them passes through the eighth hollow conductor wire 2208 of the eighth coil 2308 and flows into the heat carrier outlet pipe 122. The fourth of them passes through the eleventh hollow conductor wire 2211 of the eleventh coil 2311 and flows into the heat carrier outlet pipe 122.

The third flows through the W-phase heat carrier inlet pipe 121W and further divides into four. The first of them passes through the third hollow conductor wire 223 of the third coil 233 and flows into the heat carrier outlet pipe 122. The second of them passes through the sixth hollow conductor wire 226 of the sixth coil 236 and flows into the heat carrier outlet pipe 122. The third of them passes through the ninth hollow conductor wire 2209 of the ninth coil 2309 and flows into the heat carrier outlet pipe 122. The fourth of them passes through the twelfth hollow conductor wire 2212 of the twelfth coil 2312 and flows into the heat carrier outlet pipe 122.

Then, the flow of the current will be explained.

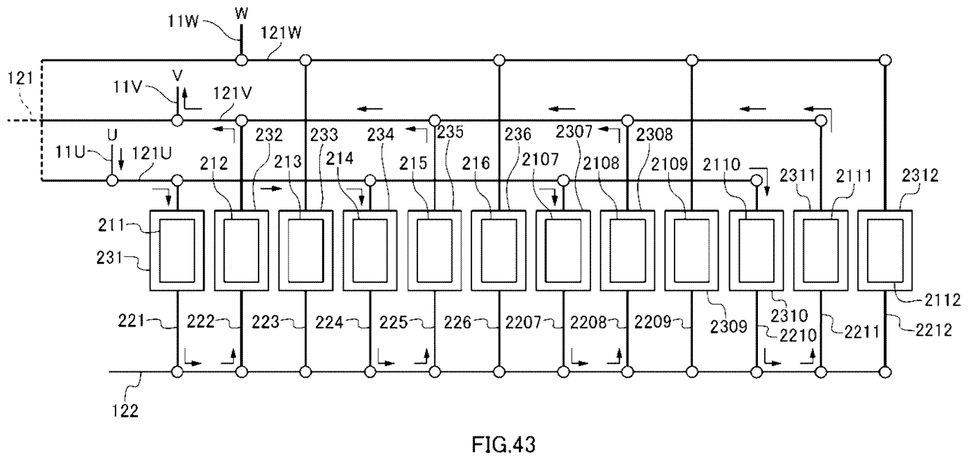

FIG. 43 is a drawing for explaining how the current flows from the U-phase line 11U to the V-phase line 11V with reference to the exploded diagram shown in FIG. 39. Note that the arrow marks indicate the flow direction of the current.

The current input from the U-phase line 11U flows through the U-phase heat carrier inlet pipe 121U, passes through the first hollow conductor wire 221 of the first coil 231 and reaches the heat carrier outlet pipe 122 as the first flow, and passes through the fourth hollow conductor wire 224 of the fourth coil 234 and reaches the heat carrier outlet pipe 122 as the second flow. In addition, the current passes through the seventh hollow conductor wire 2207 of the seventh coil 2307 and reaches the heat carrier outlet pipe 122 as the third flow, and passes through the tenth hollow conductor wire 2210 of the tenth coil 2310 and reaches the heat carrier outlet pipe 122 as the fourth flow. Then, the current flows through the second hollow conductor wire 222 of the second coil 232, the fifth hollow conductor wire 225 of the fifth coil 235 and further the eighth hollow conductor wire 2208 of the eighth coil 2308 and the eleventh hollow conductor wire 2211 of the eleventh coil 2311, flows through the V-phase heat carrier inlet pipe 121V and reaches the V-phase line 11V.

By employing the above described configuration, it is possible to achieve the rotating electrical machine where the stator 2 with twelve slots is arranged.

As apparent from the comparison between FIGS. 30A and 30B (six slots) and FIGS. 41A and 41B (twelve slots), the configuration of FIGS. 41A and 41B is formed by preparing two pairs of the configurations of FIGS. 30A and 30B and connecting them in parallel. The number of the slots can be increased by connecting necessary pairs of the configurations of FIGS. 30A and 30B in parallel. For example, eighteen slots can be achieved by connecting three pairs of the configurations of FIGS. 30A and 30B in parallel. Twenty four slots can be achieved by connecting four pairs of the configurations of FIGS. 30A and 30B in parallel.

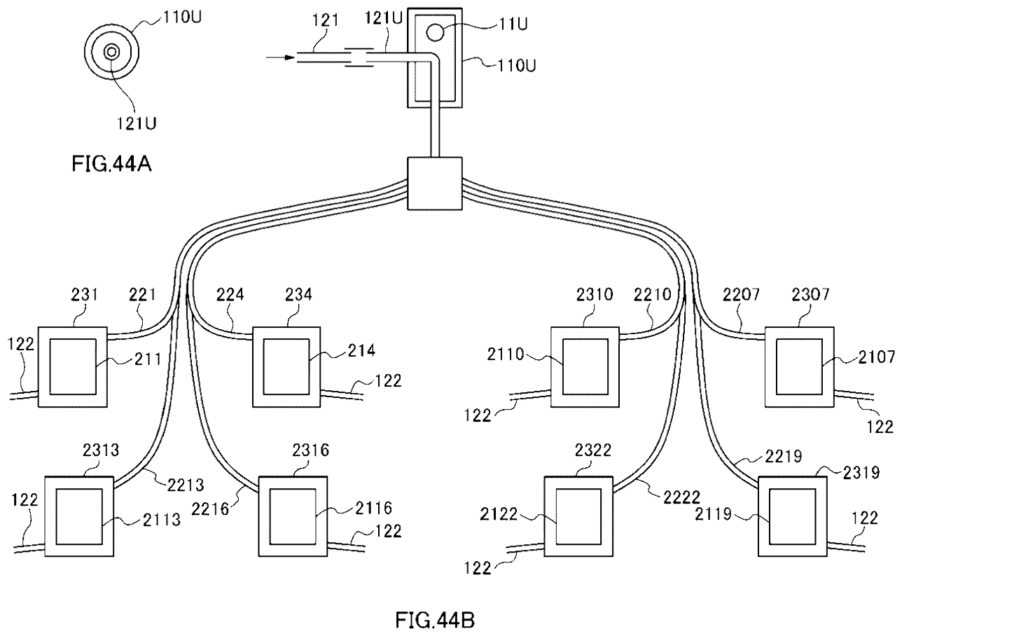

Namely, twenty four slots can be achieved by connecting the U-phase heat carrier inlet pipe 121U, the first slot 211 (first hollow conductor wire 221), the fourth slot 214 (fourth hollow conductor wire 224), the seventh slot 2107 (first hollow conductor wire 2207), the tenth slot 2110 (tenth hollow conductor wire 2210), the thirteenth slot 2113 (thirteenth hollow conductor wire 2213), the sixteenth slot 2116 (sixteenth hollow conductor wire 2216), the nineteenth slot 2119 (nineteenth hollow conductor wire 2219) and the twenty second slot 2122 (twenty second hollow conductor wire2222) in parallel as the U-phase connection portion is shown in FIGS. 44A and 44B.

Although the U-phase connection portion is explained in FIGS. 44A and 44B, the explanation of the V-phase connection portion and the W-phase connection portion is omitted since the configuration is the same.

By employing the above described configuration, it is possible to achieve the rotating electrical machine where the stator 2 with twenty four slots is arranged.

### Seventh Embodiment

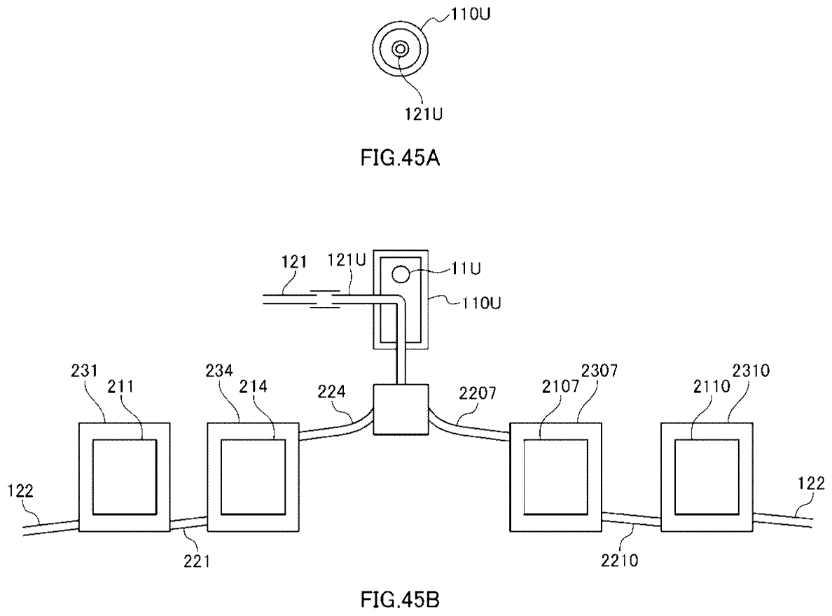

FIGS. 45A and 45B are drawings for explaining the U-phase connection portion of the rotating electrical machine of the seventh embodiment. FIG. 45A is a planar cross-sectional view of the U-phase connection portion 110U. FIG. 45B is a simplified drawing of the vicinity of the U-phase connection portion.

In the present embodiment, one end (heat carrier inlet) of the fourth hollow conductor wire 224 is continued to the U-phase heat carrier inlet pipe 121U. In addition, the other end (heat carrier outlet) of the fourth hollow conductor wire 224 is continued to one end (heat carrier inlet) of the first hollow conductor wire 221. The other end (heat carrier outlet) of the first hollow conductor wire 221 is continued to the heat carrier outlet pipe 122. By employing the above described configuration, it can be said that the first coil 231 (first hollow conductor wire 221) and the fourth coil 234 (fourth hollow conductor wire 224) are connected in series. Note that the fourth hollow conductor wire 224 may be the same as the first hollow conductor wire 221. Namely, the first hollow conductor wire 221 may be wound around the first slot 211 to form the first coil 231 and also wound around the fourth slot 214 to form the fourth coil 234.

In addition, one end (heat carrier inlet) of the seventh hollow conductor wire 2207 is continued to the U-phase heat carrier inlet pipe 121U. In addition, the other end (heat carrier outlet) of the seventh hollow conductor wire 2207 is continued to one end (heat carrier inlet) of the tenth hollow conductor wire 2210. The other end (heat carrier outlet) of the tenth hollow conductor wire 2210 is continued to the heat carrier outlet pipe 122. By employing the above described configuration, it can be said that the seventh coil 2307 (seventh hollow conductor wire 2207) and the tenth coil 2310 (tenth hollow conductor wire2210) are connected in series. Note that the seventh hollow conductor wire 2207 may be the same as the tenth hollow conductor wire 2210. Namely, the seventh hollow conductor wire 2207 may be wound around the seventh slot 2107 to form the seventh coil 2307 and also wound around the tenth slot 2110 to form the tenth coil 2310.

In addition, one end (heat carrier inlet) of the fourth hollow conductor wire 224 is connected to the U-phase heat carrier inlet pipe 121U. In addition, one end (heat carrier inlet) of the seventh hollow conductor wire 2207 is also connected to the U-phase heat carrier inlet pipe 121U. Accordingly, it can be said that the first coil 231 and the fourth coil 234 which are connected in series to each other are connected in parallel to the seventh coil 2307 and the tenth coil 2310 which are connected in series to each other.

Although the U-phase connection portion is explained in FIGS. 45A and 45B, the explanation of the V-phase connection portion and the W-phase connection portion is omitted since the configuration is the same.

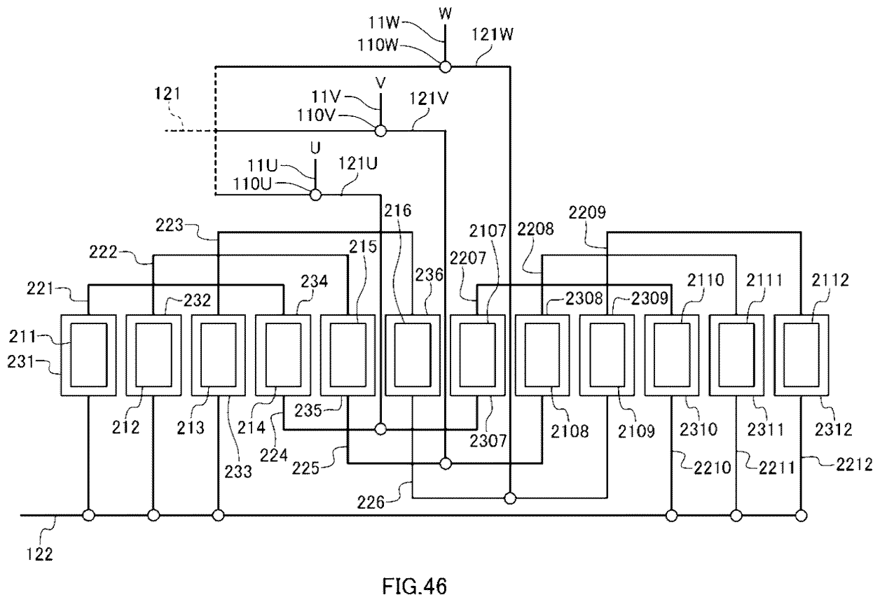

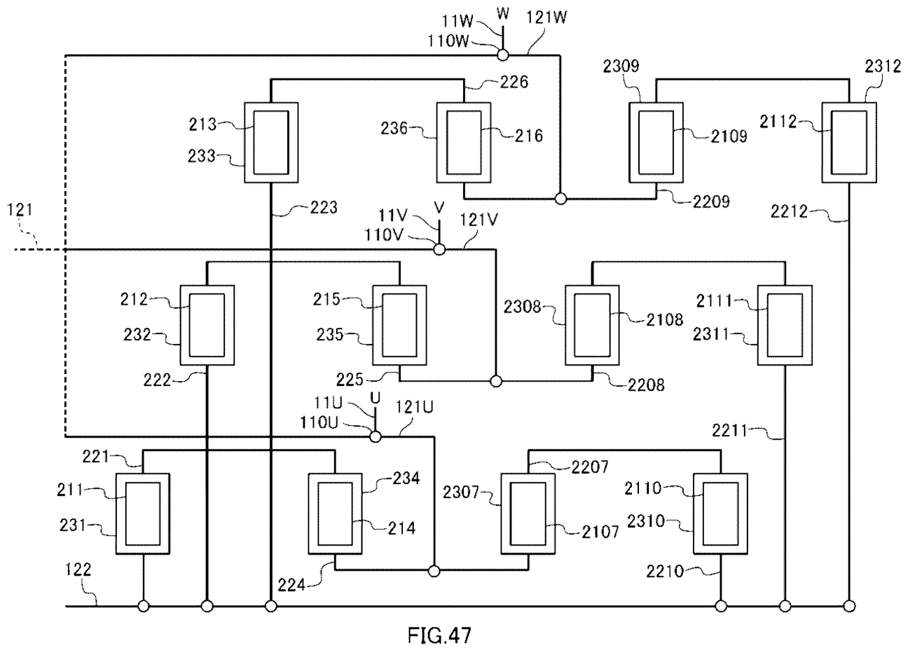

FIG. 46 is a drawing simply showing the configuration of the rotating electrical machine of the seventh embodiment. FIG. 47 is a drawing showing the configuration diagram of FIG. 46 divided vertically into U-phase, V-phase and W-phase to facilitate understanding of FIG. 46.

In the fourth embodiment (twelve slots), the number of the slots is increased by connecting a plurality pairs of the configurations of the first embodiment (six slots) in series. In the present embodiment, the number of the slots is increased with different connection.

First, the U-phase will be explained.

The fourth coil 234 is formed by winding the fourth hollow conductor wire 224 around the fourth slot 214. The fourth hollow conductor wire 224 has a hollow shape so that the heat carrier can flow through the fourth hollow conductor wire 224. One end (heat carrier inlet) of the fourth hollow conductor wire 224 is continued to the U-phase heat carrier inlet pipe 121U. The other end (heat carrier outlet) of the fourth hollow conductor wire 224 is connected to one end (heat carrier inlet) of the first hollow conductor wire 221. Note that the heat carrier inlet pipe 121 is branched into three paths on the downstream side of the heat carrier. One end (heat carrier inlet) of the fourth hollow conductor wire 224 is continued to the U-phase heat carrier inlet pipe 121U of one of the three paths.

The first coil 231 is formed by winding the first hollow conductor wire 221 around the first slot 211. The first hollow conductor wire 221 has a hollow shape so that the heat carrier can flow through the first hollow conductor wire 221. One end (heat carrier inlet) of the first hollow conductor wire 221 is connected to the other end (heat carrier outlet) of the fourth hollow conductor wire 224. The other end (heat carrier outlet) of the first hollow conductor wire 221 is continued to the heat carrier outlet pipe 122. Note that the first hollow conductor wire 221 may be the same as the fourth hollow conductor wire 224. Namely, the first hollow conductor wire 221 is wound around the first slot 211 to form the first coil 231 and also wound around the fourth slot 214 to form the fourth coil 234. In addition, the first hollow conductor wire 221 may be formed separately from the fourth hollow conductor wire 224 and continued to the fourth hollow conductor wire 224.

The seventh coil 2307 is formed by winding the seventh hollow conductor wire 2207 around the seventh slot 2107. The seventh hollow conductor wire 2207 has a hollow shape so that the heat carrier can flow through the seventh hollow conductor wire 2207. One end (heat carrier inlet) of the seventh hollow conductor wire 2207 is continued to the U-phase heat carrier inlet pipe 121U. The other end (heat carrier outlet) of the seventh hollow conductor wire 2207 is continued to one end (heat carrier inlet) of the tenth hollow conductor wire 2210 wound around the tenth slot 2110.

The tenth coil 2310 is formed by winding the tenth hollow conductor wire 2210 around the tenth slot 2110. The tenth hollow conductor wire 2210 has a hollow shape so that the heat carrier can flow through the tenth hollow conductor wire 2210.One end (heat carrier inlet) of the tenth hollow conductor wire 2210 is continued to the other end (heat carrier outlet) of the seventh hollow conductor wire 2207. The other end (heat carrier outlet) of the tenth hollow conductor wire 2210 is continued to the heat carrier outlet pipe 122. Note that the tenth hollow conductor wire 2210 may be the same as the seventh hollow conductor wire 2207 and the seventh hollow conductor wire 2207 may be also wound around the tenth slot 2110 to form the tenth hollow conductor wire 2210. Alternatively, the tenth hollow conductor wire 2210 may be formed separately from the seventh hollow conductor wire 2207 and continued to the seventh hollow conductor wire 2207.

The V-phase is the same.

Namely, the fifth coil 235 is formed by winding the fifth hollow conductor wire 225 around the fifth slot 215. The fifth hollow conductor wire 225 has a hollow shape so that the heat carrier can flow through the fifth hollow conductor wire 225. One end (heat carrier inlet) of the fifth hollow conductor wire 225 is continued to the V-phase heat carrier inlet pipe 121V. The other end (heat carrier outlet) of the fifth hollow conductor wire 225 is connected to one end (heat carrier inlet) of the second hollow conductor wire 222. Note that the heat carrier inlet pipe 121 is branched into three paths on the downstream side of the heat carrier. One end (heat carrier inlet) of the fifth hollow conductor wire 225 is continued to the V-phase heat carrier inlet pipe 121V of one of the three paths.

The second coil 232 is formed by winding the second hollow conductor wire 222 around the second slot 212. The second hollow conductor wire 222 has a hollow shape so that the heat carrier can flow through the second hollow conductor wire 222. One end (heat carrier inlet) of the second hollow conductor wire 222 is connected to the other end (heat carrier outlet) of the fifth hollow conductor wire 225. The other end (heat carrier outlet) of the second hollow conductor wire 222 is continued to the heat carrier outlet pipe 122. Note that the second hollow conductor wire 222 may be the same as the fifth hollow conductor wire 225. Namely, the second hollow conductor wire 222 may be wound around the second slot 212 to form the second coil 232 and also wound around the fifth slot 215 to form the fifth coil 235. In addition, the second hollow conductor wire 222 may be formed separately from the fifth hollow conductor wire 225 and continued to the fifth hollow conductor wire 225.

The eighth coil 2308 is formed by winding the eighth hollow conductor wire 2208 around the eighth slot 2108. The eighth hollow conductor wire 2208 has a hollow shape so that the heat carrier can flow through the eighth hollow conductor wire 2208. One end (heat carrier inlet) of the eighth hollow conductor wire 2208 is continued to the V-phase heat carrier inlet pipe 121V. The other end (heat carrier outlet) of the eighth hollow conductor wire 2208 is continued to one end (heat carrier inlet) of the eleventh hollow conductor wire 2211 wound around the eleventh slot 2111.

The eleventh coil 2311 is formed by winding the eleventh hollow conductor wire 2211 around the eleventh slot 2111. The eleventh hollow conductor wire 2211 has a hollow shape so that the heat carrier can flow through the eleventh hollow conductor wire 2211. One end (heat carrier inlet) of the eleventh hollow conductor wire 2211 is continued to the other end (heat carrier outlet) of the eighth hollow conductor wire 2208. The other end (heat carrier outlet) of the eleventh hollow conductor wire 2211 is continued to the heat carrier outlet pipe 122. Note that the eleventh hollow conductor wire 2211 may be the same as the eighth hollow conductor wire 2208 and the eighth hollow conductor wire 2208 may be also wound around the eleventh slot 2111 to form the eleventh hollow conductor wire 2211. Alternatively, the eleventh hollow conductor wire 2211 may be formed separately from the eighth hollow conductor wire 2208 and continued to the eighth hollow conductor wire 2208.

The W-phase is the same.

Namely, the sixth coil 236 is formed by winding the sixth hollow conductor wire 226 around the sixth slot 216. The sixth hollow conductor wire 226 has a hollow shape so that the heat carrier can flow through the sixth hollow conductor wire 226. One end (heat carrier inlet) of the sixth hollow conductor wire 226 is continued to the V-phase heat carrier inlet pipe 121V. The other end (heat carrier outlet) of the sixth hollow conductor wire 226 is connected to one end (heat carrier inlet) of the third hollow conductor wire 223. Note that the heat carrier inlet pipe 121 is branched into three paths on the downstream side of the heat carrier. One end (heat carrier inlet) of the sixth hollow conductor wire 226 is continued to the W-phase heat carrier inlet pipe 121W of one of the three paths.

The third coil 233 is formed by winding the third hollow conductor wire 223 around the third slot 213. The third hollow conductor wire 223 has a hollow shape so that the heat carrier can flow through the third hollow conductor wire 223. One end (heat carrier inlet) of the third hollow conductor wire 223 is connected to the other end (heat carrier outlet) of the sixth hollow conductor wire 226. The other end (heat carrier outlet) of the third hollow conductor wire 223 is continued to the heat carrier outlet pipe 122. Note that the third hollow conductor wire 223 may be the same as the sixth hollow conductor wire 226. Namely, the third hollow conductor wire 223 may be wound around the third slot 213 to form the third coil 233 and also wound around the sixth slot 216 to form the sixth coil 236. In addition, the third hollow conductor wire 223 may be formed separately from the sixth hollow conductor wire 226 and continued to the sixth hollow conductor wire 226.

The ninth hollow conductor wire 2309 is formed by winding the ninth hollow conductor wire 2209 around the ninth slot 2109. The ninth hollow conductor wire 2209 has a hollow shape so that the heat carrier can flow through the ninth hollow conductor wire 2209. One end (heat carrier inlet) of the ninth hollow conductor wire 2209 is continued to the W-phase heat carrier inlet pipe 121W. The other end (heat carrier outlet) of the ninth hollow conductor wire 2209 is continued to one end (heat carrier inlet) of the twelfth hollow conductor wire 2212 wound around the twelfth slot 2112.

The twelfth hollow conductor wire 2312 is formed by winding the twelfth hollow conductor wire 2212 around the twelfth hollow slot 2112. The twelfth hollow conductor wire 2212 has a hollow shape so that the heat carrier can flow through the twelfth hollow conductor wire 2212. One end (heat carrier inlet) of the twelfth hollow conductor wire 2212 is continued to the other end (heat carrier outlet) of the ninth hollow conductor wire 2209. The other end (heat carrier outlet) of the twelfth hollow conductor wire 2212 is continued to the heat carrier outlet pipe 122. Note that the twelfth hollow conductor wire 2212 may be the same as the ninth hollow conductor wire 2209 and the ninth hollow conductor wire 2209 may be also wound around the twelfth slot 2112 to form the twelfth hollow conductor wire 2212. Alternatively, the twelfth hollow conductor wire 2212 may be formed separately from the ninth hollow conductor wire 2209 and continued to the ninth hollow conductor wire 2209.

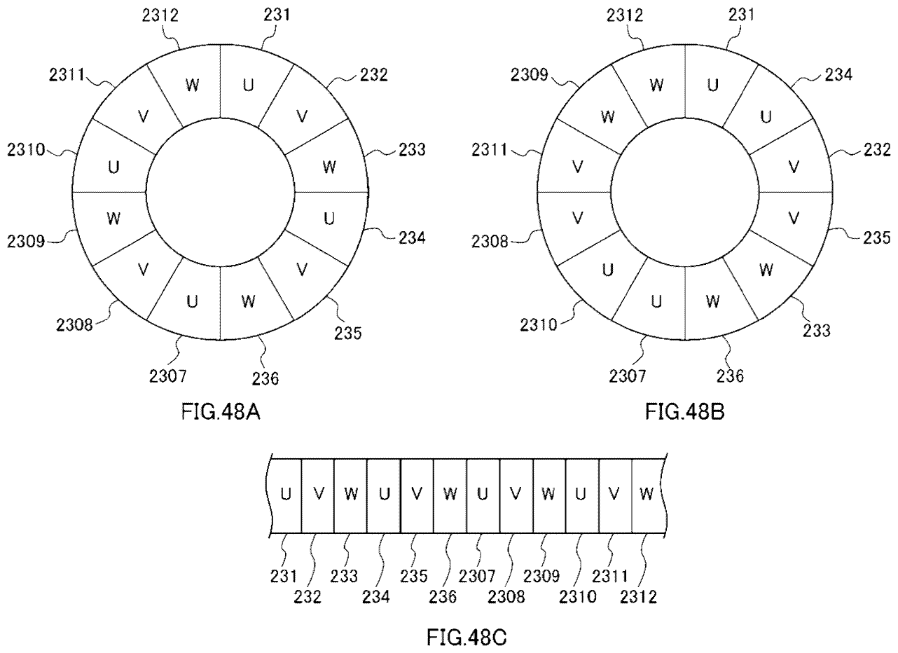

FIGS. 48A to 48C are drawings showing an example of the arrangement of the coils.

Although each of the coils is shown in a state of being exploded and arranged horizontally in a single line in FIG. 46 in order to show the configuration simply, the coils are arranged in the order as shown in FIG. 48A for the rotating electrical machine of the inner rotor type with twelve slots and eight poles (12N8P). Namely, the second coil 232, which is the V-phase coil, is positioned next to the first coil 231, which is the U-phase coil, in the clockwise direction. The third coil 233, which is the W-phase coil, is positioned next to the second coil 232. The fourth coil 234, which is the U-phase coil, is positioned next to the third coil 233. The fifth coil 235, which is the V-phase coil, is positioned next to the fourth coil 234. The sixth coil 236, which is the W-phase coil, is positioned next to the fifth coil 235. The seventh coil 2307, which is the U-phase coil, is positioned next to the sixth coil 236. The eighth coil 2308, which is the V-phase coil, is positioned next to the seventh coil 2307. The ninth coil 2309, which is the W-phase coil, is positioned next to the eighth coil 2308. The tenth coil 2310, which is the U-phase coil, is positioned next to the ninth coil 2309. The eleventh coil 2311, which is the V-phase coil, is positioned next to the tenth coil 2310. The twelfth coil 2312, which is the W-phase coil, is positioned next to the eleventh coil 2311.

As apparent from referring to FIG. 25A, the above described arrangement is the same as the fourth embodiment. In case of the rotating electrical machine of the outer rotor type with twelve slots and eight poles (12N8P), since the configuration is the same as the fourth embodiment shown in FIG. 25B, a detailed description is omitted.

In case of the rotating electrical machine of the inner rotor type with twelve slots and fourteen poles (12N14P), the coils are arranged as shown in FIG. 48B. Namely, the fourth coil 234, which is the U-phase coil, is positioned next to the first coil 231, which is the U-phase coil, in the clockwise direction. The second coil 232, which is the V-phase coil, is positioned next to the fourth coil 234. The fifth coil 235, which is the V-phase coil, is positioned next to the second coil 232. The third coil 233, which is the W-phase coil, is positioned next to the fifth coil 235. The sixth coil 236, which is the W-phase coil, is positioned next to the third coil 233. The seventh coil 2307, which is the U-phase coil, is positioned next to the sixth coil 236. The tenth coil 2310, which is the U-phase coil, is positioned next to the seventh coil 2307. The eighth coil 2308, which is the V-phase coil, is positioned next to the tenth coil 2310. The eleventh coil 2311, which is the V-phase coil, is positioned next to the eighth coil 2308. The ninth coil 2309, which is the W-phase coil, is positioned next to the eleventh coil 2311. The twelfth coil 2312, which is the W-phase coil, is positioned next to the ninth coil 2309.

As apparent from referring to FIG. 26A, the above described arrangement is the same as the fourth embodiment. In case of the rotating electrical machine of the outer rotor type with twelve slots and fourteen poles (12N14P), since the configuration is the same as the fourth embodiment shown in FIG. 26B, a detailed description is omitted.

Furthermore, when the electrical energy-mechanical energy converter is a linear motor, the coils are arranged in the order shown in FIG. 48C. Namey, the second coil 232, which is the V-phase coil, is positioned next to the first coil 231, which is the U-phase coil. The third coil 233, which is the W-phase coil, is positioned next to the second coil 232. The fourth coil 234, which is the U-phase coil, is positioned next to the third coil 233. The fifth coil 235, which is the V-phase coil, is positioned next to the fourth coil 234. The sixth coil 236, which is the W-phase coil, is positioned next to the fifth coil 235. The seventh coil 2307, which is the U-phase coil, is positioned next to the sixth coil 236. The eighth coil 2308, which is the V-phase coil, is positioned next to the seventh coil 2307. The ninth coil 2309, which is the W-phase coil, is positioned next to the eighth coil 2308. The tenth coil 2310, which is the U-phase coil, is positioned next to the ninth coil 2309. The eleventh coil 2311, which is the V-phase coil, is positioned next to the tenth coil 2310. The twelfth coil 2312, which is the W-phase coil, is positioned next to the eleventh coil 2311.

As apparent from referring to FIG. 27, the above described arrangement is the same as the fourth embodiment.

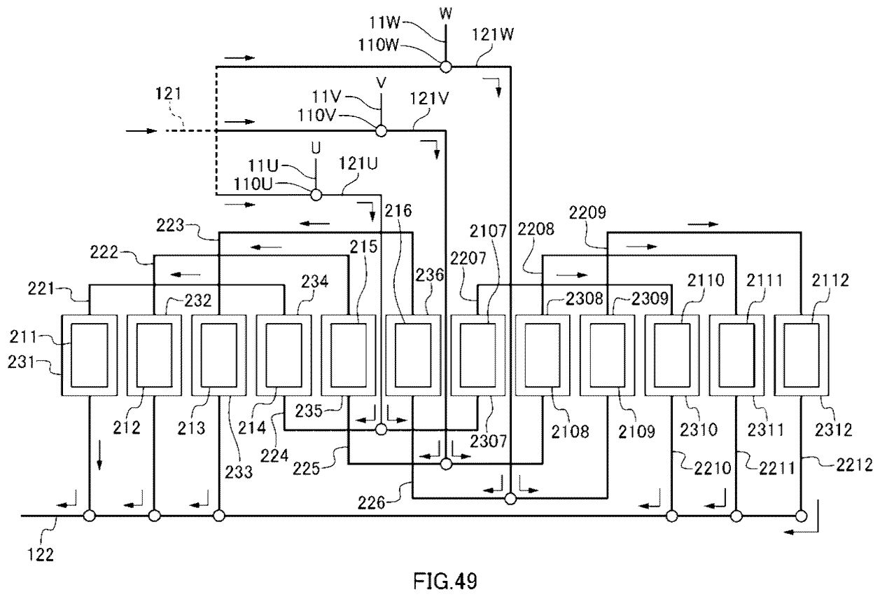

FIG. 49 is a drawing for explaining the flow of the heat carrier in FIG. 46. Note that the arrow marks indicate the flow direction of the heat carrier.

After the heat carrier flows through the heat carrier inlet pipe 121, the heat carrier divides into three flows.

The first flow passes through the U-phase heat carrier inlet pipe 121U and further branched into two. The first of them flows through the fourth hollow conductor wire 224 of the fourth coil 234, passes through the first hollow conductor wire 221 of the first coil 231 and flows into the heat carrier outlet pipe 122. The second of them flows through the seventh hollow conductor wire 2207 of the seventh coil 2307, passes through the tenth hollow conductor wire 2210 of the tenth coil 2310 and flows into the heat carrier outlet pipe 122.

The second flow passes through the V-phase heat carrier inlet pipe 121V and further branched into two. The first of them flows through the fifth hollow conductor wire 225 of the fifth coil 235, passes through the second hollow conductor wire 222 of the second coil 232 and flows into the heat carrier outlet pipe 122. The second of them flows through the eighth hollow conductor wire 2208 of the eighth coil 2308, passes through the eleventh hollow conductor wire 2211 of the eleventh coil 2311 and flows into the heat carrier outlet pipe 122.

The third flow passes through the W-phase heat carrier inlet pipe 121W and further branched into two. One of them flows through the sixth hollow conductor wire 226 of the sixth coil 236, passes through the third hollow conductor wire 223 of the third coil 233 and flows into the heat carrier outlet pipe 122. The second of them flows through the ninth hollow conductor wire 2209 of the ninth coil 2309, passes through the twelfth hollow conductor wire 2212 of the twelfth coil 2312 and flows into the heat carrier outlet pipe 122.

Then, the flow of the current will be explained.

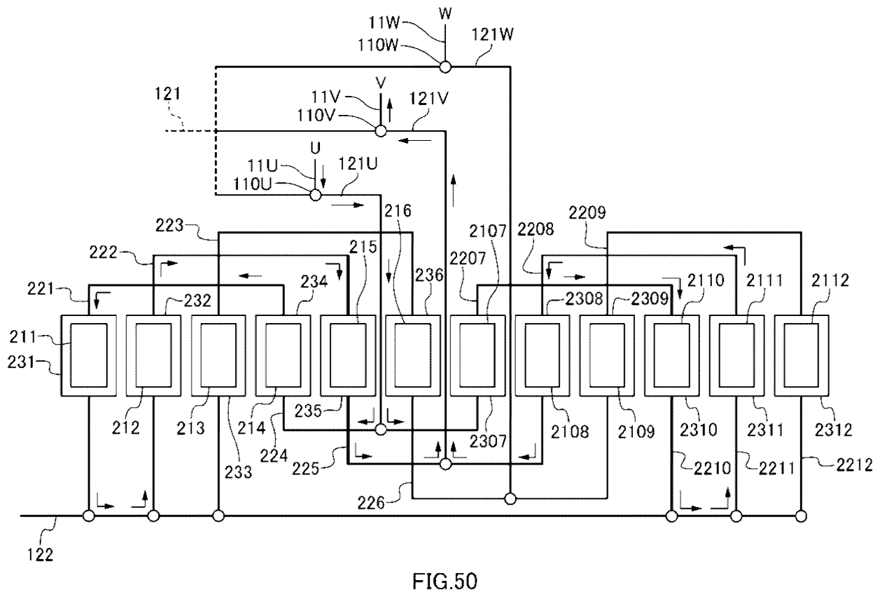

FIG. 50 is a drawing for explaining how the current flows from the U-phase line 11U to the V-phase line 11V with reference to the exploded diagram shown in FIG. 46. Note that the arrow marks indicate the flow direction of the current.

The current input from the U-phase line 11U flows through the U-phase heat carrier inlet pipe 121U and further branched into two. The current flows through the fourth hollow conductor wire 224 of the fourth coil 234, passes through the first hollow conductor wire 221 of the first coil 231 and reaches the heat carrier outlet pipe 122 as the first flow. In addition, the current flows through the seventh hollow conductor wire 2207 of the seventh coil 2307, passes through the tenth hollow conductor wire 2210 of the tenth coil 2310 and reaches the heat carrier outlet pipe 122 as the second flow. Then, the current passes through the second hollow conductor wire 222 of the second coil 232 and flows through the fifth hollow conductor wire 225 of the fifth coil 235, and passes through the eleventh hollow conductor wire 2211 of the eleventh coil 2311 and flows through the eighth hollow conductor wire 2208 of the eighth coil 2308, flows through the V-phase heat carrier inlet pipe 121V and reaches the V-phase line 11V.

By employing the above described configuration, it is also possible to achieve the rotating electrical machine where the stator 2 with twelve slots is arranged.

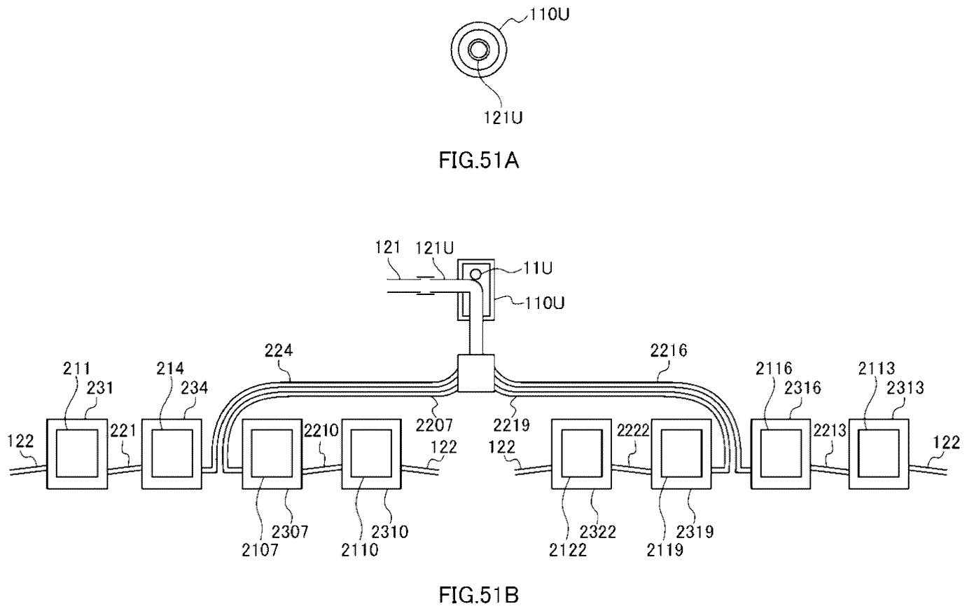

For increasing the number of the slots (e.g., twenty four slots), the U-phase is configured as shown in FIGS. 51A and 51B. Namey, the following configuration is added to the configuration of FIGS. 45A and 45B. The thirteenth coil 2313 and the sixteenth coil 2316 are connected in series. Then, one end (heat carrier inlet) of the sixteenth hollow conductor wire 2216 of the sixteenth coil 2316 is connected to the U-phase heat carrier inlet pipe 121U. In addition, the other end (heat carrier outlet) of the thirteenth hollow conductor wire 2213 of the thirteenth coil 2313 is connected to the heat carrier outlet pipe 122. In addition, the nineteenth coil 2319 and the twenty second coil 2322 are connected in series. Then, one end (heat carrier inlet) of the nineteenth hollow conductor wire 2219 of the nineteenth coil 2319 is connected to the U-phase heat carrier inlet pipe 121U. The other end (heat carrier outlet) of the twenty second hollow conductor wire 2222 of the twenty second coil 2322 is connected to the heat carrier outlet pipe 122.

Although FIGS. 51A and 51B explain the U-phase, the explanation of the V-phase and the W-phase is omitted since the configuration is the same.

By employing the above described configuration, it is possible to achieve the twenty four slots.

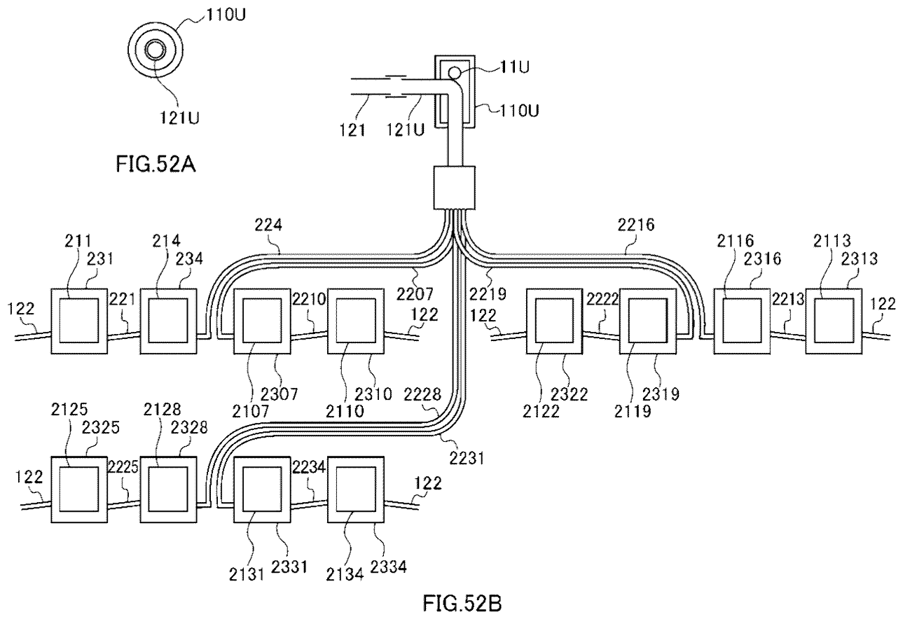

For the thirty six slots, the U-phase is configured as shown in FIGS. 52A and 52B. Namey, the following configuration is added to the configuration of FIGS. 51A and 51B. The twenty fifth coil 2325 and the twenty eighth coil 2328 are connected in series. One end (heat carrier inlet) of the twenty eighth hollow conductor wire 2228 of the twenty eighth coil 2328 is connected to the U-phase heat carrier inlet pipe 121U. In addition, the other end (heat carrier outlet) of the twenty fifth hollow conductor wire 2225 of the twenty fifth coil 2325 is connected to the heat carrier outlet pipe 122. Furthermore, the thirty first coil 2331 and the thirty fourth coil 2334 are connected in series. One end (heat carrier inlet) of the thirty first hollow conductor wire 2231 of the thirty first coil 2331 is connected to the U-phase heat carrier inlet pipe 121U. In addition, the other end (heat carrier outlet) of the thirty fourth hollow conductor wire 2234 of the thirty fourth coil 2334 is connected to the heat carrier outlet pipe 122.

Although FIGS. 52A and 52B explain the U-phase, the explanation of the V-phase and the W-phase is omitted since the configuration is the same.

By employing the above described configuration, it is possible to achieve the thirty six slots.

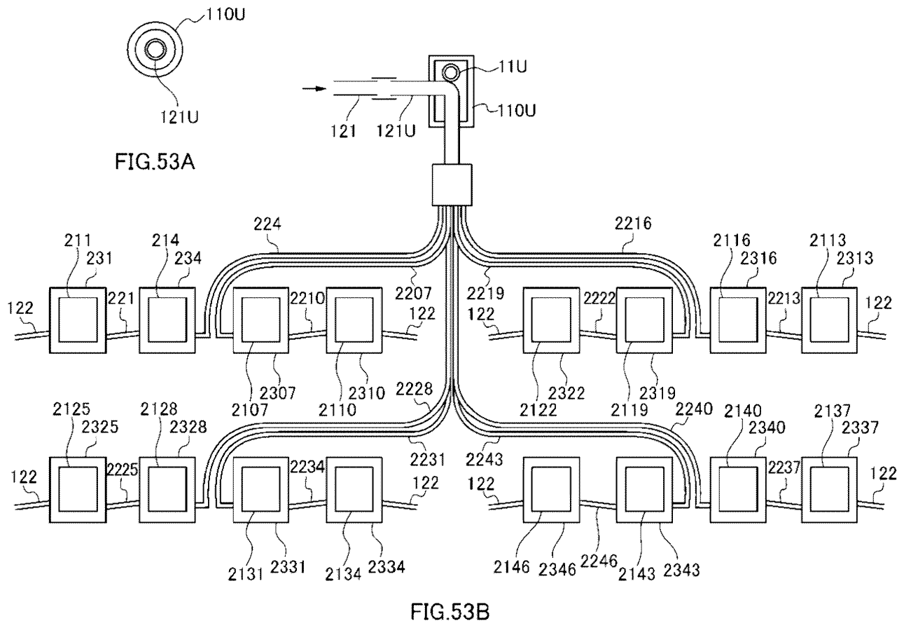

For the forty eight slots, the U-phase is configured as shown in FIGS. 53A and 53B. Namey, the following configuration is added to the configuration of FIGS. 52A and 52B. The thirty seventh coil 2337 and the fortieth coil 2340 are connected in series. In addition, one end (heat carrier inlet) of the fortieth hollow conductor wire 2240 of the fortieth coil 2340 is connected to the U-phase heat carrier inlet pipe 121U. The other end (heat carrier outlet) of the thirty seventh hollow conductor wire 2237 of the thirty seventh coil 2337 is connected to the heat carrier outlet pipe 122. Furthermore, the forty third coil 2343 and the forty sixth coil 2346 are connected in series. In addition, one end (heat carrier inlet) of the forty third hollow conductor wire 2243 of the forty third coil 2343 is connected to the U-phase heat carrier inlet pipe 121U. In addition, the other end (heat carrier outlet) of the forty sixth hollow conductor wire 2246 of the forty sixth coil 2346 is connected to the heat carrier outlet pipe 122.

Although FIGS. 53A and 53B explain the U-phase, the explanation of the V-phase and the W-phase is omitted since the configuration is the same.

By employing the above described configuration, it is possible to achieve the forty eight slots.

### Eighth Embodiment

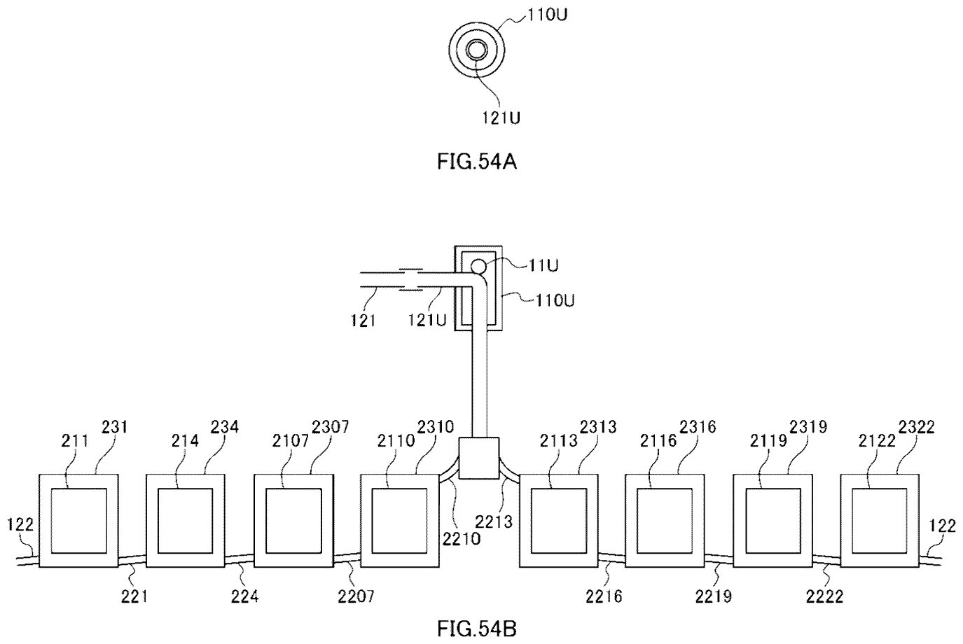

FIGS. 54A and 54B are drawings for explaining the U-phase connection portion of the eighth embodiment. FIG. 54A is a planar cross-sectional view of the U-phase connection portion 110U. FIG. 54B is a simplified drawing of the vicinity of the U-phase connection portion.

In the seventh embodiment, two coils are continued in series, one end (heat carrier inlet) of the hollow conductor wire of one of the two coils is connected to the heat carrier inlet pipe of the U-phase or the like and the other end (heat carrier outlet) of the hollow conductor wire of the other of the two coils is connected to the heat carrier outlet pipe 122. Furthermore, another two coils are also continued in series, one end (heat carrier inlet) of the hollow conductor wire of one of the another two coils is connected to the heat carrier inlet pipe of the U-phase or the like and the other end (heat carrier outlet) of the hollow conductor wire of the other of the another two coils is connected to the heat carrier outlet pipe 122. A plurality groups of the coils described above is prepared and connected to the heat carrier inlet pipe of the U-phase or the like to accommodate an increase in the number of slots. Therefore, as the number of slots increases and the number of groups of the coils increases, the heat carrier inlet pipe of the U-phase or the like requires a relatively large space.

On the other hand, the present embodiment is configured as follows. Namely, the first coil 231, the fourth coil 234, the seventh coil 2307 and the tenth coil 2310 are continued in series. The one end (heat carrier inlet) of the tenth hollow conductor wire 2210 of the tenth coil 2310 is connected to the U-phase heat carrier inlet pipe 121U. In addition, the other end (heat carrier outlet) of the first hollow conductor wire 221 of the first coil 231 is connected to the heat carrier outlet pipe 122. Furthermore, the thirteenth coil 2313, the sixteenth coil 2316, the nineteenth coil 2319 and the twenty second coil 2322 are continued in series. One end (heat carrier inlet) of the thirteenth hollow conductor wire 2213 of the thirteenth coil 2313 is connected to the U-phase heat carrier inlet pipe 121U. In addition, the other end (heat carrier outlet) of the twenty second hollow conductor wire 2222 of the twenty second coil 2322 is connected to the heat carrier outlet pipe 122.

Although FIGS. 54A and 54B explain the U-phase, the explanation of the V-phase and the W-phase is omitted since the configuration is the same.

As described above, the increase in the number of slots is accommodated by increasing the number of coils that are continued in series in the present embodiment. By employing the above described configuration, it is possible to achieve the twenty four slots. By employing the configuration of the present embodiment, the number of the hollow conductor wires can be reduced and manufacturing process of the U-phase or the like can be reduced even if the number of slots increases. In addition, the coil winding form of either the seventh embodiment or the eighth embodiment can be optimally selected based on the internal space and various parameters at the coil design stage.

### Ninth Embodiment

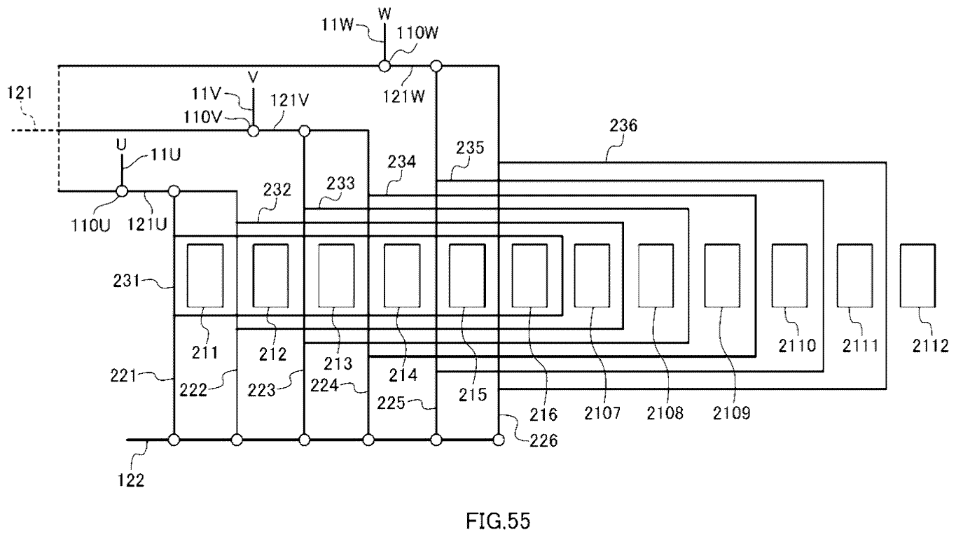

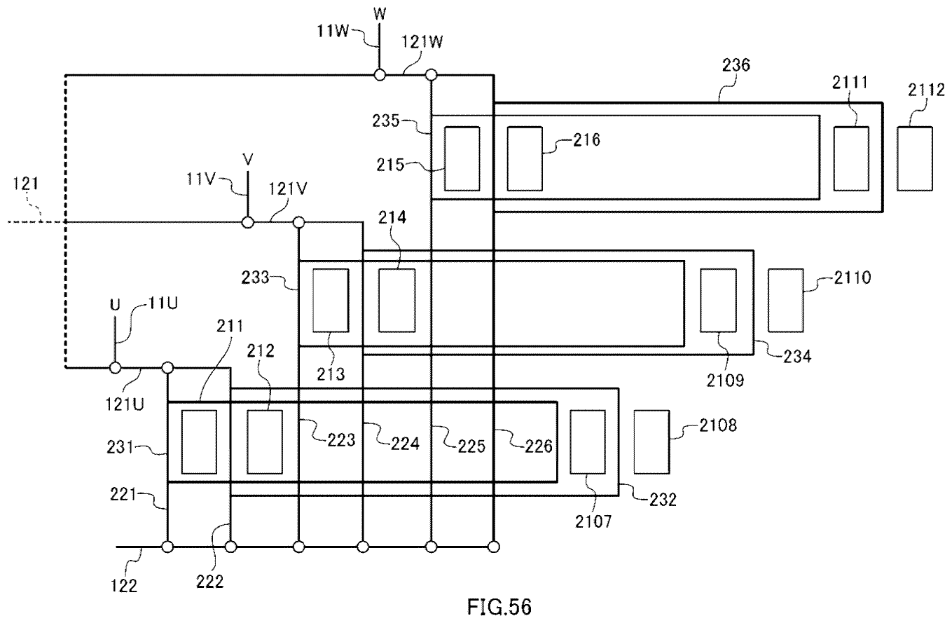

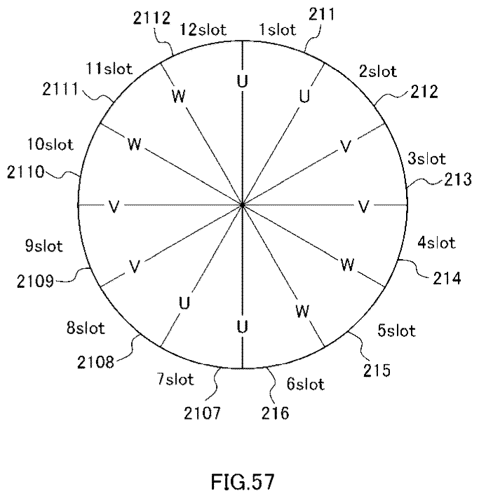

FIG. 55 is a drawing simply showing a configuration of the coil of the electrical energy-mechanical energy converter system of the ninth embodiment. FIG. 56 is a drawing showing the configuration diagram of FIG. 55 divided vertically into U-phase, V-phase and W-phase to facilitate understanding of FIG. 55. FIG. 57 is a phase arrangement diagram of the coil.

The above described embodiments employ the concentrated winding type where the hollow conductor wires are wound around each slot to form the coils. However, the type of the coil is not limited to the above described configuration. It is also possible to employ the distributed winding type where the hollow conductor wires are wound across multiple slots to form the coils.

The electrical energy-mechanical energy converter system shown in FIG. 55 is the electrical energy-mechanical energy converter with twelve slots and two poles (12N2P). In addition, the coils employ the distributed winding type.

The stator core 21 of the stator 2 of the present embodiment is formed with twelve slots. Specifically, the first slot 211, the second slot 212, the third slot 213, the fourth slot 214, the fifth slot 215, the sixth slot 216, the seventh slot 2107, the eighth slot 2108, the ninth slot 2109, the tenth slot 2110, the eleventh slot 2111 and the twelfth slot 2112 are formed in the stator core 21.

The first coil 231 is formed by winding the first hollow conductor wire 221 to pass between the first slot 211 and the twelfth slot 2112 and also between the sixth slot 216 and the seventh slot 2107. The first hollow conductor wire 221 has a hollow shape so that the heat carrier can flow through the first hollow conductor wire 221. One end (heat carrier inlet) of the first hollow conductor wire 221 is connected to the U-phase heat carrier inlet pipe 121U. The other end (heat carrier outlet) of the first hollow conductor wire 221 is connected to the heat carrier outlet pipe 122.

The second coil 232 is formed by winding the second hollow conductor wire 222 to pass between the first slot 211 and the second slot 212 and also between the seventh slot 2107 and the eighth slot 2108. The second hollow conductor wire 222 has a hollow shape so that the heat carrier can flow through the second hollow conductor wire 222. One end (heat carrier inlet) of the second hollow conductor wire 222 is connected to the U-phase heat carrier inlet pipe 121U. The other end (heat carrier outlet) of the second hollow conductor wire 222 is connected to the heat carrier outlet pipe 122.

The third coil 233 is formed by winding the third hollow conductor wire 223 to pass between the second slot 212 and the third slot 213 and also between the eighth slot 2108 and the ninth slot 2109. The third hollow conductor wire 223 has a hollow shape so that the heat carrier can flow through the third hollow conductor wire 223. One end (heat carrier inlet) of the third hollow conductor wire 223 is connected to the V-phase heat carrier inlet pipe 121V. The other end (heat carrier outlet) of the third hollow conductor wire 223 is connected to the heat carrier outlet pipe 122.

The fourth coil 234 is formed by winding the fourth hollow conductor wire 224 to pass between the third slot 213 and the fourth slot 214 and also between the ninth slot 2109 and the tenth slot 2110. The fourth hollow conductor wire 224 has a hollow shape so that the heat carrier can flow through the fourth hollow conductor wire 224. One end (heat carrier inlet) of the fourth hollow conductor wire 224 is connected to the V-phase heat carrier inlet pipe 121V. The other end (heat carrier outlet) of the fourth hollow conductor wire 224 is connected to the heat carrier outlet pipe 122.

The fifth coil 235 is formed by winding the fifth hollow conductor wire 225 to pass between the fourth slot 214 and the fifth slot 215 and also between the tenth slot 2110 and the eleventh slot 2111. The fifth hollow conductor wire 225 has a hollow shape so that the heat carrier can flow through the fifth hollow conductor wire 225. One end (heat carrier inlet) of the fifth hollow conductor wire 225 is connected to the W-phase heat carrier inlet pipe 121W. The other end (heat carrier outlet) of the fifth hollow conductor wire 225 is connected to the heat carrier outlet pipe 122.

The sixth coil 236 is formed by winding the sixth hollow conductor wire 226 to pass between the fifth slot 215 and the sixth slot 216 and also between the eleventh slot 2111 and the twelfth slot 2112. The sixth hollow conductor wire 226 has a hollow shape so that the heat carrier can flow through the sixth hollow conductor wire 226. One end (heat carrier inlet) of the sixth hollow conductor wire 226 is connected to the W-phase heat carrier inlet pipe 121W. The other end (heat carrier outlet) of the sixth hollow conductor wire 226 is connected to the heat carrier outlet pipe 122.

By employing the above described configuration, it is possible to achieve the rotating electrical machine of the distributed winding type with twelve slots and two poles (12N2P).

The flow of the heat carrier will be explained.

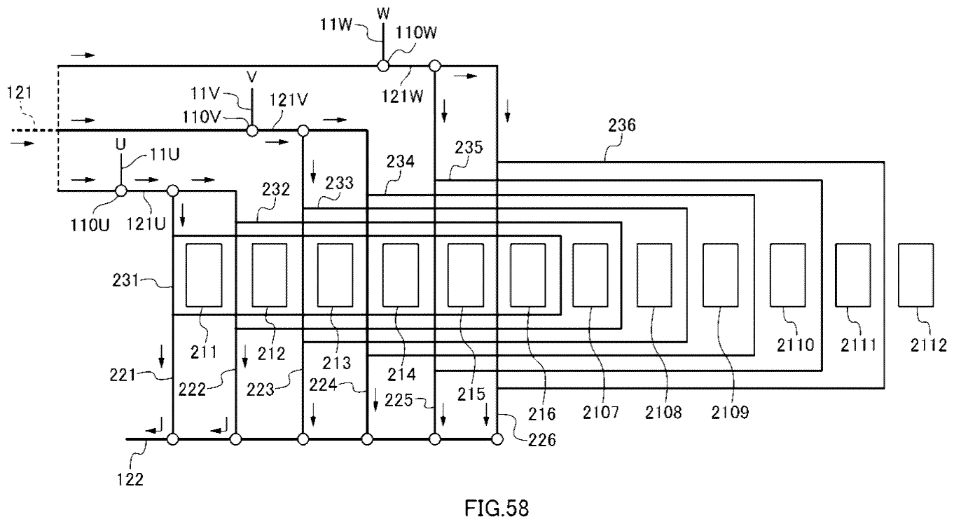

FIG. 58 is a drawing for explaining the flow of the heat carrier in FIG. 55. Note that the arrow marks indicate the flow direction of the heat carrier.

After the heat carrier flows through the heat carrier inlet pipe 121, the heat carrier divides into three flows. The first flow passes through the U-phase heat carrier inlet pipe 121U and branched into two. One of them passes through the first hollow conductor wire 221 of the first coil 231 and flows into the heat carrier outlet pipe 122. The other of them passes through the second hollow conductor wire 222 of the second coil 232 and flows into the heat carrier outlet pipe 122.

The second flow passes through the V-phase heat carrier inlet pipe 121V and branched into two. One of them passes through the third hollow conductor wire 223 of the third coil 233 and flows into the heat carrier outlet pipe 122. The other of them passes through the fourth hollow conductor wire 224 of the fourth coil 234 and flows into the heat carrier outlet pipe 122.

The third flow passes through the W-phase heat carrier inlet pipe 121W and branched into two. One of them passes through the fifth hollow conductor wire 225 of the fifth coil 235 and flows into the heat carrier outlet pipe 122. The other of them passes through the sixth hollow conductor wire 226 of the sixth coil 236 and flows into the heat carrier outlet pipe 122.

Then, the flow of the current will be explained.

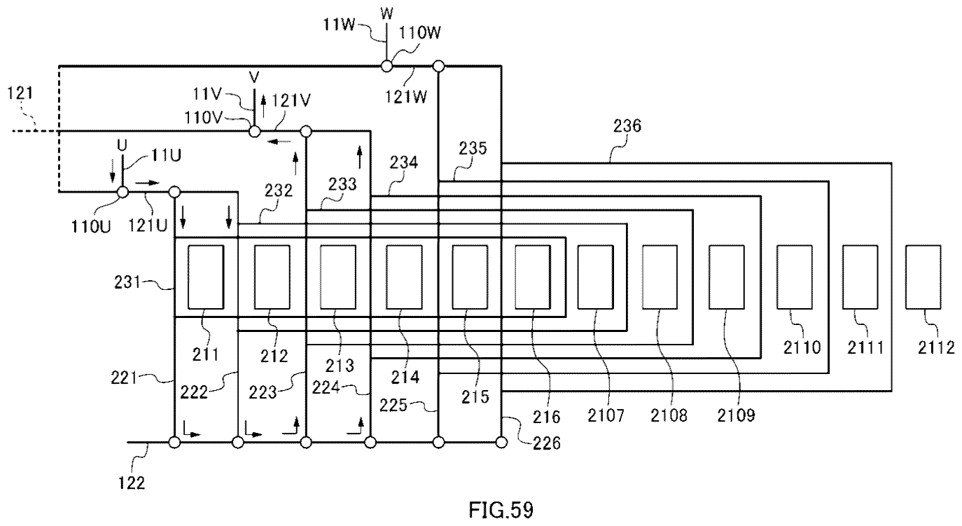

FIG. 59 is a drawing for explaining how the current flows from the U-phase line 11U to the V-phase line 11V in FIG. 55. Note that the arrow marks indicate the flow direction of the current.

The current input from the U-phase line 11U flows through the first hollow conductor wire 221 and reaches the heat carrier outlet pipe 122 as the first flow. In addition, the current flows through the second hollow conductor wire 222 and reaches the heat carrier outlet pipe 122 as another flow. Furthermore, the current flows through the third hollow conductor wire 223 and reaches the V-phase line 11V as another flow. Furthermore, the current flows through the fourth hollow conductor wire 224 and reaches the V-phase line 11V as another flow.

As described above, even in the distributed winding type where the hollow conductor wires are wound across a plurality of slots to form the coils, the same effects as the concentrated winding type can be obtained. Namely, since the heat carrier flows through the inside of the hollow conductor wire, the cooling performance of the electrical energy-mechanical energy converter is excellent.

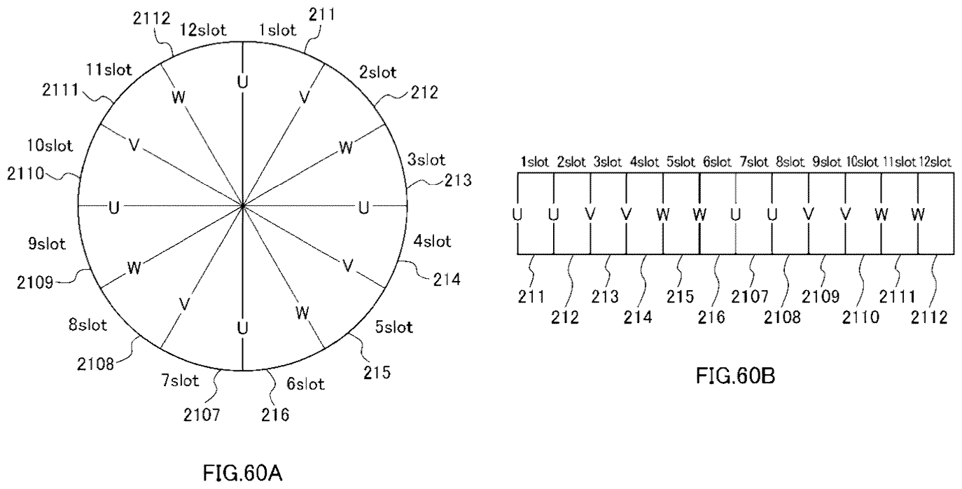

In order to achieve the rotating electrical machine of the distributed winding type with twelve slots and four poles (12N4P), the phase arrangement of the coils shown in the phase arrangement diagram in FIG. 60A can be used. Namely, the first coil 231 is formed by winding the first hollow conductor wire 221 to pass between the first slot 211 and the twelfth slot 2112 and also between the third slot 213 and the fourth slot 214.

The second coil 232 is formed by winding the second hollow conductor wire 222 to pass between the first slot 211 and the second slot 212 and also between the fourth slot 214 and the fifth slot 215.

The third coil 233 is formed by winding the third hollow conductor wire 223 to pass between the second slot 212 and the third slot 213 and also between the fifth slot 215 and the sixth slot 216.

The fourth coil 234 is formed by winding the fourth hollow conductor wire 224 to pass between the sixth slot 216 and the seventh slot 2107 and also between the ninth slot 2109 and the tenth slot 2110.

The fifth coil 235 is formed by winding the fifth hollow conductor wire 225 to pass between the seventh slot 2107 and the eighth slot 2108 and also between the tenth slot 2110 and the eleventh slot 2111.

The sixth coil 236 is formed by winding the sixth hollow conductor wire 226 to pass between the eighth slot 2108 and the ninth slot 2109 and also between the eleventh slot 2111 and the twelfth slot 2112.

By employing the above described configuration, it is possible to achieve the rotating electrical machine of the distributed winding type with twelve slots and four poles (12N4P).

In addition, when the electrical energy-mechanical energy converter is a linear motor, the coils are arranged in the order shown in FIG. 60B. Namely, the first coil 231 is formed by winding the first hollow conductor wire 221 to pass between the first slot 211 and the twelfth slot 2112 and also between the sixth slot 216 and the seventh slot 2107.

The second coil 232 is formed by winding the second hollow conductor wire 222 to pass between the first slot 211 and the second slot 212 and also between the seventh slot 2107 and the eighth slot 2108.

The third coil 233 is formed by winding the third hollow conductor wire 223 to pass between the second slot 212 and the third slot 213 and also between the eighth slot 2108 and the ninth slot 2109.

The fourth coil 234 is formed by winding the fourth hollow conductor wire 224 to pass between the third slot 213 and the fourth slot 214 and also between the ninth slot 2109 and the tenth slot 2110.

The fifth coil 235 is formed by winding the fifth hollow conductor wire 225 to pass between the fourth slot 214 and the fifth slot 215 and also between the tenth slot 2110 and the eleventh slot 2111.

The sixth coil 236 is formed by winding the sixth hollow conductor wire 226 to pass between the fifth slot 215 and the sixth slot 216 and also between the eleventh slot 2111 and the twelfth slot 2112.

By employing the above described configuration, it is possible to achieve the linear motor of the distributed winding type.

The embodiments of the present invention are described above. However, the above described embodiments merely show a part of the application examples of the present invention. The embodiments are not intended to limit the technical scope of this invention to the specific configurations of the above described embodiments.

For example, the electrical energy-mechanical energy converter (rotating electrical machine/linear motor) where the coils are formed by winding the hollow conductor wire around the slots is shown in the above described embodiments. However, the electrical energy-mechanical energy converter is not limited to the above described type.

As disclosed in Japanese Unexamined Patent Application Publication No. 2002-101591, a slotless type rotating electrical machine (electrical energy-mechanical energy converter) is known, where air-core coils are arranged on the inner peripheral surface of the stator core without having slots.

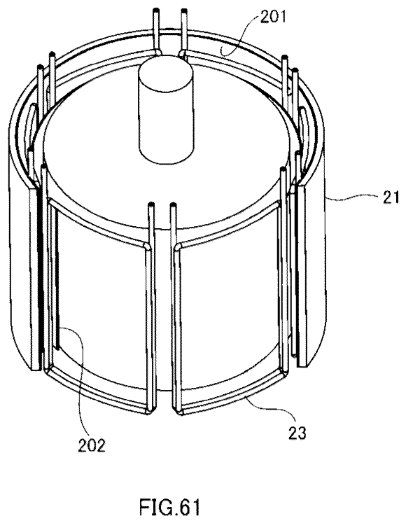

An example of the stator of the above described rotating electrical machine is shown in FIG. 61. FIG. 61 is a perspective view showing the stator of the slotless type rotating electrical machine, where a part of the stator core is cut away.

The stator 2 of the slotless type rotating electrical machine is an example of the configuration where a coil 23 is arranged on the inside of the stator core 21 via an insulation sheet 201 and the coil 23 is further held and fixed by a protective layer 202 on the further inside. Note that the coil 23 is wound only once in FIG. 61 to avoid complication of the drawing. However, the coil 23 is wound a plurality of times in reality as necessary. In addition, the insulating sheet and the protective layer may be appropriately substituted by other means or a structure. Alternatively, it is also possible to omit them. The slotless type rotating electrical machine allows to reduce cogging torque, magnetic losses, iron losses, stray losses and the like.

The above described slotless type can be used as the electrical energy-mechanical energy converter (rotating electrical machine/linear motor) of the present invention.

In addition, the reference numeral 121 is assigned to “heat carrier inlet pipe,” the reference numeral 122 is assigned to “heat carrier outlet pipe” and the heat carrier is explained to flow from the reference numeral 121 to the reference numeral 122 in the above described embodiments. However, the heat carrier may flow in opposite direction, from the reference numeral 122 to the reference numeral 121. In this case, the reference numeral 121 is “heat carrier outlet pipe” and the reference numeral 122 is “heat carrier inlet pipe.”

Furthermore, the type of the rotating electrical machine is not limited. For example, the rotating electrical machine can be applied to an axial flux type rotating electrical machine, an SR rotating electrical machine, an induction rotating electrical machine, a synchronous rotating electrical machine and the like. For example, a superconducting rotating electrical machine can be realized by using liquid nitrogen or liquid helium as the heat carrier.

As a matter of course, the insulating heat carrier and gases such as air can be used as the heat carrier. Alternatively, antifreeze solutions, liquefied freon/halon compounds, liquefied hydrocarbons, silicone oils, liquefied ammonia, liquefied nitrogen, liquefied hydrogen, liquefied rare gases, liquefied carbon dioxide or the like can be also used. As the heat carrier such as water, pure water with very low conductivity can be used while mixing anti-corrosion and other additives.

Furthermore, conductive heat carrier such as water-based liquids can also be used by coating the inside of the hollow conductor wire with an insulating film.

A superconducting rotating electric machine can be realized by using extreme low-temperature heat carrier such as liquid nitrogen or liquid helium as the heat carrier and using superconducting materials for the hollow conductor wire.

Furthermore, an ion exchange resin filter may be installed in the path of the heat carrier. By adopting the above described configuration, ions in the heat carrier can be removed, the electrical conductivity of the heat carrier can be lowered and the insulation property can be increased. Even if the conductive heat carrier leaks, electric leakage can be minimized.

In the above described embodiments, the electrical energy-mechanical energy converter system is mounted on a machine with adjustable output. However, the machine on which the electrical energy-mechanical energy converter system is mounted is not limited. The electrical energy-mechanical energy converter system may be used for the generators such as a wind turbine and a water turbine. The electrical energy-mechanical energy converter system may be used for a generator in a hybrid unit. In this case, system efficiency, miniaturization and weight reduction can be achieved. The electrical energy-mechanical energy converter system may be used for a portable type generator. The electrical energy-mechanical energy converter system may be used for a rotating electrical machine for robots.

The shape of the coil (i.e., conductor wire) may be round, rectangular, or polygonal and may be formed by a metal 3D printer. In addition, the material of the coil is not limited to copper or aluminum. Any kinds of conductors can be used.

The above-mentioned embodiments can be combined appropriately.

The present application claims priority to Japanese Patent Application No. 2023-012342, filed in the Japan Patent Office on Jan. 30, 2023, and the contents of this application are incorporated herein by reference in their entirety.

1. An electrical energy-mechanical energy converter comprising:
a heat carrier inlet pipe having an electrically non-conductive property so that a heat carrier flows inside the heat carrier inlet pipe;
a U-phase heat carrier inlet pipe continued to the heat carrier inlet pipe so that the heat carrier flows inside the U-phase heat carrier inlet pipe after the heat carrier flows inside the heat carrier inlet pipe, the U-phase heat carrier inlet pipe having an electrically conductive property;
a U-phase heat carrier coil including a first wound hollow conductor wire which is continued to the U-phase heat carrier inlet pipe so that the heat carrier flows inside the first wound hollow conductor after the heat carrier flows inside the U-phase heat carrier inlet pipe, the U-phase heat carrier coil having an electrically conductive property;
a U-phase line connected to the U-phase heat carrier inlet pipe, the U-phase line having an electrically conductive property;
a V-phase heat carrier inlet pipe continued to the heat carrier inlet pipe so that the heat carrier flows inside the V-phase heat carrier inlet pipe after the heat carrier flows inside the heat carrier inlet pipe, the V-phase heat carrier inlet pipe having an electrically conductive property;
a V-phase heat carrier coil including a second wound hollow conductor wire which is continued to the V-phase heat carrier inlet pipe so that the heat carrier flows inside the second wound hollow conductor wire after the heat carrier flows inside the V-phase heat carrier inlet pipe, the V-phase heat carrier coil having an electrically conductive property;
a V-phase line connected to the V-phase heat carrier inlet pipe, the V-phase line having an electrically conductive property;
a W-phase heat carrier inlet pipe continued to the heat carrier inlet pipe so that the heat carrier flows inside the W-phase heat carrier inlet pipe after the heat carrier flows inside the heat carrier inlet pipe, the W-phase heat carrier inlet pipe having an electrically conductive property;
a W-phase heat carrier coil including a third wound hollow conductor wire which is continued to the W-phase heat carrier inlet pipe so that the heat carrier flows inside the third wound hollow conductor wire after the heat carrier flows inside the W-phase heat carrier inlet pipe, the W-phase heat carrier coil having an electrically conductive property;
a W-phase line connected to the W-phase heat carrier inlet pipe, the W-phase line having an electrically conductive property; and
a heat carrier outlet pipe having an electrically conductive property so that the heat carrier flows inside the heat carrier outlet pipe after the heat carrier flows inside the U-phase heat carrier coil, and after the heat carrier flows inside the V-phase heat carrier coil, and after the heat carrier flows inside the W-phase heat carrier coil and a current flows through the heat carrier outlet pipe after the current flows through the U-phase heat carrier coil, and after the current flows through the V-phase heat carrier coil, and after the current flows through the W-phase heat carrier coil.

2. The electrical energy-mechanical energy converter according to claim 1, further comprising:
a second U-phase heat carrier coil including a fourth wound hollow conductor wire which is continued to the U-phase heat carrier coil so that the heat carrier flows inside the fourth wound hollow conductor wire after the heat carrier flows inside the U-phase heat carrier coil, the second U-phase heat carrier coil having an electrically conductive property;
a second V-phase heat carrier coil including a fifth wound hollow conductor wire which is continued to the V-phase heat carrier coil so that the heat carrier flows inside the fifth wound hollow conductor wire after the heat carrier flows through the V-phase heat carrier coil, the second V-phase heat carrier coil having an electrically conductive property;
a second W-phase heat carrier coil including a sixth wound hollow conductor wire which is continued to the W-phase heat carrier coil so that the heat carrier flows inside the sixth wound hollow conductor wire after the heat carrier flows inside the W-phase heat carrier coil, the second W-phase heat carrier coil having an electrically conductive property, wherein the heat carrier flows inside the heat carrier outlet pipe after the heat carrier flows inside the U-phase heat carrier coil and the second U-phase heat carrier coil, and after the heat carrier flows inside the V-phase heat carrier coil and the second V-phase heat carrier coil, and after the heat carrier flows inside the W-phase heat carrier coil and the second W-phase heat carrier coil, and
the current flows through the heat carrier outlet pipe after the current flows through the U-phase heat carrier coil and the second U-phase heat carrier coil, and after the current flows through the V-phase heat carrier coil and the second V-phase heat carrier coil, and after the current flows through the W-phase heat carrier coil and the second W-phase heat carrier coil.

3. The electrical energy-mechanical energy converter according to claim 2, further comprising:
a third U-phase heat carrier coil including a seventh wound hollow conductor wire which is continued to the second U-phase heat carrier coil so that the heat carrier flows inside the seventh wound hollow conductor wire after the heat carrier flows inside the second U-phase heat carrier coil, the third U-phase heat carrier coil having an electrically conductive property;
a fourth U-phase heat carrier coil including an eighth wound hollow conductor wire which is continued to the third U-phase heat carrier coil so that the heat carrier flows inside the eighth wound hollow conductor wire after the heat carrier flows inside the third U-phase heat carrier coil, the fourth U-phase heat carrier coil having an electrically conductive property;
a third V-phase heat carrier coil including a ninth wound hollow conductor wire which is continued to the second V-phase heat carrier coil so that the heat carrier flows inside the ninth wound hollow conductor wire after the heat carrier flows inside the second V-phase heat carrier coil, the third V-phase heat carrier coil having an electrically conductive property;
a fourth V-phase heat carrier coil including a tenth wound hollow conductor wire which is continued to the third V-phase heat carrier coil so that the heat carrier flows inside the tenth wound hollow conductor wire after the heat carrier flows inside the third V-phase heat carrier coil, the fourth V-phase heat carrier coil having an electrically conductive property;
a third W-phase heat carrier coil including an eleventh wound hollow conductor wire which is continued to the second W-phase heat carrier coil so that the heat carrier flows inside the eleventh wound hollow conductor wire after the heat carrier flows inside the second W-phase heat carrier coil, the third W-phase heat carrier coil, the third W-phase heat carrier coil having an electrically conductive property; and
a fourth W-phase heat carrier coil including a twelfth wound hollow conductor wire which is continued to the third W-phase heat carrier coil so that the heat carrier flows inside the twelfth wound hollow conductor wire after the heat carrier flows inside the third W-phase heat carrier coil, the fourth W-phase heat carrier coil having an electrically conductive property, wherein
the heat carrier flows inside the heat carrier outlet pipe after the heat carrier flows inside the U-phase heat carrier coil, the second U-phase heat carrier coil, the third U-phase heat carrier coil and the fourth U-phase heat carrier coil, and after the heat carrier flows inside the V-phase heat carrier coil, the second V-phase heat carrier coil, the third V-phase heat carrier coil and the fourth V-phase heat carrier coil, and after the heat carrier flows inside the W-phase heat carrier coil, the second W-phase heat carrier coil, the third W-phase heat carrier coil and the fourth W-phase heat carrier coil, and
the current flows through the heat carrier outlet pipe after the current flows through the U-phase heat carrier coil, the second U-phase heat carrier coil, the third U-phase heat carrier coil and the fourth U-phase heat carrier coil, and after the current flows through the V-phase heat carrier coil, the second V-phase heat carrier coil, the third V-phase heat carrier coil and the fourth V-phase heat carrier coil, and after the current flows through the W-phase heat carrier coil, the second W-phase heat carrier coil, the third W-phase heat carrier coil and the fourth W-phase heat carrier coil.

4. The electrical energy-mechanical energy converter according to claim 2, further comprising:
a third U-phase heat carrier coil including a seventh wound hollow conductor wire which is continued to the U-phase heat carrier inlet pipe so that the heat carrier flows inside the seventh wound hollow conductor wire after the heat carrier flows inside the U-phase heat carrier inlet pipe, the third U-phase heat carrier coil having an electrically conductive property, a fourth U-phase heat carrier coil including an eighth wound hollow conductor wire which is continued to the third U-phase heat carrier coil so that the heat carrier flows inside the eighth wound hollow conductor wire after the heat carrier flows inside the third U-phase heat carrier coil, the fourth U-phase heat carrier coil having an electrically conductive property;
a third V-phase heat carrier coil including a ninth wound hollow conductor wire which is continued to the V-phase heat carrier inlet pipe so that the heat carrier flows inside the ninth wound hollow conductor wire after the heat carrier flows inside the V-phase heat carrier inlet pipe, the third V-phase heat carrier coil having an electrically conductive property;
a fourth V-phase heat carrier coil including a tenth wound hollow conductor wire which is continued to the tenth wound hollow conductor wire so that the heat carrier flows inside the fourth V-phase heat carrier coil after the heat carrier flows inside the third V-phase heat carrier coil, the fourth V-phase heat carrier coil having an electrically conductive property;
a third W-phase heat carrier coil including an eleventh wound hollow conductor wire which is continued to the W-phase heat carrier inlet pipe so that the heat carrier flows inside the eleventh wound hollow conductor wire after the heat carrier flows inside the W-phase heat carrier inlet pipe, the third W-phase heat carrier coil having an electrically conductive property; and
a fourth W-phase heat carrier coil including a twelfth wound hollow conductor wire which is continued to the third W-phase heat carrier coil so that the heat carrier flows inside the twelfth wound hollow conductor wire after the heat carrier flows inside the third W-phase heat carrier coil, the fourth W-phase heat carrier coil having an electrically conductive property, wherein
the heat carrier flows inside the heat carrier outlet pipe after the heat carrier flows through the U-phase heat carrier coil and the second U-phase heat carrier coil, and after the heat carrier flows inside the third U-phase heat carrier coil and the fourth U-phase heat carrier coil, and after the heat carrier flows inside the V-phase heat carrier coil an the second V-phase heat carrier coil, and after the heat carrier flows inside the third V-phase heat carrier coil and the fourth V-phase heat carrier coil, and after the heat carrier flows inside the W-phase heat carrier coil and the second W-phase heat carrier coil, or the heat carrier flows inside the third W-phase heat carrier coil and the fourth W-phase heat carrier coil, and
the current flows through the heat carrier outlet pipe after the current flows through the U-phase heat carrier coil and the second U-phase heat carrier coil, and after the current flows through the third U-phase heat carrier coil and the fourth U-phase heat carrier coil, and after the current flows through the V-phase heat carrier coil and the second V-phase heat carrier coil, and after the current flows through the fourth V-phase heat carrier coil, and after the current flows through the W-phase heat carrier coil and the second W-phase heat carrier coil, and after the current flows through the third W-phase heat carrier coil and the fourth W-phase heat carrier coil.

5. The electrical energy-mechanical energy converter according to claim 1, further comprising:
a second U-phase heat carrier coil including a fourth wound hollow conductor wire which is continued to the U-phase heat carrier inlet pipe so that the heat carrier flows inside the fourth wound hollow conductor wire after the heat carrier flows inside the U-phase heat carrier inlet pipe, the second U-phase heat carrier coil having an electrically conductive property;
a second V-phase heat carrier coil including a fifth wound hollow conductor wire which is continued to the V-phase heat carrier inlet pipe so that the heat carrier flows inside the fifth wound hollow conductor wire after the heat carrier flows inside the V-phase heat carrier inlet pipe, the second V-phase heat carrier coil having an electrically conductive property;
a second W-phase heat carrier coil including a sixth wound hollow conductor wire which is continued to the W-phase heat carrier inlet pipe so that the heat carrier flows inside the sixth wound hollow conductor wire after the heat carrier flows inside the W-phase heat carrier inlet pipe, the second W-phase heat carrier coil having an electrically conductive property, wherein the heat carrier flows inside the heat carrier outlet pipe after the heat carrier flows through the U-phase heat carrier coil, and after the heat carrier flows through the second U-phase heat carrier coil, and after the heat carrier flows through the V-phase heat carrier coil, and after the heat carrier flows through the second V-phase heat carrier coil, and after the heat carrier flows through the W-phase heat carrier coil, and after the heat carrier flows through the second W-phase heat carrier coil, and
the current flows through the heat carrier outlet pipe after the current flows through the U-phase heat carrier coil, and after the current flows through the second U-phase heat carrier coil, and after the current flows through the V-phase heat carrier coil, and after the current flows through the second V-phase heat carrier coil, and after the current flows through the W-phase heat carrier coil, and after the current flows through the second W-phase heat carrier coil.

6. The electrical energy-mechanical energy converter according to claim 5, further comprising:
a third U-phase heat carrier coil including a seventh wound hollow conductor wire which is continued to the U-phase heat carrier inlet pipe so that the heat carrier flows inside the seventh wound hollow conductor wire after the heat carrier flows inside the U-phase heat carrier inlet pipe, the third U-phase heat carrier coil having an electrically conductive property;
a fourth U-phase heat carrier coil including an eighth wound hollow conductor wire which is continued to the U-phase heat carrier inlet pipe so that the heat carrier flows inside the eighth wound hollow conductor wire after the heat carrier flows inside the U-phase heat carrier inlet pipe, the fourth U-phase heat carrier coil having an electrically conductive property;
a third V-phase heat carrier coil including a ninth wound hollow conductor wire which is continued to the V-phase heat carrier inlet pipe so that the heat carrier flows inside the ninth wound hollow conductor wire after the heat carrier flows inside the V-phase heat carrier inlet pipe, the third V-phase heat carrier coil having an electrically conductive property;
a fourth V-phase heat carrier coil including a tenth wound hollow conductor wire which is continued to the V-phase heat carrier inlet pipe so that the heat carrier flows inside the tenth wound hollow conductor wire after the heat carrier flows inside the V-phase heat carrier inlet pipe, the fourth V-phase heat carrier coil having an electrically conductive property;
a third W-phase heat carrier coil including an eleventh wound hollow conductor wire which is continued to the W-phase heat carrier inlet pipe so that the heat carrier flows inside the eleventh wound hollow conductor wire after the heat carrier flows inside the W-phase heat carrier inlet pipe, the third W-phase heat carrier coil having an electrically conductive property;
a fourth W-phase heat carrier coil including a twelfth wound hollow conductor wire which is continued to the W-phase heat carrier inlet pipe so that the heat carrier flows inside the twelfth wound hollow conductor wire after the heat carrier flows inside the W-phase heat carrier inlet pipe, the fourth W-phase heat carrier coil having an electrically conductive property, wherein
the heat carrier flows inside the heat carrier outlet pipe after the heat carrier flows inside the U-phase heat carrier coil, and after the heat carrier flows inside the second U-phase heat carrier coil, and after the heat carrier flows inside the third U-phase heat carrier coil, and after the heat carrier flows inside the fourth U-phase heat carrier coil, and after the heat carrier flows inside the V-phase heat carrier coil, and after the heat carrier flows inside the second V-phase heat carrier coil, and after the heat carrier flows inside the third V-phase heat carrier coil, and after the heat carrier flows inside the fourth V-phase heat carrier coil, and after the heat carrier flows inside the W-phase heat carrier coil, and after the heat carrier flows inside the second W-phase heat carrier coil, and after the heat carrier flows inside the third W-phase heat carrier coil, and after the heat carrier flows inside the fourth W-phase heat carrier coil, and the current flows through the heat carrier outlet pipe after the current flows the U-phase heat carrier coil, and after the current flows through the second U-phase heat carrier coil, and after the current flows through the third U-phase heat carrier coil, and after the current flows through the fourth U-phase heat carrier coil, and after the current flows through the V-phase heat carrier coil, and after the current flows through the second V-phase heat carrier coil, and after the current flows through the third V-phase heat carrier coil, and after the current flows through the fourth V-phase heat carrier coil, and after the current flows through the W-phase heat carrier coil, and after the current flows through the second W-phase heat carrier coil, and after the current flows through the third W-phase heat carrier coil, and after the current flows through the fourth W-phase heat carrier coil.

7. The electrical energy-mechanical energy converter according to claim 1, wherein
each of the U-phase heat carrier coil, the V-phase heat carrier coil and the W-phase heat carrier coil is a concentrated winding type where the hollow conductor wire is wound around each of the U-phase heat carrier coil, the V-phase heat carrier coil and the W-phase heat carrier coil of a stator core.

8. The electrical energy-mechanical energy converter according to claim 1, wherein
each of the U-phase heat carrier coil, the V-phase heat carrier coil and the W-phase heat carrier coil is a distributed winding type where the hollow conductor wire is wound over a plurality of slots of a stator core.
